(19) United States
(12) Patent Application Publication
(10) Pub. No.: US 2009/0038669 A1
(43) Pub. Date: Feb. 12, 2009

(54) Thin Film Solar Cell III

(75) Inventor: Petar B. Atanackovic, Henley Beach (AU)

Correspondence Address: FERNANDEZ & ASSOCIATES LLP, 1047 EL CAMINO REAL, SUITE 201, MENLO PARK, CA, 94025, US

(73) Assignee: Translucent Photonics, Inc., Palo Alto, CA (US)

(21) Appl. No.: 11/858,838

(22) Filed: Sep. 20, 2007

Related U.S. Application Data
(60) Provisional application No. 60/846,818, filed on Sep. 20, 2006.
(60) Provisional application No. 60/847,767, filed on Sep. 27, 2006.

(51) Int. Cl. H01L 31/00

(52) U.S. Cl. 136/244; 136/261; 136/256; 257/E31.001

(57) ABSTRACT

The present invention teaches a device for converting solar radiation to electrical energy comprising a thin film, single crystal device chosen from a variety of semiconductor materials, optionally, employing an alternative substrate, and various combinations of p-n, p-i-n and avalanche p-i-n diodes to enable high conversion efficiency photo-voltaic devices.

### CROSS REFERENCE TO RELATED APPLICATIONS

Applications and patent Ser. Nos. 09/924,392, 10/666,897, 10/746,957, 10/799,549, 10/825,912, 10/825,974, 11/022,078, 11/025,363, 11/025,680, 11/025,681, 11/025,692, 11/025,693, 11/084,486, 11/121,737, 11/187,213, U.S. 20050166834, U.S. 20050161773, U.S. 20050163692, 11/053,775, 11/053,785, 11/054,573, 11/054,579, 11/054,627, 11/068,222, 11/188,081, 11/253,525, 11/254,031, 11/257,517, 11/257,597, 11/393,629, 11/398,910, 11/472,087, 11/788,153, 60/533,378, 60/811,311, 60/820,438, 60/847,767, 60/876,182, 60/905,415, 60/944,369, 60/949,753, U.S. Pat. No. 7,018,484, U.S. Pat. No. 6,734,453, U.S. Pat. No. 7,023,011, U.S. Pat. No. 6,858,864, U.S. Pat. No. 7,037,806, U.S. Pat. No. 7,135,699, and U.S. Pat. No. 7,199,015, all held by the same assignee, contain information relevant to the instant invention and are included herein in their entirety by reference. “Thin Film Silicon Energy Conversion Devices”, which is attached, is included herein by reference in its entirety.

### PRIORITY

This application claims priority from Provisional Application titled “Thin Film Solar Cell” filed on Sep. 24, 2006, Ser. No. 60/846,818 and Provisional Application titled “Thin Film Solar Cell II” filed on Sep. 27, 2006, Ser. No. 60/847,767, now Ser. No. 11/788,153; both are included herein by reference in their entirety.

### FIELD OF INVENTION

The present invention is generally, but not limited to, the field of energy conversion devices. In particular, the present invention converts solar radiation directly into electrical energy capable of doing useful work when delivered to an electrical load or energy storage medium.

### BACKGROUND OF INVENTION

Thin Film Silicon Energy Conversion Devices

Optimal structures for high efficiency thin film silicon solar energy conversion devices and systems are disclosed. Large substrate area handling and planar processing methods are disclosed. A planar integrated process disclosed is preferentially embodied using high volume, scalable fabrication techniques. Thin film, silicon active layer, photoelectron conversion structures using ion implantation are disclosed. Thin film semiconductor devices optimized for exploiting the high energy and ultraviolet portion of the solar spectrum at the earths surface are also disclosed. Single crystal Si films based on a novel internal steam cleaving layer separation method is disclosed. Solar cell fabrication using high oxygen concentration single crystal silicon substrates formed using in preference the Czochralski, CZ, method are used advantageously. Oxide crucibles for CZ growth of high oxygen content single crystal Si substrates are also disclosed for application to low cost solar cell manufacture. A long standing deficiency in prior art is overcome in the present invention by the use of large throughput planar processing techniques, such as, ion implantation and lithographic techniques to significantly reduce the cost per solar cell. Furthermore, the present invention discloses optical coatings for advantageous coupling of solar radiation into thin film solar cell devices via the use of rare-earth metal oxide (REOₓ), rare-earth metal oxynitride (REOₓN_{y}), and rare-earth metal oxy-phosphide (REOₓP_{y}) glasses, optionally crystalline, optionally single or poly-crystalline, material. A rare-earth metal is chosen from the group commonly known in the periodic table of elements as the lanthanide series. Optionally, a rare-earth metal oxide, nitride or phosphide may comprise two or more rare-earths and two or more elements from a group comprising oxygen, nitrogen, phosphorous, silicon, germanium, carbon, and III-V elements.

### FIELD OF INVENTION

The present invention is generally, but not limited to, the field of energy conversion devices. In particular, the present invention converts solar radiation in the optical spectrum directly into electrical energy capable of doing useful work when delivered to an electrical load or energy storage medium.

### BACKGROUND OF INVENTION

Present Silicon (Si) solar cell devices are manufactured using bulk and/or thin film configurations. Typically, bulk Si solar cells are classed as first generation devices. In an effort to reduce cell cost, the volume of Si required is reduced using thin films of Si on relatively cheaper substrates, such as glass (e.g., SiO₂). Thin film semiconductor solar cell approaches form generally second generation devices. Unfortunately, depositing high quality single crystal (or monocrystalline) silicon, sc-Si, on amorphous substrates has proved extremely difficult. Typically, the Si deposited on glass substrates is amorphous. Efforts to produce amorphous Si (a-Si) solar cells have consistently shown inferior performance compared to single crystal bulk Si solar cells. To improve the crystal quality of the a-Si films, they must be heat treated to temperatures approaching the melting point of Si (Tₘₑₗₜ˜1420° C.) in order for recrystallization to occur. The result of which is either polycrystalline (poly-Si) and/or large domain single crystal Si. Again, the poly-Si and/or large domain single crystal Si (sc-Si) thin film solar cells have energy conversion efficiency below single crystal bulk Si solar cells. Both first and second generation Si solar devices are based on single junction (SJ) configuration. A limitation of SJ's is that only a small optical energy absorption window can be used advantageously, thereby rejecting a large portion of the available radiation from the solar spectrum. It has been theoretically shown by workers in the field that the maximum attainable energy conversion efficiency for SJ cells is η(SJ)=25-32%. The present invention solves a long standing problem of detrimental high energy photon effects in Si solar cell devices.

The superior crystal quality of bulk Si substrates manufactured using Czochralski (CZ) growth techniques is due to Si ultra-large-scale-integrated-circuits (ULSICs) based on complementary-metal-oxide-semiconductor (CMOS) transistors. Single crystal Si substrates with diameters of 300 mm are presently in widespread CMOS production with plans to implement 450 mm in the future. A unique aspect of ULSI CMOS industry is the extremely successful manipulation of large form factor substrates using area fabrication tools, such as, ion implantation, thin film deposition and lithography. This allows high complexity structures to be economically manufactured with high throughput—i.e., wafer scale manufacture.

The silicon solar cell industry in comparison can be described as a discrete fabrication technology with extremely low levels of integration. For example, a single junction Si solar cell typically delivers less than 0.7V and large numbers of discrete cells must be interconnected into modules in order to generate useful voltages for power generation. Furthermore, each cell must be separately packaged and environmentally sealed. The present invention discloses wafer scale manufacture of SJ silicon modules using high throughput and large area substrates. Furthermore, the present invention discloses large area thin film Si transfer technique onto cost effective substrates. The device fabrication methods disclosed allow complex power systems with low cost when applied to high volume throughput. As a general observation, a solar power fabrication plant producing 1 gigawatt using silicon SJ devices will consume approximately 150-200 times more Si substrate area than a 300 mm CMOS plant.

Solar Energy Conversion Devices

The broadband solar optical spectrum at ground level ranges from 300 nm to over 1700 nm, spanning the ultraviolet to far infrared. FIG. 1 shows a general power spectrum, punctuated with multiple absorption regions. The spectral variance is seen to occur in the 400-600 nm region. Optical photon to electron conversion devices employing semiconductors are well known. FIG. 2 shows the absorption coefficient α_{abs} of several technologically mature semiconductors. The indirect bandgap semiconductors Si and germanium (Ge) span major portions of the solar spectrum. Group III-V direct band gap compound semiconductors, such as, gallium arsenide (GaAs), indium phosphide (InP) and indium gallium arsenide (InGaAs) and alloys also have good spectrum coverage and exhibit sharp cut-on wavelengths defined by the direct band edges. Wide band gap silicon-carbide (6H:SiC) absorbs only at the highest energies in the UV, and covers the least fraction of the solar spectrum. In comparison Si and Ge, have long wavelength absorption tails due to the indirect energy-momentum band structure. If an optical photon incident upon the Si crystal has energy equal to or above the fundamental band gap energy it is absorbed. This creates an electron-hole pair with the aid of an appropriate lattice phonon wave vector—which is required in the photocarrier generation process in order to conserve energy and momentum. The inverse process of electron-hole (e-h) recombination is extremely inefficient compared to direct band gap semiconductors. For the present case of optical to electronic conversion, indirect band gap Si is advantageous for high sensitivity photodetection compared to direct band gap semiconductors where e-h radiative recombination is efficient and represents a significant loss mechanism. Looking closely at the absorption coefficient of Si in FIG. 1, it is clear that the absorption depth near the fundament band gap (Eg˜1.1 eV) is extremely long. This means that photons with energy equal to or slightly greater than band gap energy Eg(Si) will penetrate to a depth Lₑ=1/α_{abs}, deep within the crystal. However, the highest absorption coefficient for all the semiconductors is found for Si for wavelengths shorter than ˜400 nm. Silicon photodetectors (SiPDs) have been shown to exhibit very low noise, high sensitivity and efficient avalanche multiplication effects. The low noise property is due to the small probability of radiative recombination due to the intrinsic indirect energy bandgap structure. The spectral range of SiPDs spans the broad range 200 nm to 1200 nm, and will be discussed later for application to UV solar cell conversion.

FIG. 3 shows the overlap of Si 303 and Ge 302 absorption with the solar spectrum 301 as a function of wavelength. Therefore, Ge is a superior choice for solar spectrum absorption and has 10-100× higher absorption co-efficient than Si in the 1.1-3 eV range. This means 10-100× thinner film absorbers using Ge are possible compared to Si. The use of Ge extends absorption down to 0.66 eV and therefore can potentially access more of the available solar spectrum and power.

For the case of high volume, large area and low cost solar cell fabrication, Si substrates are still advantageous and at least ˜10-50× cheaper than Ge substrates. However, even by using Si substrates in preference to all other commercially relevant semiconductors, there is a need to increase solar cell efficiency and dramatically reduce cost.

One of the disadvantages of conventional solar cells based on a bulk Silicon semiconductor absorber is that the incidence of high energy photons degrades the absorption and conversion efficiency of the Silicon solar cell. Whilst the monochromatic efficiency can be high, the wide energy bandwidth or polychromatic efficiency is much lower. Clearly, this is a large disadvantage with Silicon as the solar cells are designed to generate energy from solar radiation. One attempt to overcome this disadvantage is to employ optical filtering to narrow the wavelength band of incident radiation. However, this has the obvious disadvantage that large amounts of useful spectrum are discarded and accordingly more incident power is required at a specific wavelength to increase the output current of the solar cell. Other methods use semiconductors from either III-V compounds or II-VI compounds in preference to Si or in conjunction with Silicon. Specifically GaAs, gallium-indium-phosphide (GaInP), copper-indium-gallium-selenide (CIGS) and cadmium-telluride/sulphide (CdTe/CdS) compounds are disposed on cost effective substrates. Electrical conversion efficiency can be relatively high but typically lower than compared with single crystal silicon solar cells and further suffer the disadvantage of either high cost, non-abundant materials and use of toxic substances. All such devices based on alternative conversion medium are typically SJ devices and therefore constrained to maximum potential efficiency identical to single crystal Si SJ cell.

Impurity atom doping of bulk semiconductors is also possible, wherein an electrical defect level is created within the forbidden energy gap of the host semiconductor. The defect adsorption can extend the optical absorption to longer wavelengths (i.e., smaller photon energy) but suffers the disadvantage of poor electrical transport of photo-generated e-h carriers. Therefore, defect type adsorber generally exhibit poor optical to electrical conversion efficiency in an external circuit.

In theory, Si should be a very efficient solar cell material; however high energy photons degrade the conversion efficiency. FIG. 4 shows the energy band structure of bulk single crystal Si as a function real space co-ordinate (left) and as an indirect energy-momentum E-k band structure (right). The periodic array of Si atoms in the crystal forms an extended band structure consisting of conduction and valence bands. An electron and hole is constrained to satisfy the E-k dispersion as shown. High energy UV photons are efficiently absorbed (within 2 μm (microns) of the surface for 400 nm photons) in the upper conduction and valence bands creating electron hole pairs—but quickly thermalize by emitting lattice phonons of energy ω_{LO}. The UV photo-generated carriers therefore cannot easily participate in photocurrent generation in p-n junction devices.

To increase UV responsivity, or conversion efficiency, it is therefore essential to avoid dead layer formation on the surface. Dead layers are typically due to heavy dopant implantation and/or diffusion required for good ohmic contacts to Si. A method to circumvent dead layer region(s) is via the use of inversion layer diodes (ILDs). ILDs are constructed by creating a charge inversion layer at the interface between a dielectric material and semiconductor, for example SiO₂/Si interface. Alternatively, an inversion layer can generate a potential energy Schottky barrier via appropriate work function metal placed in contact with intrinsic Si. The UV response of ILDs is superior to vertical and/or planar p-n and/or p-i-n junction type photodiodes. Only small reverse bias are required to deplete the inversion layer region and is advantageous for improving responsivity via higher efficiency photogenerated carrier collection. Photovoltaic operation can be optimized via a built-in voltage generated by advantageous placement of a lightly doped shallow diffused and/or implanted junction formation close to the surface of the device. The UV responsivity at a particular wavelength λ can be improved by growing an SiO₂ layer on the silicon surface with a thickness equal to mλ/(4n_{SiO2}), where λ is the wavelength of light in SiO₂,n_{SiO2} is the refractive index of SiO₂ and m=˜1, 3, 5 . . . is an odd integer. High quality SiO₂ has a large band gap, Eg(SiO₂)˜9 eV, and does not absorb UV light. Depending on the growth and/or deposition technique used to form SiO₂, various amounts of hydrogen may be incorporated in the glass layer. The hydrogen may affect the transmission/absorption properties of the film. Conversely, SiO₂ and hydrogen are beneficial for surface passivation of the Si surface states and is a desirable property. Typically, SiO₂ is an optimal antireflection (AR) coating as well as a passivation layer. The use of transparent AR layers is used in preferred embodiment of the present invention.

Typically, monochromatic solar cell efficiency ηₘₒₙₒ is good. Conversely, polychromatic solar efficiency ηₛₒₗₐᵣ is much less than ηₘₒₙₒ for conventional SJ solar devices. Optical filtering helps efficiency but discards a large portion of useful spectrum. Using optical filtering techniques to narrow the incident optical energy spectrum therefore requires more incident power at specific wavelength to increase output electrical current. Optical filters using quarter wavelength dielectric multilayers are well known. The dielectric filters typically use at least two dissimilar refractive index materials, exhibiting high transparency at the desired wavelength range of operation.

Typically, wide band gap energy materials, optically transparent to the solar spectrum, such as, SiO₂, magnesium-oxide (MgO), calcium fluoride (CaF₂), magnesium fluoride (MgF₂), silicon-nitride (Si₃N₄), titanium-dioxide TiO₂, tantalum-pentoxide (Ta₂O₅) and the like are used.

### SUMMARY OF INVENTION

The present invention teaches a device for converting solar radiation to electrical energy comprising a thin film, single crystal device chosen from a variety of semiconductor materials, optionally employing alternative substrates, and various combinations of p-n, p-i-n and avalanche p-i-n diodes to enable high conversion efficiency photo-voltaic devices.

Complex multilayer constructions are possible to create interference filters with narrow and/or broadband transmission and/or AR characteristics. Less well known, is the use of one-dimensional photonic bandgap materials combined with principles of two-dimensionally layered dielectric stacks. Omni-directional reflectors are possible, with reflection property substantially independent of wavelength as a function of incident angle to the surface—similar to an ideal metal, but with negligible absorption. The present invention further teaches that such principles can be used to create omni-directional transmitters to form broadband optical couplers to solar cell active regions.

High Throughput Thin Film Si Solar Devices

The present invention solves a long standing problem in thin film single crystal silicon solar cell manufacture. The aim of thin film sc-Si solar cell is twofold. Thin film sc-Si reduces manufacturing cost via reducing the amount of high quality sc-Si consumed in solar cell and the use of cheaper substrates, such as glass, metal, polymer and/or flexible substrates. Generally, prior art approaches at generating thin films of sc-Si have been limited via mechanical sawing of bulk Si material and/or deposition of Si followed by complex recrystallization processes. Such prior art approaches have resulted in solar cell conversion efficiency approaching bulk sc-Si cells only via general class of process using essentially sawing techniques. That is, the bulk sc-Si substrate CZ manufacturing process produces the highest crystalline structure perfection and thus the highest efficiency solar cell. Sawing techniques are limited to sc-Si film thickness of the order of millimeters.

One embodiment of the present invention teaches that optimal thin film sc-Si solar cells require active layer film thickness L_{Si} in the range of 20 nm≦L_{Si}≦250 μm. Single junction thin film devices in this regime are required to attain maximum conversion efficiency exceeding 32%.

Therefore, there is a need for a low cost, high throughput, large area handling manufacturing technique for producing thin films of high quality sc-Si.

Furthermore, there is a need for a cost effective, high throughput, and large area handling manufacturing technique for producing thin films of high quality sc-Si disposed upon low cost substrates.

There is also a need for a cost effective, high throughput, and large area handling manufacturing technique for creating large numbers of selective area doped Si regions for producing electrical function of the solar cell devices using the said thin films of high quality sc-Si disposed upon low cost substrates.

There is also a need for a cost effective, high throughput, and large area handling manufacturing technique for integrating and interconnecting large numbers of solar cell devices for producing high power modules using the said thin films of high quality sc-Si disposed upon low cost substrates.

The present invention solves the aforementioned needs via the use of planar processing method and large wafer handling techniques.

### BRIEF DESCRIPTION OF THE DRAWINGS

Illustrative embodiments of the present invention are discussed with reference to the accompanying drawings. The Figures are exemplary and not meant to be limiting; alternative compositions, as discussed in the specification and known to one knowledgeable in the art are possible for each material combination presented in the figures.

FIG. 1A is a plot of ground level spectral composition of solar radiation from 300 nanometers to 1,800 nanometers; FIG. 1B is an overview of the photon-to-electron conversion process.

FIG. 2 shows adsorption coefficients versus wavelength for various materials.

FIG. 3A, B and C are plots of ground level spectral composition of solar radiation and adsorption coefficients and useful ranges for conventional semiconductors.

FIGS. 4A, B, C and D present overviews of the optical absorption process in a semiconductor.

FIG. 5 shows H and/or He ion implantation to a predetermined depth.

FIG. 6A shows ion depth profile beneath the Si surface versus implant energy. FIG. 6B shows the article and implantation configuration.

FIG. 7A schematically shows ion implant; FIG. 7B shows calculated depth profile of H+ ions implanted for a given ion energy.

FIG. 8A shows various steps in preparing for thin film defoliation. FIG. 8B shows the preparation steps for the alternative or replacement substrate.

FIG. 9 shows steps for bonding an active wafer to a replacement substrate.

FIG. 10 shows preparation for original semiconductor substrate removal and thin film transfer onto alternative substrate.

FIG. 11 shows steps for original substrate removal and thin film layer transfer.

FIG. 12A shows steps for electrical connection of electrode and coupling of incident optical energy to thin film active layer; 12B shows reclaim steps of bulk semiconductor substrate.

FIGS. 13A and B show alternative steps for thin film preparation and patterning of buried electrodes on alternative substrate.

FIGS. 14 A and B show alternative steps for replacement substrate bonding to thin film handle substrate.

FIG. 15 shows alternative steps for original substrate removal using thermally activated delamination.

FIG. 16 shows alternative steps for original substrate removal.

FIGS. 17 A and B shows alternative steps for operating device and substrate reclaim.

FIG. 18 shows alternative steps for replacement substrate preparation including preparation of buried electrodes.

FIG. 19 shows alternative steps for original bulk semiconductor substrate preparation, including steps of masking, forming thin film separation layer, and the selective area implantation of regions within the thin film layer.

FIGS. 20 A and B show alternative steps for replacement substrate bonding to bulk semiconductor substrate containing buried delamination layer and thin film layer.

FIG. 21 shows alternative steps for original substrate preparation for separation.

FIG. 22 shows alternative steps for original substrate separation and formation of thin film active layer electrically connected via selective area implantation regions to electrodes disposed upon the alternative substrate.

FIGS. 23 A and B shows alternative steps for operating device and substrate reclaim.

FIG. 24 shows an electrode pattern and implantation regions in a thin film semiconductor forming a photovoltaic device or cell.

FIGS. 25 A and B shows wafer scale electrode patterns for a photovoltaic module and interconnection scheme consisting of multiple repeating photovoltaic cells.

FIG. 26 shows an optional format for a photovoltaic apparatus; FIG. 26B shows an optional layout scheme for a photovoltaic module fabricated on circular wafer; FIG. 26A shows another optional layout scheme for a photovoltaic module fabricated on large area rectangular wafer. FIG. 26C shows an optional configuration and interconnection for a photovoltaic module using unit cell devices configured to operate in substantially voltage source or current source.

FIG. 27 shows an optional configuration for a thin film photovoltaic devices.

FIGS. 28A and B show another optional configuration for a thin film photovoltaic device.

FIGS. 29A and B show another optional configuration for a thin film photovoltaic device.

FIG. 30 shows another optional configuration for a thin film photovoltaic device.

FIG. 31 shows another optional configuration for a thin film photovoltaic device.

FIG. 32 shows another optional configuration for a thin film photovoltaic device.

FIG. 33 shows another optional configuration for a thin film photovoltaic device.

FIG. 34 shows another optional configuration for a thin film photovoltaic device.

FIG. 35 shows another optional configuration for a thin film photovoltaic device.

FIG. 36 shows another optional configuration for a thin film photovoltaic device.

FIG. 37 shows the increased adsorption coefficient for silicon at short wavelengths.

FIG. 38 shows solar spectral variance at ground level.

FIG. 39 shows spectral sensitivity of thin film single crystal silicon in a UV selective solar cell.

FIG. 40 shows spectral sensitivity of thin film sc silicon in a solar cell compared with the solar spectrum.

FIG. 41A shows a multi-wavelength selective solar energy conversion device using wedge shaped active layer thin film semiconductor-on-glass. For example, wedge thin film formed by CMP process. FIG. 41B shows an alternative CMP multi-wavelength selective solar energy conversion device.

FIG. 42 shows manufacturing cost per solar cell versus number of cells per module.

FIG. 43 shows solar efficiency versus cost per area and device type.

FIG. 44 schematically shows an alternative radiation conversion type device, a lateral p-n diode.

FIG. 45 schematically shows an alternative radiation conversion type device, a dual lateral-vertical p-n diode.

FIG. 46 schematically shows an alternative radiation conversion type device, a double p-n solar cell (n-p-n).

FIG. 47A schematically shows an alternative radiation conversion type device, a lateral p-n multi-finger junction; FIG. 47B schematically shows another alternative radiation conversion type device, a lateral p-n multi-finger junction with a backside contact.

FIGS. 48 A and B schematically show alternative radiation conversion type devices composed of multilayers and/or differing conductivity types; FIGS. 48C and D schematically show the Energy Band structure for p-n junction and p-i-n devices.

FIG. 49 schematically shows an alternative radiation conversion type device, a vertical p-i-n, using implantation induced conductivity regions.

FIG. 50A schematically shows an alternative radiation conversion type device, a lateral p-i-n; FIGS. 50B and C show alternative electrode patterns.

FIG. 51 schematically shows an alternative radiation conversion type device, a n+/p substrate and buried collector.

FIG. 52 schematically shows energy-momentum band structure for an indirect semiconductor and possible photogenerated electron and hole pairs.

FIG. 53 schematically shows an alternative energy-momentum band structure for a degenerate n-type indirect semiconductor radiation conversion device.

FIG. 54 schematically shows an alternative energy-momentum band structure for a degenerate p-type indirect semiconductor radiation conversion device.

FIG. 55 schematically compares adsorption coefficient versus wavelength for undoped and degenerately doped indirect semiconductor radiation conversion device.

FIG. 56 schematically compares adsorption coefficient and solar spectrum versus wavelength for undoped and degenerately doped indirect semiconductor radiation conversion device.

FIG. 57 schematically shows energy-momentum band structure for an indirect semiconductor under the influence of increasing temperature.

FIG. 58 schematically shows adsorption coefficient versus wavelength for an indirect semiconductor under the influence of increasing temperature.

FIG. 59 is a schematic of alternative process for layer separation using sacrificial layer.

FIG. 60 shows an optional layout scheme for a photovoltaic module wafer, utilizing reconfigurable interconnections.

FIG. 61 shows a system level layout scheme for a photovoltaic module wafer.

FIG. 62 shows multiple modules wired together utilizing interfacing function.

FIG. 63 shows alternative configuration of scheme for energy conversion device based on charge-pump concept.

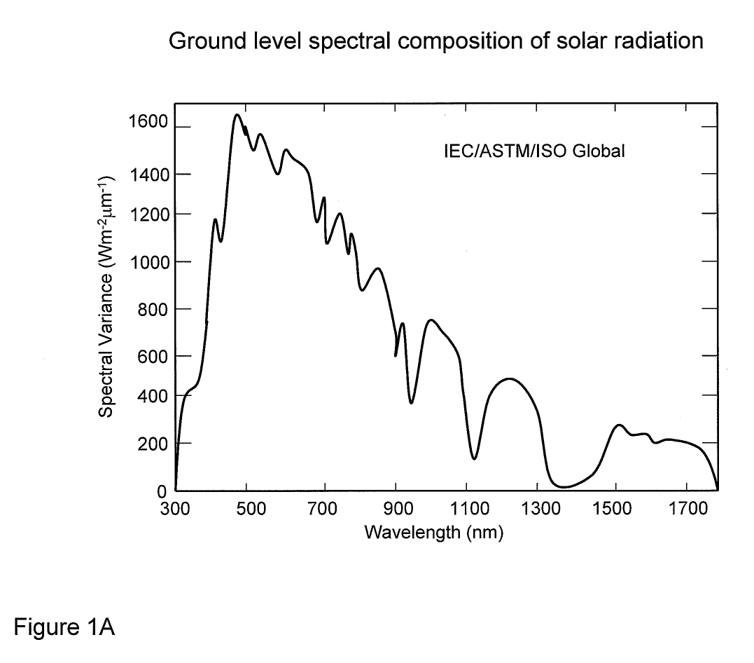

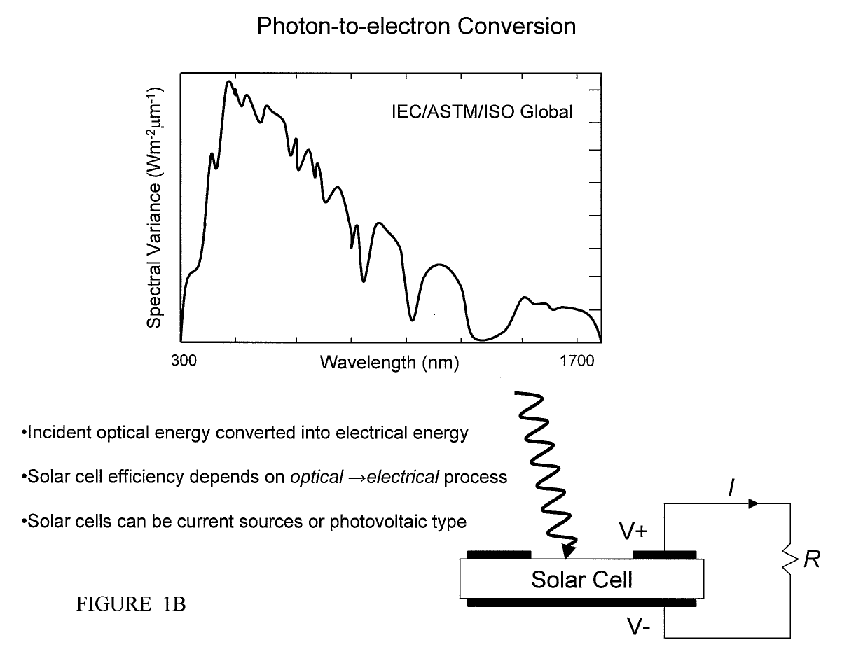

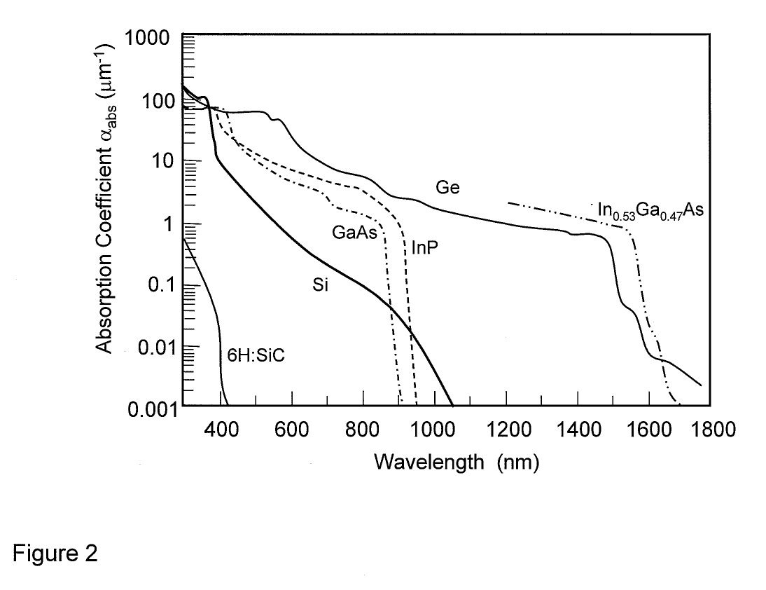

### DETAILED DESCRIPTION OF SEVERAL EMBODIMENTS

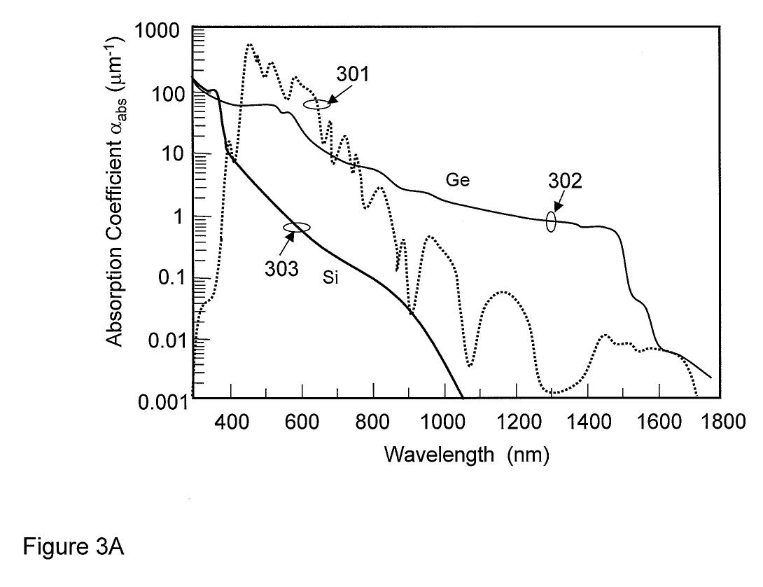

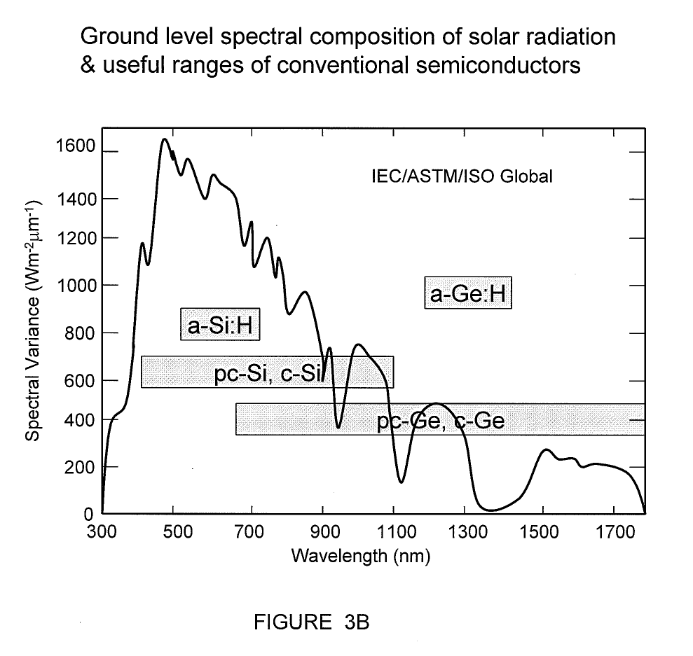

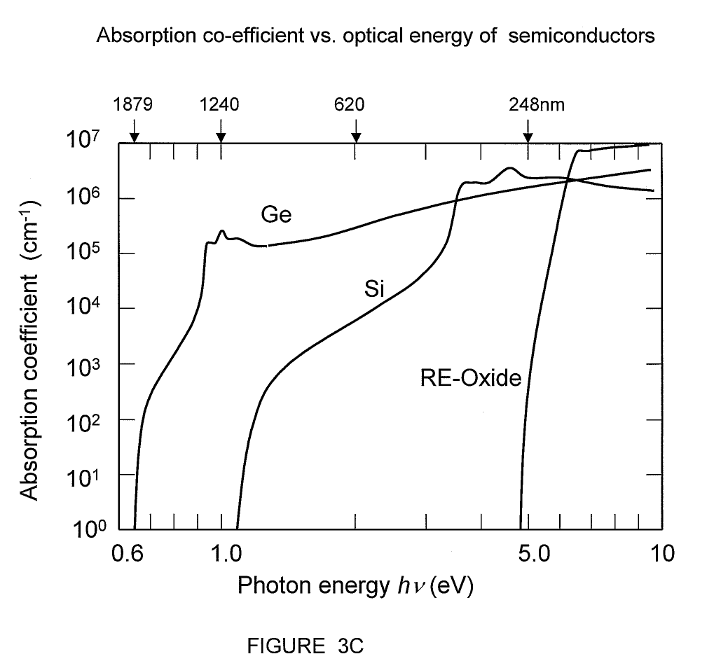

FIGS. 3A and 3B are plots of ground level spectral composition of solar radiation and adsorption coefficients and useful ranges of use for conventional semiconductors such as single crystal silicon, (sc-Si), and single crystal germanium, (sc-Ge); polycrystalline silicon, (pc-Si) and polycrystalline germanium, (pc-Ge); amorphous, hydrogenated germanium, (a-Ge:H) and; amorphous hydrogenated silicon, (a-Si:H). FIG. 3C is a plot of the absorption co-efficient vs. optical energy of various semiconductors, namely single crystal Silicon (Si) 307, single crystal Germanium (Ge) 308 and an exemplary Rare-earth Oxide (RE-Ox) 306. The absorption co-efficient of Ge extends to the far infrared; note, the rare-earth oxide semiconductor is substantially transparent to solar radiation.

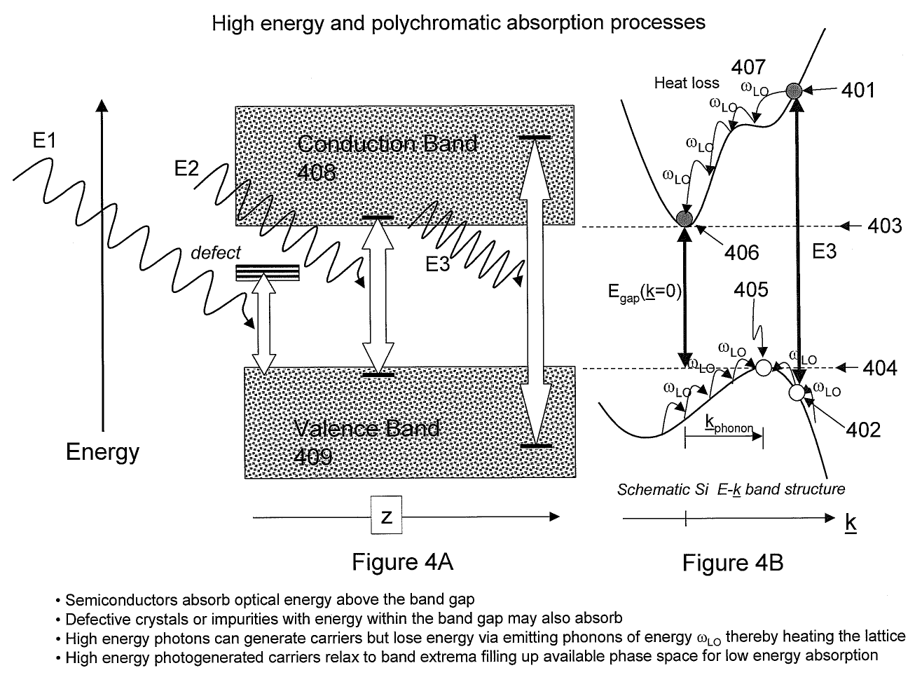

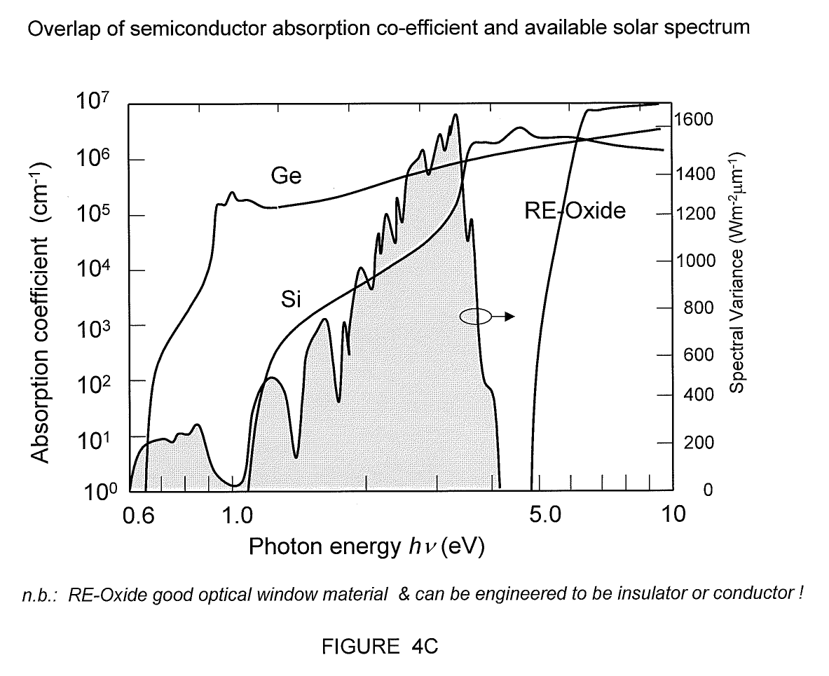

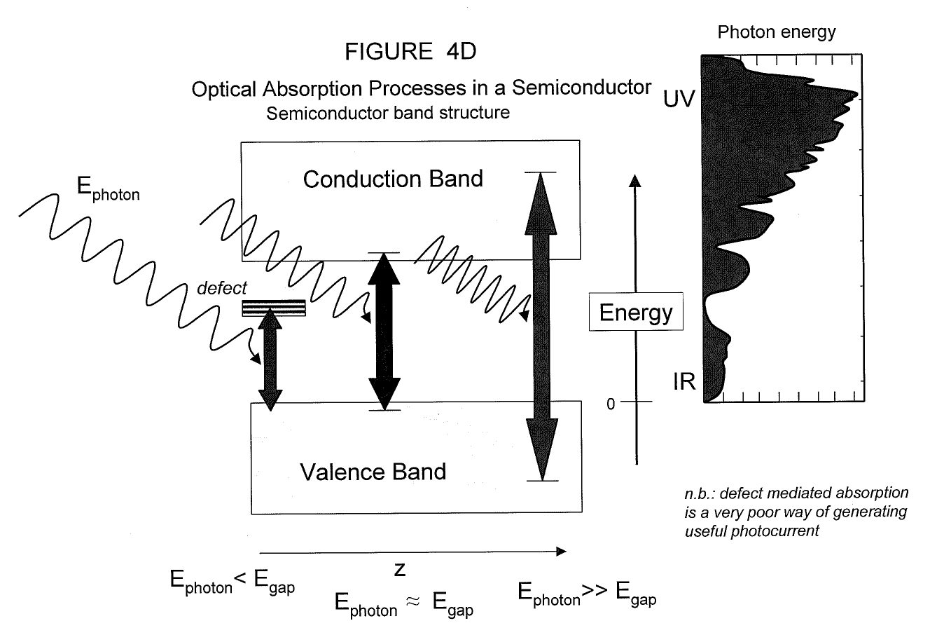

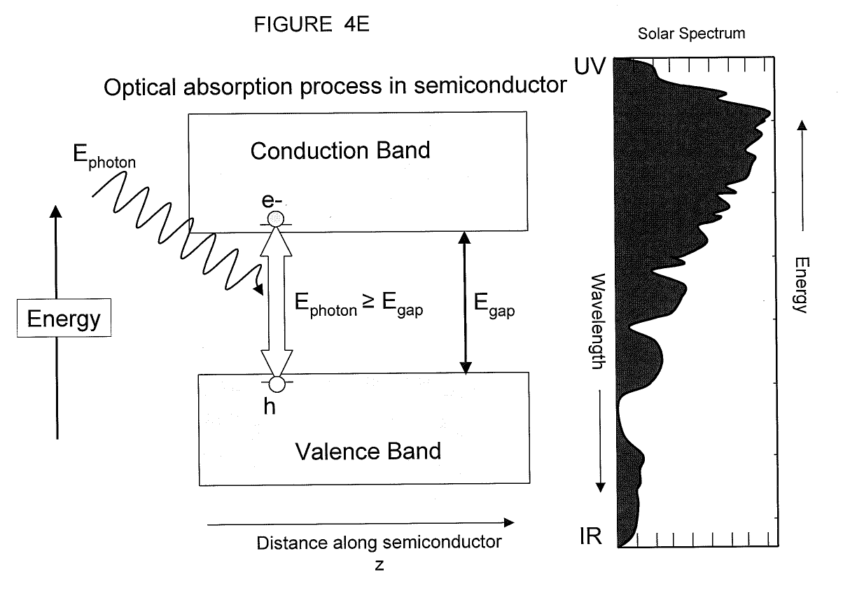

FIGS. 4A, 4B, 4C and 4D present overviews of the optical absorption process in a semiconductor. An incident photon with energy Eₚₕₒₜₒₙ incident upon a semiconductor surface will be transmitted through the material if Eₚₕₒₜₒₙ is less than the electronic band gap E_{gap} of the semiconductor, as shown in FIG. 4A. Conversely, photons of energy coincident or slightly higher energy than E_{gap} 406 will be absorbed. The band gap energy is defined as the energy difference between the lowest lying energy states of the conduction band 409 and the highest lying energy states of the valence band 410, and is determined by the composition and crystal structure of the semiconductor. As shown in FIG. 4B, an absorbed photon of energy co-incident with the band gap 406 simultaneously creates an electron in the conduction band 414 and a hole 415 in the valence band. FIG. 4D shows solar photons with high energy are represented as ultraviolet (UV) 430 and low energy photons are represented as infrared (IR) 431. Photon energies below E_{gap} are not absorbed and the material is transparent to this energy or equivalent wavelength. An exception to this rule is for the presence of optically active defect energy states 402 residing within the forbidden energy gap 405 of the semiconductor. Such isolated defects may participate efficiently in modifying the absorption co-efficient of a pure crystalline semiconductor, however, the resulting photogenerated charge carriers germane to the defects are typically poorly conducted to the conduction band.

FIG. 4C is a plot of the overlap of Si 425, Ge 424 and [RE]Ox 426 semiconductor absorption coefficients 421 and available solar spectrum 427. Rare-earth metal oxides may be created to exhibit the properties of optical transparency to the solar spectrum and have electrical properties of either insulating or conducting depending upon the stoichiometry or oxygen to rare-earth ratio of the [RE]Ox compound.

FIG. 4D is further overview of the optical absorption processes in a semiconductor wherein a defect energy state aligned with energy within the energy band gap of the semiconductor can participate in absorption process. The defect state may arise from structural imperfections of the crystal structure of the semiconductor or be introduced intentionally via the additions of impurity atoms into the crystal structure of the host semiconductor. Localized structural or impurity defect mediated absorption is typically not efficient in the generation of mobile charge carriers such as electrons and holes suitable for external photocurrent extraction.

Impurity atom doping of bulk semiconductors is also possible, wherein an electrical defect level is created within the forbidden energy gap of the host semiconductor. The defect absorption can extend the optical absorption to longer wavelengths (i.e., smaller photon energy) but suffers the disadvantage of poor electrical transport of photogenerated e-h carriers. Therefore, defect type absorber generally exhibit poor optical to electrical conversion efficiency in an external circuit.

In theory, Si should be a very efficient solar cell material; however high energy photons degrade the conversion efficiency. FIG. 4A shows the schematic energy band structure of a general bulk single crystal semiconductor as a function of real space co-ordinate (left) and energy-momentum E-k band structure (right). The periodic array atoms of definite crystal symmetry in the crystal forms an extended band structure consisting of delocalized conduction and valence bands. An electron and hole is constrained to satisfy the E-k dispersion as shown. For silicon, high energy UV photons are efficiently absorbed (within 2 μm of the surface for 400 nm photons) creating energetic electron 416 and hole 417 pairs relative to the conduction band minimum and valence band maximum. These energetic carriers quickly thermalize by emitting lattice phonons of energy ω_{LO} 408 The UV photogenerated carriers therefore cannot easily participate in photocurrent generation in p-n junction devices.

To increase UV responsivity it is therefore essential to avoid dead layer formation on the surface. Dead layers are typically due to heavy dopant implantation and/or diffusion required for good ohmic contacts to Si. A method to circumvent dead layer region(s) is via the use of inversion layer diodes (ILDs). ILDs are constructed by creating a charge inversion layer at the interface between a dielectric material and semiconductor, for example SiO₂/Si interface. Alternatively, an inversion layer can generate a potential energy Schottky barrier via appropriate work function metal placed in contact with intrinsic Si. The UV response of ILDs is superior to vertical and/or planar p-n and/or p-i-n junction type photodiodes. Only small reverse bias is required to deplete the inversion layer region and is advantageous for improving responsivity via higher efficiency photogenerated carrier collection. Photovoltaic operation can be optimized via a built-in voltage generated by advantageous placement of a lightly doped shallow diffused and/or implanted junction formation close to the surface of the device. The UV responsivity at a particular wavelength λ can be improved by growing an SiO₂ or high dielectric constant layer (e.g., RE[Ox]) on the silicon surface with a thickness equal to m/λ(2*nₖ), where λ is the wavelength of light in the dielectric, nₖ is the refractive index of dielectric and m=1, 3, . . . is an odd integer. High quality SiO₂ has a large band gap Eg(SiO₂)˜9 eV, and does not absorb UV light. Depending on the growth and/or deposition technique used to form SiO₂, (e.g., PECVD or IBD) various amounts of hydrogen may be incorporated in the glass layer. The hydrogen may affect the transmission/absorption properties of the film. Conversely, SiO₂ and hydrogen are beneficial for surface passivation of the Si surface states and is a desirable property. Typically, SiO₂ is an optimal antireflection (AR) coating well as a passivation layer. The use of alternative transparent AR layers based on rare-earth oxides and the like are used in some embodiments of the present invention.

Typically, single junction (SJ) monochromatic solar cell efficiency ηₘₒₙₒ at wavelengths in the immediate vicinity of the semiconductor band gap is good; For Si, ηₘₒₙₒ is >10%. Conversely, polychromatic solar efficiency is ηₛₒₗₐᵣ is much less than ηₘₒₙₒ for conventional SJ solar devices. Optical filtering helps efficiency but discards a large portion of useful spectrum and adds to solar cell manufacturing cost. Using optical filtering techniques to narrow the incident optical energy spectrum therefore requires more incident power at specific wavelength to increase output electrical current. Optical filters using quarter- and half-wavelength dielectric multilayers are well known. The dielectric filters typically use at least two dissimilar refractive index materials, exhibiting high transparency at the desired wavelength range of operation.

Typically, wide band gap energy materials are optically transparent to the solar spectrum; examples are SiO₂, magnesium-oxide (MgO), calcium fluoride (CaF₂), magnesium fluoride (MgF₂), silicon-nitride (Si₃N₄), titanium-dioxide TiO₂, tantalum-pentoxide (Ta₂O₅) and the like are used. The preferential use of large refractive index contrast materials, namely, RE[Ox] and SiOx materials, are advantageous for broad band optical coatings, in particular suitable for ultraviolet applications. The band gap of RE[Ox] (E_{g}(RE[Ox])=5.8 eV) is substantially larger (˜1 eV greater) than silicon nitride E_{g}(SiNₓ)≦5.0 eV. Therefore, for solar cell applications the preferential use of RE[Ox] and SiOₓ is desirable for tailoring multilayer coating below 5.8 eV. In some embodiments x varies from greater than zero to ≦5.

The present invention further teaches a new class of wide band gap optical materials suitable for optical coating; specifically, the materials of rare-earth metal oxide (REOₓ), rare-earth metal oxynitride (REOₓN_{y}) and rare-earth metal oxy-phosphide (REOₓP_{y}) glasses and/or crystalline material and mixtures thereof; in some embodiments as many as three different rare-earths may be present; varying proportions of O, N and P may be present; and combinations of Si, Ge and Si—Ge mixtures may be present; a generalized formula is [Z]ᵤ[RE1]ᵥ[RE2]_{w}[RE3]ₓ[J1]_{y}[J2]_{z} wherein [RE] is chosen from a group comprising the lanthanide series; [Z] is chosen from a group comprising silicon, germanium and SiGe mixtures, [J1] and [J2] are chosen from a group comprising Carbon (C), Oxygen (O),

Nitrogen (N), and Phosphorus (P), and 0≦u, v, w, z≦5, and 0<x, y≦5. A rare-earth metal is chosen from the group commonly known in the periodic table of elements as the lanthanide series or Lanthanum (La), Cerium (Ce), Praseodymium (Pr), Neodymium (Nd),

Promethium (Pm), Samarium (Sm), Europium (Eu), Gadolinium (Gd), Terbium (Tb), Dysprosium (Dy), Holmium (Ho), Erbium (Er), Thulium (Tm), Ytterbium (Yb) and Luthium (Lu).

Complex multilayer constructions are possible to create interference filters with narrow and/or broadband transmission and/or AR characteristics. Less well known, is the use of one-dimensional photonic bandgap and principles of two-dimensionally layered dielectric stacks. Omni-directional reflectors are possible, with reflection property substantially independent of wavelength as a function of incident angle to the surface, similar to an ideal metal, but with negligible absorption. The present invention further teaches that such principles can be used to create omnidirectional transmitters to form broadband optical couplers to solar cell active regions.

High Throughput Thin Film Si Solar Devices

The present invention solves a long standing problem in thin film single crystal silicon solar cell manufacture. The aim of thin film sc-Si solar cell is twofold. Thin film sc-Si reduces the manufacturing cost via reducing the amount of high quality sc-Si consumed in solar cell and the use of cheaper substrates, such as glass, metal, polymer and/or flexible substrates. Generally, prior art approaches at generating thin films of sc-Si have been limited via mechanical sawing of bulk Si material and/or deposition of amorphous Si followed by complex recrystallization processes. Such prior art approaches have resulted in solar cell conversion efficiency approaching bulk sc-Si cells only via general class of process using essentially sawing techniques. That is, the bulk sc-Si substrate CZ manufacturing process produces the highest crystalline structure perfection and thus the highest efficiency solar cell. Sawing techniques are limited to sc-Si film thickness of the order of millimeters.

The present invention teaches that optimal thin film sc-Si solar cells require active layer film thickness L_{Si} in the range of about 0.1 μm≦L_{Si}≦250 μm. Single junction thin film devices as disclosed in this regime can attain maximum conversion efficiency approaching 25-32%.

Therefore, there is a need for a low cost, high throughput, large area manufacturing technique for producing thin films of high quality sc-Si. Furthermore, there is a need for a cost effective, high throughput, and large area manufacturing technique for producing thin films of high quality sc-Si disposed upon low cost substrates.

There is also a need for a cost effective, high throughput, and large area handling manufacturing technique for creating large numbers of selective area electrically doped Si regions for producing electrical function of the solar cell devices using the said thin films of high quality sc-Si disposed upon low cost substrates.

There is also a need for a cost effective, high throughput, and large area handling manufacturing technique for integrating and interconnecting large numbers of solar cell devices for producing high power modules using the said thin films of high quality sc-Si disposed upon low cost substrates. The present invention solves all the aforementioned needs via the use of planar processing method and large wafer handling technique.

Thin Film Layer Separation

Ion implantation is used to create preferential defect layer and/or multiple layers beneath the Si surface of a Si substrate in order to allow removal of a desired thickness of thin film Si in the range of about 0.1 μm≦L_{Si}≦250 μm. The defect layer of the instant invention is produced across the entire wafer to approximately the same depth and thickness. The said defect layer can then be induced to create a chemical and/or mechanical reaction so as to locally disrupt the otherwise perfect Si crystal structure. Mechanical fracture localized at the defect layer can separate the topmost sc-Si film from the bulk of the substrate. Prior art for thin film separation is found in U.S. Pat. No. 5,374,564, U.S. Pat. No. 6,372,609, U.S. Pat. No. 6,809,044 and U.S. Pat. No. 7,067,396. The instant invention distinguishes itself from the prior art by requiring the reaction of two species in the defect layer and subsequent volume expansion of the reacted compound to produce a fracture zone separating a thin film from its original substrate.

High energy ion implanters up to 5 MeV are presently used in CMOS processing to generate deep doped Si wells. An embodiment of the present invention utilizes large amounts of foreign atoms being placed in a specific depth range below the Si surface in order to exceed the solubility limit of the host Si crystal structure. The method of ion implantation typically produces a Gaussian depth concentration of the implanted species. The peak of the Gaussian depth L_{D}, is primarily controlled by the ion species and the beam energy of the ion. The CMOS industry routinely implants silicon, germanium, oxygen, hydrogen, deuterium, helium and dopant species such as As, P, B and Sb. Various energy regimes are used to create shallow, medium and deep implant profiles relative to the surface. Typically, CMOS processes do not exceed several microns in depth. The present invention teaches the use of extremely deep implantation profiles in the range of about 1 μm≦L_{D}≦250 μm to form removable thin films of sc-Si.

One embodiment of the present invention uses high energy ion implantation of hydrogen and/or helium and/or silicon and/or germanium and/or oxygen and/or nitrogen and/or carbon to imbed large concentration of foreign, or non-native, atoms below the surface to a specific depth of a high quality Si substrate. The use of hydrogen is well known to workers in the field as a means to generate buried layer cleaving plane disposed substantially parallel to the wafer surface [1-5]. The present invention further teaches the use of implantation of single ion species and/or sequential ion implant of different species.

Ion implantation of rare-gas species in many materials has been known for some time to result in blisters at or immediately below the material surface at fluences of 10¹⁶-10¹⁷ cm⁻². For example, Ar⁺ in Ge and/or Si, H⁺ in GaP and Si [9], He⁺ in metals such as, Mo, Nb, Ni and Al.

Prior art techniques for Si thin film separation from the remaining bulk substrate using this blistering effect have concentrated on injecting large external source concentrations of ions into the said substrate at the required depth. The substrate is initially deficient in the injected atom species. Upon implantation and thermal anneal sequence, the high concentration of introduced ions, typically hydrogen, form gaseous microbubbles in a predetermined region and results in layer separation. The present invention can also benefit from this method.

A further aspect of the present invention is the use of an improved method of ion implantation facilitated layer separation technique. Implantation of H ions into Si at doses of ˜5×10¹⁶ cm⁻² [10] are required to form uniform density of decorated defects and/or microbubbles in a buried defect layer. The microbubbles can be made to coalesce into larger structures via externally applied thermal energy. The gaseous hydrogen builds pressure in the defect layer eventually splitting the thin layer from the reaming bulk substrate. A critical step for uniform fracture of large diameter Si substrates requires the defect plane to be substantially aligned to a crystallographic plane to serve as a cleaving plane.

Thin Film Separation Using Helium in Si

The use of helium ion implantation to generate a buried defect plane beneath the Si surface can also be used in the present invention. The heavier atomic mass of He relative to H requires approximately twice as much implant energy for He to penetrate the Si surface to the same depth. Sequential implantation of H and He ion implants may also be used, with the latter providing a means to potentially reduce the total dose required.

While other species such as rare-gases, carbon, nitrogen and fluorine may also result in the same bubble and split process, the energy requirements on the ion implanter are high for the depths proposed for today's SJ thin film sc-Si solar cell devices; devices with higher efficiency and thinner films may be constructed using the disclosed technique however.

Thin Film Separation Using Hydrogen and Oxygen in Single Crystal CZ Si

The growth of single crystal Si from high purity polysilicon (polySi) is germane to wafer production. Two techniques are typically used: (i) crystal pulling (or Czochralski, CZ) method [8]; and (ii) zone-melting (or float-zone, FZ) method [7]. Large area Si substrates (≧300 mm diam.) are typically grown using the CZ method, in which a single crystal is grown by pulling from a molten region of Si. The molten region of Si is contained, (and heat energy supplied from by an external source), using a high purity quartz or vitreous silica (SiO₂) crucible. A crucible is filled with polySi pieces and heated just past the melting point of Si. The diameter of the quartz crucible limits the size of the single crystal boule pulled from the molten Si source and thus determines the upper limit on wafer diameter. Prior art has determined the highest quality Si boule is via the use of high purity quartz in preference to all other known crucible materials capable of containing molten Si. A major limiting factor for choice of crucible materials is the fact that Si forms an alloys readily with all refractory metals and/or commercially available ceramics, well below the melting point of Si, rendering alternative crucible materials useless. The poisoning of the Si boule by the crucible material is a key aspect determining the final quality and application of the Si product. Single crystal Si is therefore grown by physically pulling from the melt contained in the quartz crucible, with the pulling rate determined in part by the melt temperature. The surface of the quart crucible in contact with the molten Si is consumed over time as a result of the reaction SiO₂+Si→2SiO, and the quartz is said to devitrify. This reaction enriches the Si melt and pulled Si crystal with oxygen atoms. A portion of the oxygen atoms evaporate from the melt surface as volatile silicon monoxide (SiO), and the remaining oxygen atoms become incorporated at the melt-crystal interface and thus into the growing Si crystal boule. These incorporated oxygen atoms determine the electrical, chemical and strength properties of the Si crystal. Historically, oxygen contamination was viewed as a problem and it was determined by prior art that the oxygen atoms were preferentially incorporated at interstitial lattice sites within the Si crystal. The concentration of incorporated oxygen into CZ Si crystals typically exceeds the solid solubility limit, and the supersaturated oxygen can precipitate during subsequent thermal annealing treatments. A key step forward in CZ Si development and therefore CMOS performance, was the observation that the interior defects produced by the oxygen precipitation produce an effective method to suppress epitaxial stacking faults in CZ crystals. Furthermore, the impurity oxygen concentration in CZ Si was shown to advantageously act as an internal gettering agent, and is widely used presently in high performance CMOS industry. The effectiveness of the internal gettering action of oxygen is determined by the initial oxygen concentration and anneal process. In addition to the beneficial effect of oxygen containing CZ Si it has been shown to be advantageous in supersaturated regime rather than oxygen lean regime. Prior art has demonstrated that FZ Si is inferior in mechanical strength compared to oxygen containing CZ Si. Therefore, the oxygen concentration in CZ Si affects: (i) internal defects produced by oxygen precipitation, (ii) mechanical strength, and (iii) the presence of oxygen donors.

The present invention exploits the use of oxygen containing CZ Si wafer for the direct application to the present invention for the purpose thin film cleaving and separation method. The control of oxygen concentration in CZ Si is of paramount importance for application to CMOS ULSICs. The process control, lifetime and purity control of the quartz crucibles is a major component in the manufacture of large diameter Si substrates suitable for CMOS manufacture. The Si wafer becomes the active layer of the field-effect-transistors (FETs) and is the most critical component in the entire front-end-of-line (FEOL) process. The oxygen concentration in CZ Si can be classified into low, medium and high concentration [O]_{CZ} ranges. For CMOS applications, the medium range is characterized by [O]_{CZ} in the 14-17 ppma range [6]. The high and low concentrations are therefore relative to the medium range. For the present invention a preferred CZ Si medium [O]_{CZ} range is given as about 1×10¹⁷ cm⁻³≦[O]_{CZ}≦1×10¹⁸ cm⁻³ in the Si crystal; alternative embodiments may be about 2×10¹⁶ cm⁻³≦[O]_{CZ}≦1×10¹⁹ atoms/cm³.

Therefore, the present invention teaches, in some embodiments, at least a three step process wherein: (i) a Si substrate is chosen in preference from oxygen containing CZ Si; (ii) a wafer is implanted by bombardment of high energy ions, in preference hydrogen (H⁺) to form hydrogen containing layer spatially separated from the Si surface and residing a predetermined depth from the surface with finite thickness. The hydrogen containing layer substantially uniform in extent and substantially parallel to plane of the wafer surface; (iii) subjecting at least one of a frontside and/or backside of a CZ Si wafer containing the as-implanted ions to heat treatment in suitable ambient gas so as to promote reaction between hydrogen and oxygen species in the immediate vicinity of the implanted layer; alternatively other combinations of implantable ions are used.

A wafer comprising regions of associated hydrogen and oxygen and/or bubbles and/or steam generated wherein reactants act so as to cleave the desired topmost CZ Si film free from the remaining portion of the substrate. The prime advantage of the above film separation method in preference to the previously described prior art techniques is the significant reduction of hydrogen dose required for film splitting and separation. This directly translates into shorter and lower cost H⁺-implanter beam times.

An optional advantage is the steam as produced using the above process may also act so as to oxidize the Si atoms in the immediate neighborhood of the cleave, thereby forming native SiO₂ and/or releasing hydrogen. This may act as an optional means to passivate surface states at the cleaved Si surfaces.

An additional benefit of the above disclosed process is the use of the denuding action of oxygen during thermal treatment [6]. Oxygen is well known in CZ Si to form a denuded region under thermal treatment. Depending on the exposed surface ambient, either oxygen rich or deficient, the oxygen profile near the exposed Si surface can be manipulated. Typically, oxygen precipitates can be driven into the interior of the Si crystal away from the surface. This is advantageous for the present invention wherein the oxygen precipitates can be driven toward the hydrogen containing layer defining the cleave plane. Note, different temperature selectivity of steam splitting and denuding can be used advantageously. The denuding effect can be incorporated in a separate thermal treatment independent of the cleaving process.

For application to SJ Si solar cell manufacture, the oxygen concentration is not critical. Heat treatment of the oxygen containing CZ Si above approximately 500° C. results in electrically inactive and/or neutral precipitates and does not disadvantage the performance of SJ solar cells. This allows cheaper CZ production methods to be utilized to form high quality single crystal Si. That is, single crystal Si substrates can be manufactured for solar cells but not to the same tight tolerances required in the CMOS industry.

The present invention, in some embodiments, utilizes supersaturated oxygen containing CZ Si (O:Si CZ) wafer for the creation of thin film separation method. The O:Si CZ wafer is implanted preferentially with hydrogen to a predetermined depth such as to produce a large hydrogen concentration layer—called the defect or fracture layer, with H+doses of about 10¹⁴≦H⁺≦10¹⁶ cm⁻². Upon thermal annealing the buried hydrogen and oxygen atoms preferentially combined to form water molecules and/or oxygen precipitates and/or hydrogenic clusters. The said water molecules and the like cluster to form nanometer and micrometer sized water and/or oxygen precipitate and/or hydrogenic cluster containing regions. Under the external influence of an appropriate heat treatment, anneal time and oxygen to hydrogen ratio (O:H) the water containing regions will expand in volume with temperature and form a predetermined fracture plane substantially defined by the hydrogen implant profile. The heated water containing regions form gaseous species at low temperature (below about 500° C.) and generally reduces the thermal budget required for defect layer fracture.

As medium to high oxygen incorporation is encouraged via the above described invention, other oxide crucible materials may potentially be used. U.S. patent application No. 60/454,280 filed March 2003, now Ser. No. 10/799,549, discloses how zirconium oxide (ZrO₂) can be used successfully for the containment of molten Si well in excess of the melting point of Si (1420° C.), up to approximately 1700° C. This high temperature operation allows the CZ method to pull the Si boule at a substantially faster rate, thereby increasing CZ Si boule production throughput and thus reducing Si wafer cost. This new method for thin film sc-Si layer production is disclosed and claimed in its entirety herein.

One alternate embodiment of the present invention is the use of alternative means for introducing various ions or atoms or molecules into a wafer; one example is an ion-exchange process for driving large amounts of foreign atoms from the surface to a predetermined fracture depth by imposing a voltage on the wafer in a solution of the desired ions; for instance an acidic solution for protons; or other solutions as one knowledgeable in the art is familiar. The defect or fracture layer so formed using the above methods, is then subjected to a predetermined reaction and/or stress and/or bending to initiate and/or complete the fracturing and/or cleave process. The fracturing process propagates across the wafer and separates the thin sc-Si film from the bulk portion of the CZ Si substrate. By combining the aforementioned film removal and cleaving process with layer transfer and bonding to a lower cost substrate, thin film silicon, optionally comprising devices, can be bonded to a cost-effective substrate, optionally comprising devices.

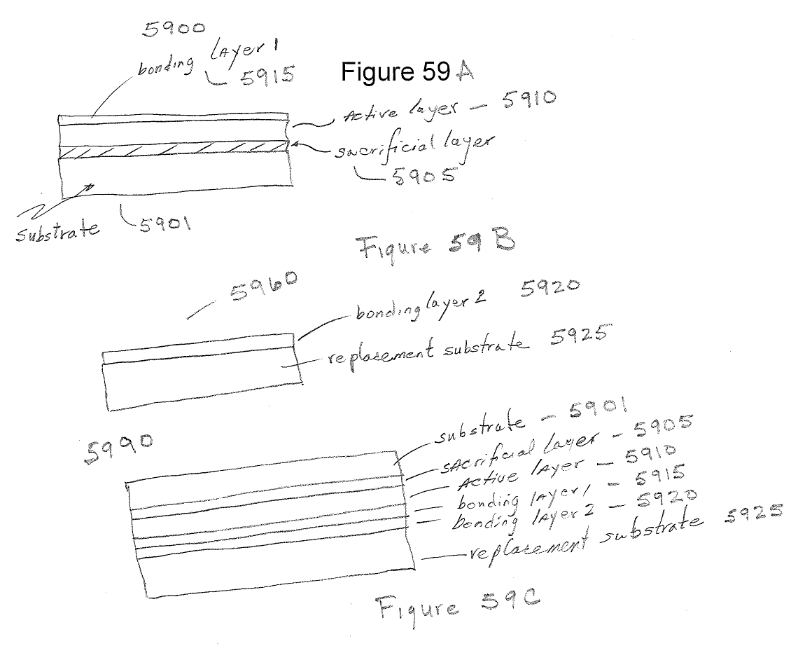

An alternate embodiment of the present invention is the use of a sacrificial layer upon which a single crystal silicon layer can be deposited in a preferred orientation, as illustrated in FIG. 59A, B and C. In one embodiment a rare-earth oxide, nitride or phosphide thin film, optionally single crystal, layer 5905 is deposited onto a substrate 5901, optionally single crystal as in FIG. 59A. A silicon or other semiconductor material 5910, optionally single crystal, is deposited upon the rare-earth layer. A key requirement is that the rare-earth layer be removable, either through liquid or vapor phase processes such that it does not affect the semiconductor layer 5910. Semiconductor layer 5910 may comprise one or more layers suitable for a photovoltaic device and/or other semiconductor device such as required for control circuitry, microprocessor function or other functions built with an integrated circuit. Active layer 5910 material comprises one or more of Group IV, Group III-V and Group II-VI members. Over layer 5910 is, optionally, one or more bonding layers 5915 comprising materials to facilitate bonding original structure 5900, in FIG. 59A, to replacement substrate structure 5960; these materials to facilitate bonding may comprise passivation layers to protect active layer 5910, metallization layers to interconnect devices on layer 5910, organic adhesives, low temperature melting glasses or metals. In FIG. 59B, replacement substrate 5925 comprises a variety of optional structures ranging from plastic, metal, glass, ceramic, semiconductor and wafers with active devices built therein. Bonding layer 2, 5920, comprises layers similar to 5915. In FIG. 59C, structure 5990 is a schematic after structure 5900 and 5960 have been bonded by bringing surface of layer 5915 into contact with surface of 5920 and undergoing a bonding process. A bonding process is determined by the choice of bonding layers; it may comprise thermal bonding, anodic bonding, fusion bonding, compression bonding or other bonding process known to one knowledgeable in the art. A key novelty of the process is that a single crystal rare-earth may be grown on substrate 5901 and then single crystal semiconductor, optionally silicon, may be grown on sacrificial layer 5905; alternately large grained, polycrystalline rare-earth may be grown and polycrystalline semiconductor, optionally silicon, grown on the rare-earth. The final step of the process, not shown, is to separate substrate 5901 from structure 5990 by removing sacrificial layer 5905 through a subtractive process such as etching or other means for dissolution.

Thin Film Single Crystal Silicon Layer Transfer onto Alternative Substrate for Solar Energy Conversion Devices

The present invention discloses alternative methods of single crystal Si layer transfer process onto alternative or replacement substrates to form a thin film article or device. Furthermore, the present invention discloses methods of single crystal Si layer transfer process onto alternative substrates and methods for incorporating electrical and opto-electrical conversion regions within a thin film article or device.

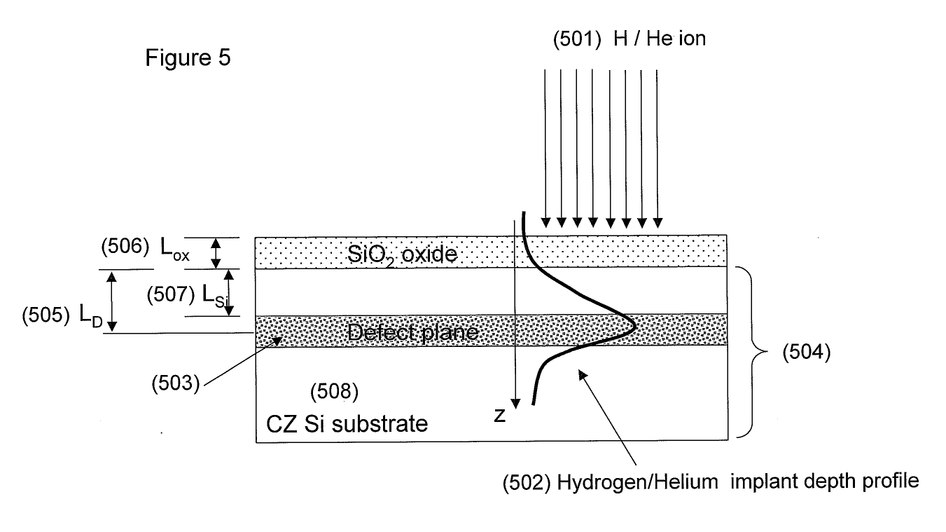

FIG. 5 describes the geometry used for ion implantation of foreign species 501 into CZ Si substrate 508 to form a Gaussian profile distribution volume 502 of ions in a Si crystal. The defect plane 503 substantially plane parallel to a Si crystal surface. The depth of the peak of the defect layer distribution is distance L_{D} 505 from a Si surface. An optional protective layer 506, optionally composed of SiO₂, is also shown.

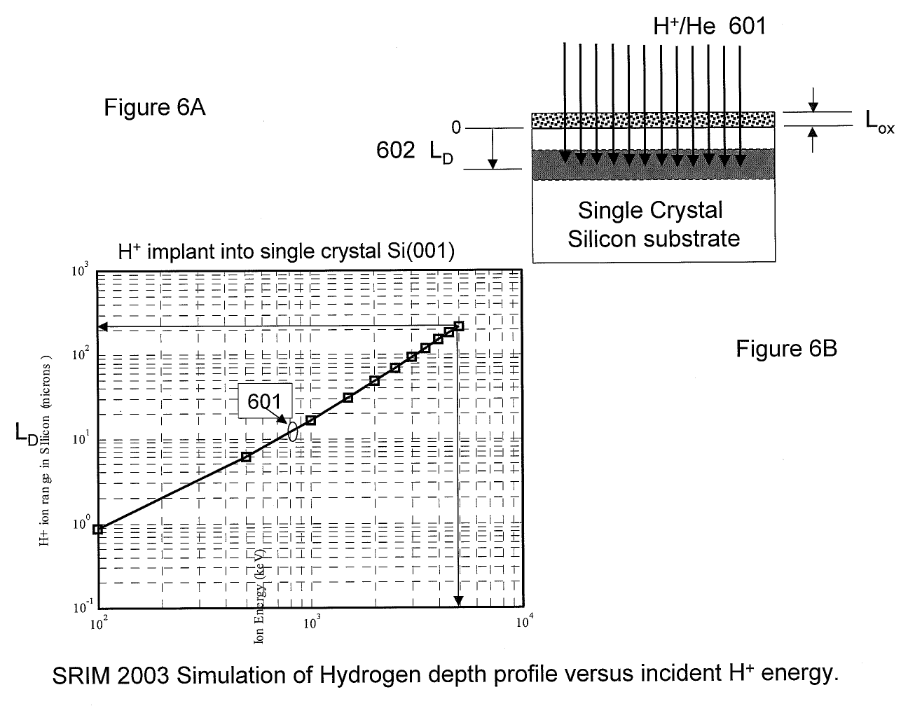

FIG. 6A shows calculated depth profiles for H+ ions 601 of FIG. 6B using various incident energy implants. Optionally, the ion species is chosen from hydrogen and/or helium. For the case of H+, the peak depth L_{D} versus implant energy range 100 keV≦E≦5 MeV is shown. Clearly, the defect layer depth beneath the surface can be placed in the range of about 1≦L_{D}<250 μm, depending on the energy used. The calculated results were performed using SRIM 2003 ion implant code, and Lₒₓ=200 Å SiO₂, and single crystal Si substrate.

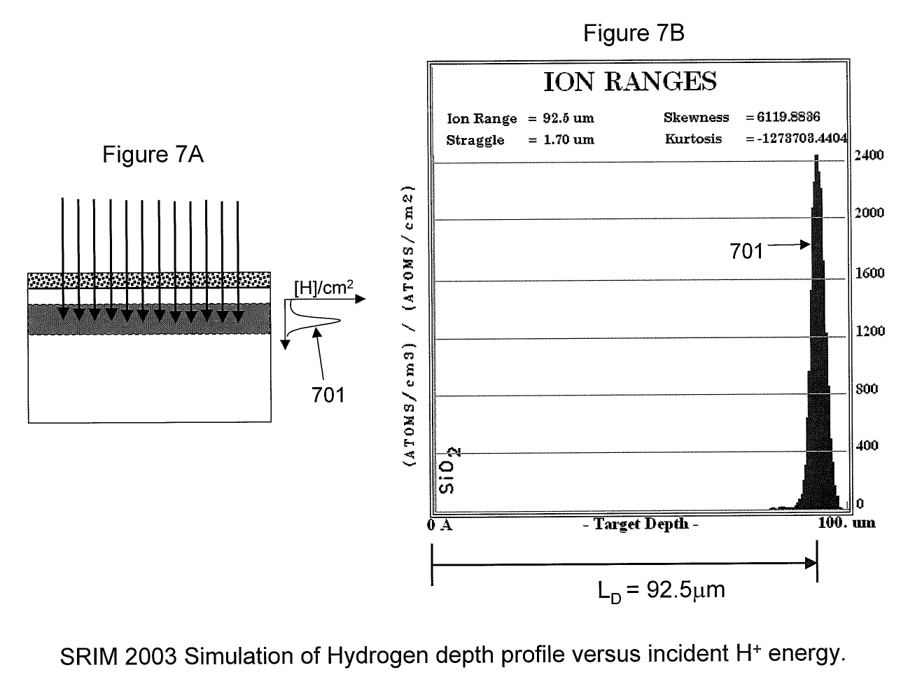

FIG. 7B shows the distribution of H+ ions 701 of FIG. 7A in the buried layer beneath the Si surface for the case of 3 MeV.

In an alternative embodiment oxygen rich single crystal Si substrate is implanted with H-ions and the selective interaction of the hydrogen and oxygen species is used to form defective region suitable for thin film Si layer transfer process.

### Example 1 Thin Film Solar Vertical Process

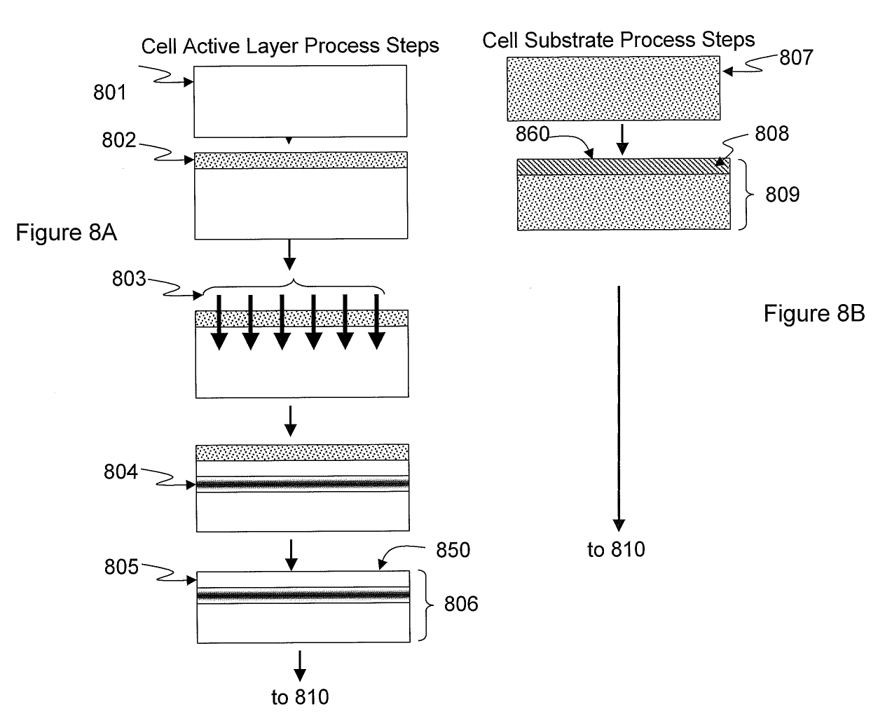

In one embodiment a disclosed process is used to fabricate a vertical type opto-electronic solar spectrum energy conversion device using thin film single crystal Si layer transfer method. FIGS. 8A and B shows the individual parallel process paths for fabrication of thin film solar cell article. A single crystal CZ Si substrate 801 and alternative substrate 807 are cleaned and prepared for processing. An protective layer 802, optionally SiO₂, is deposited or thermally grown on the CZ Si substrate 801. The CZ substrate is then implanted according to the method described in the present invention to form a buried defect layer 804. The layer 802 is removed via wet or dry etch or other means known to one knowledgeable in the art. The cleaned alternative substrate is then deposited with a uniform conductive layer 808, for example metal such as aluminum and/or rare-earth metal.

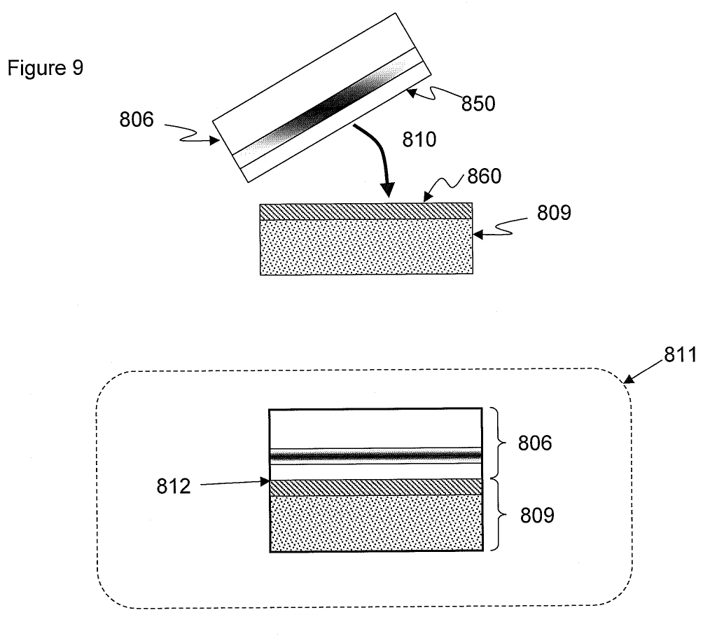

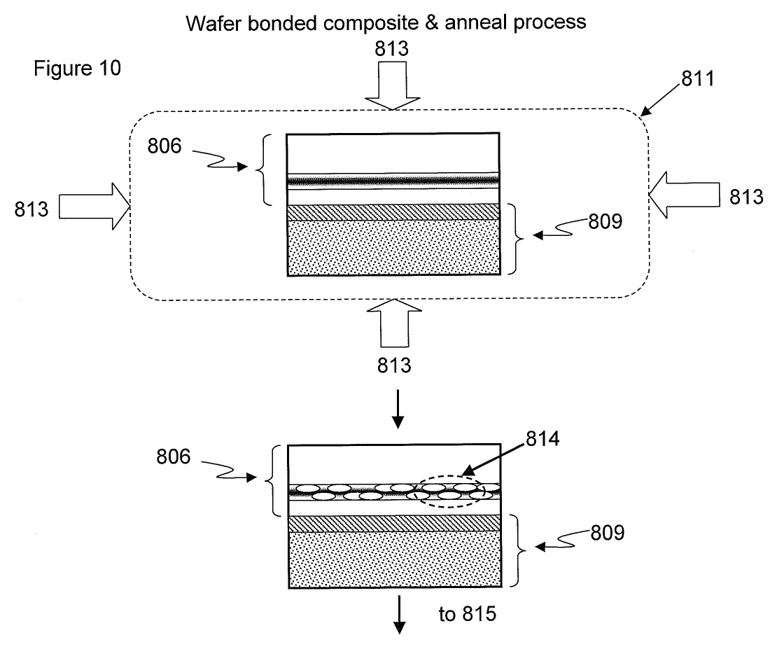

FIG. 9 shows how the alternative substrate with conductive layer 809 and implanted CZ Si substrate 806 are joined together 810 with opposing surfaces 850 and 860. The surfaces must be free from particulate contamination and can be vacuum joined, van der Waals attraction bonding, fusion bonded, anodically and the like bonded together. FIG. 10 shows how the compound multilayer article 811 is then subjected to thermal annealing sequence 813 to strengthen the bond between surfaces 850 and 860 and to initiate temperature dependent defect fracture 814 confined to a region advantageously aligned with CZ Si crystallographic axes. The thermal anneal sequence 813 generates fracture within said CZ Si crystal confined substantially to the plane defined by the defect plane. In one embodiment a thermal anneal step is done between 150° C. and 500° C.

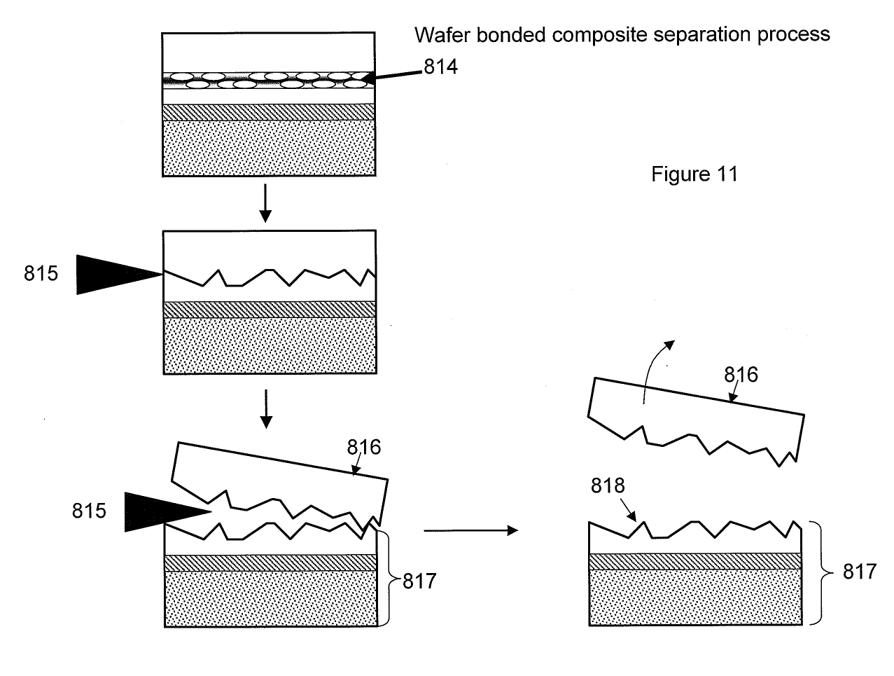

FIG. 11 next shows how, in one embodiment, with application of external mechanical stimulus 815 to at least one region of the edge of the compound article 811, the fracture propagates throughout the defect plane causing physical separation of remaining bulk CZ Si substrate 816 and thin film CZ Si coupled to alternative substrate 817. The resulting defect plane may exhibit rough surface 818 on both the exposed thin film CZ Si and the cleaved surface of the bulk substrate. The surface roughness of 818 may have surface features ranging from several nanometers to several micrometers depending on the O:H ration and implant energy. Typically, higher implant energies result in wider full width at half maximum of the Gaussian defect layer. For example, a 3 MeV H⁺ implant results in a straddle of ˜1 μm.

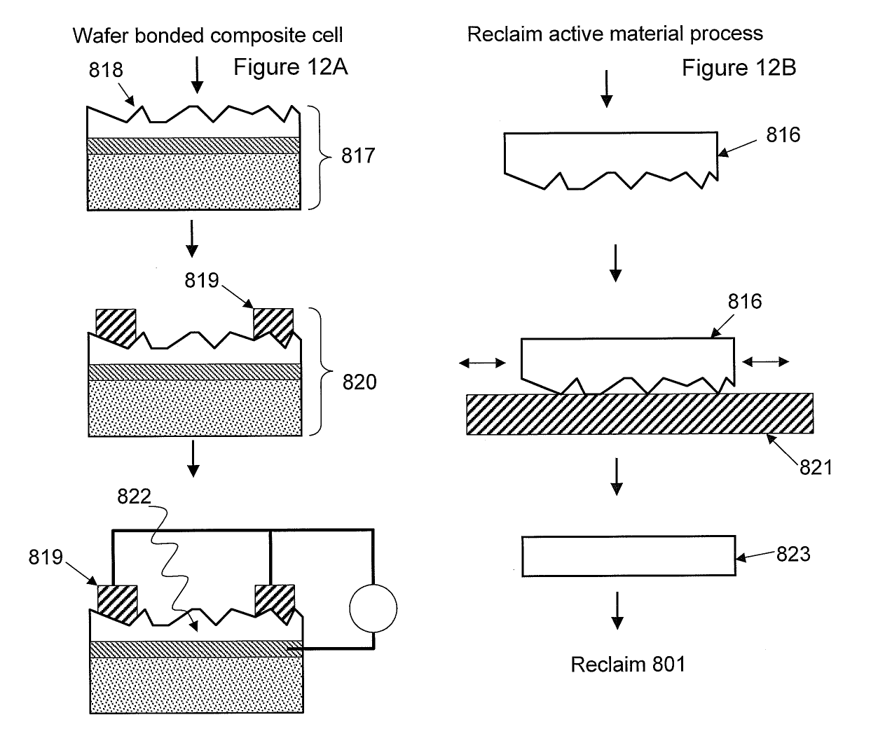

FIG. 12A shows how the wafer bonded thin film CZ Si and conductive buried contact on the alternative substrate 817 are then processed to form a vertical type solar cell device 820. Metal contacts 819 are disposed on the surface 818. Contacts 819 are preferred to be ohmic. For example, high performance solar cells may use rare-earth silicide (RE-Siₓ) and/or platinum silicide (Pt—Siₓ) ohmic contacts. The said silicide contact can be deposited as RE and/or Pt metal and then annealed to form the respective silicide by consuming and alloying with Si atoms within the film. The vertical solar cell functions by converting incident solar radiation 822 into photogenerated electronic charge carriers extracted through the external circuit shown.

Lastly, in FIG. 12B, removed bulk CZ Si substrate portion 816 can be reprocessed via chemical mechanical processing (CMP) 821 to form a substantially flat surface 823 resembling the initial CZ Si substrate. As the removed thin Si film has thickness significantly less than the total thickness of the starting CZ Si substrate 801, the reprocessed substrate 823 can be used for subsequent processing of another thin film removal 801.

In one embodiment a method for producing a thin film layer comprises providing a first substrate having a face surface and an oxygen concentration of at least 2×10¹⁶ atoms/cm³; introducing ions into the first substrate at the face surface, such that introduced ions are proximate oxygen atoms in a predetermined range from the face surface, wherein a thin film layer extends from the face surface to the mid-point of the introduced ions; optionally, bonding a replacement substrate to the face surface of the first substrate; processing the first substrate through a predetermined temperature cycle for combining the introduced ions and the oxygen; and, optionally, applying mechanical force to the thin layer, optionally, through the replacement substrate to fracture the thin film layer from the first substrate; wherein applying mechanical force to the thin film layer comprises applying a mechanical force to the second substrate selected from the group consisting of tensile force, shear force, bending forces, and combinations thereof. Optionally, oxygen ions may be introduced into the first substrate at the face surface, such that introduced ions are in a predetermined range from the face surface. Optionally, oxygen or other atoms may be incorporated at the time of crystal growth or later. Optionally, introduced ions may be hydrogen, helium, oxygen, nitrogen, carbon, fluorine or combinations thereof.

### Example 2 Thin Film Solar Planar Process

In one embodiment a disclosed process is used to fabricate a planar type opto-electronic solar spectrum energy conversion device using thin film single crystal Si layer transfer method. A key feature of this process is the extensive use of selective patterning of electrical contacts to form planar buried contact arrangement to a interface of the CZ Si thin film active layer.

This planar contact arrangement is suitable for optimized metal-semiconductor-metal (MSM) inter-digitated finger configurations. The shorter wavelengths (i.e., high energy) of the solar spectrum contains the majority of the solar spectrum fluence. Typically, high energy photons, particularly UV photons, are considered detrimental to the performance of single junction solar cells, particularly using Si (refer FIG. 4). The present invention solves this long standing problem by utilizing the wavelength selective nature of absorption of photons in the Si crystal. Silicon SJ solar cells, for example p-n junction diodes, typically can only convert optical energies with relatively high external photocurrent efficiency at or slightly above the fundamental indirect band edge ˜1.1 eV. In fact, this is a limitation of all semiconductors used in SJ configuration.

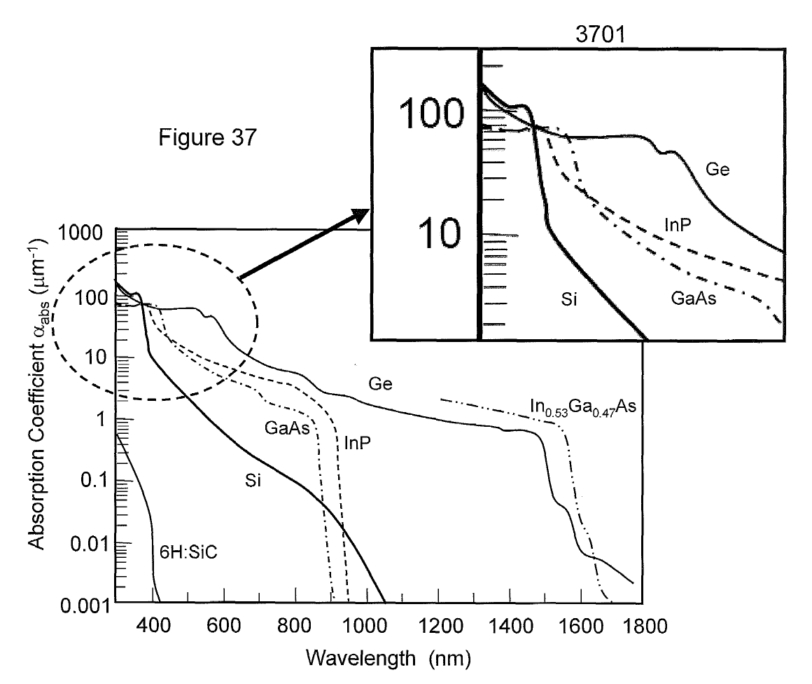

The absorption coefficient of single crystal Si is exceptionally high for UV photons (α_{abs}>100 μm⁻¹). Compared to the poor absorption near the Si indirect band gap, the UV behavior is superior to all the other commercially relevant semiconductors, as shown FIG. 37 region 3701. UV photons are almost completely absorbed within approximately 2 μm of the surface, forming e-h pairs. Unfortunately, the energetic electrons and holes couple strongly to the lattice phonons and dissipate their energy as heat. This loss mechanism can be reduced and the photocarriers extracted in thin film CZ Si solar devices, disclosed herein.

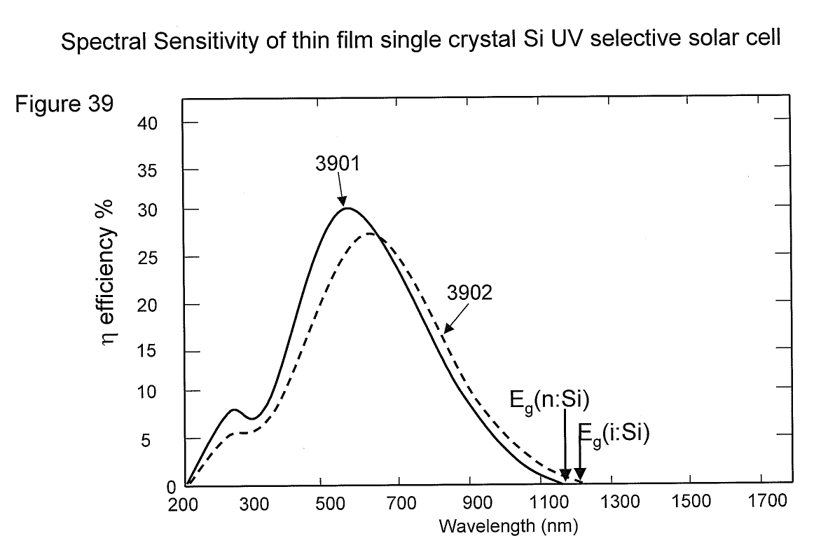

Utilizing thin film Si and the MSM configuration allows UV photons to be converted into useful electron and/or hole (e-h) photocarriers. The said photocreated e-h can be extracted into the external circuit before non-radiative recombination losses occur. The efficiency of SJ thin film CZ Si solar cells in the range 400-700 nm can therefore be optimized as shown in FIG. 39, and therefore utilize a higher energy portion of the solar spectrum.

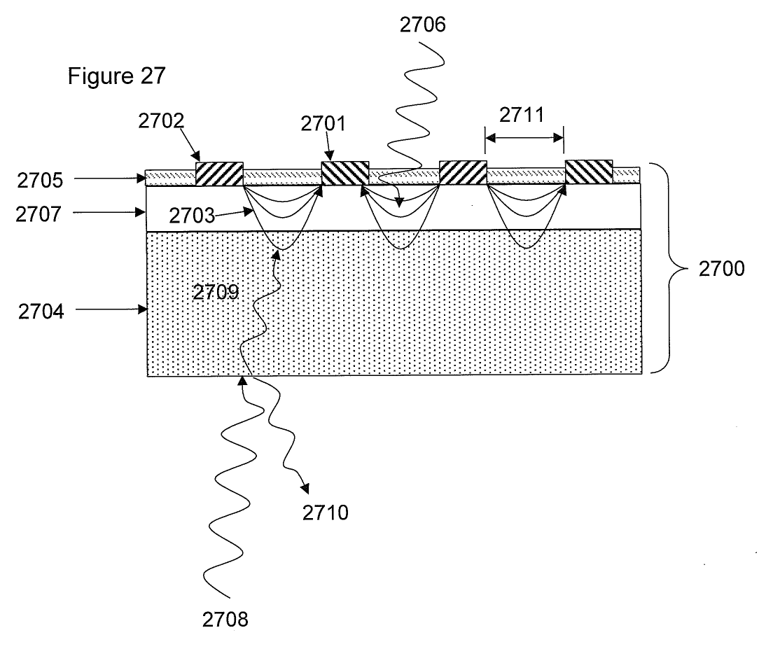

The electronic structures possible are discussed later and disclosed in FIGS. 27 to 41, inclusive.

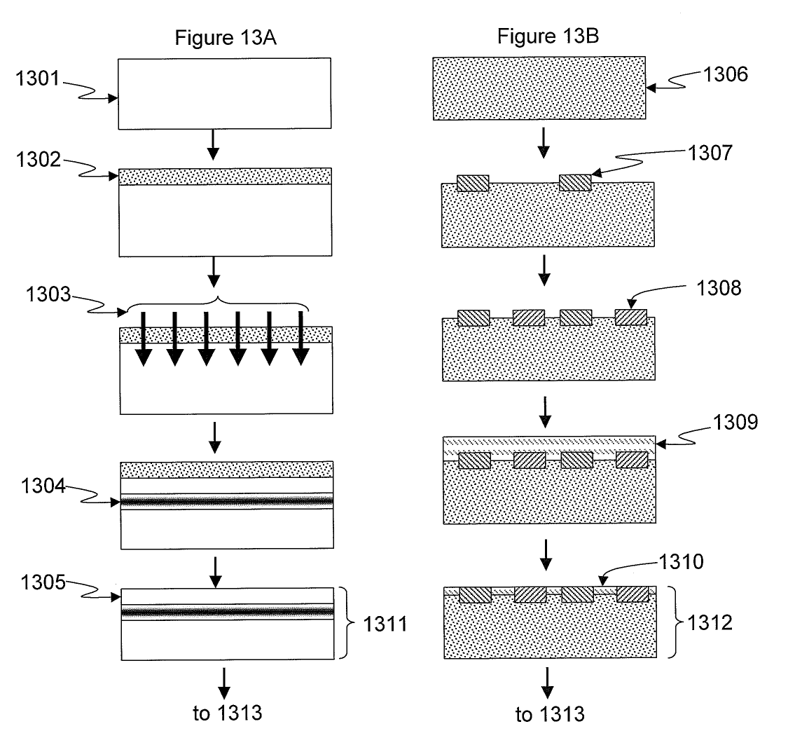

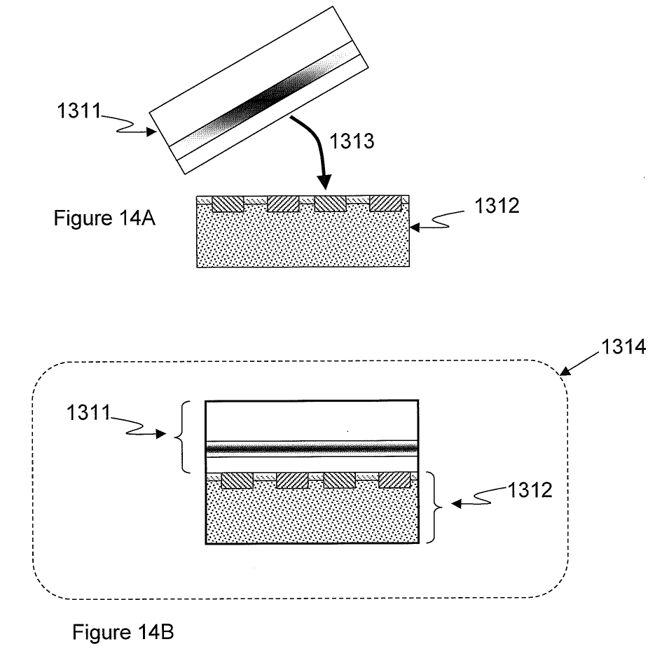

FIGS. 13A and B show the individual parallel process paths for fabrication of thin film solar cell article. A single crystal CZ Si substrate 1301 and alternative substrate 1306, in FIG. 13B, are cleaned and prepared for processing. An optional SiO₂ or dielectric or metal protective layer 1302 is deposited or thermally grown on the CZ Si substrate 1301. The CZ substrate is then implanted 1303 according to the method described in the present invention to form a buried defect layer 1304. The layer 1302 can be removed via wet or dry etch or evaporated. The cleaned alternative substrate 1306 is then deposited with a spatially patterned conductive layers 1307 and 1308, for example metals such as aluminum (Al) and/or rare-earth (RE) metal. If separate metals are used for 1307 and 1308 they can be deposited sequentially using an appropriate mask (not shown). After the contacts 1307 and 1308 are fabricated, an insulating layer 1309 is deposited as shown. The layer 1309 can be SiO₂, high-k and/or low-k dielectric film. The contacts 1307/1308 and insulating film 1309 can optionally be planarized via CMP to form flat surface 1310, free from particulate contamination. The surface 1310 of article 1312 is then used for wafer bonding in step 1313 in FIG. 14A.

FIG. 14A shows how the alternative substrate with conductive layers 1312 and implanted CZ Si substrate 1311 are joined together 1313 with opposing surfaces similar to 850 and 860. The surfaces must be free from particulate contamination and interfacial voids and can be vacuum joined, van der Waals and the like bonded together, as shown in FIG. 14B, to form article 1314.

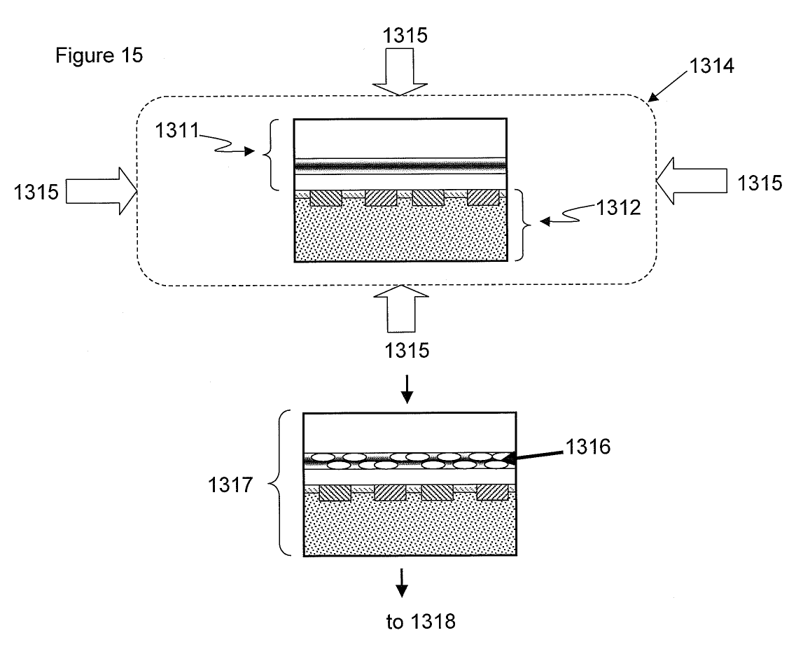

FIG. 15 shows how the compound multilayer article 1314 is then subjected to thermal annealing sequence 1315 to strengthen the bond between surfaces and to initiate temperature dependent defect fracture 1316 confined to a region advantageously aligned with CZ Si crystallographic axes. The thermal anneal sequence 1315 generates fracture within said CZ Si crystal confined substantially to the plane defined by the defect plane, 1316.

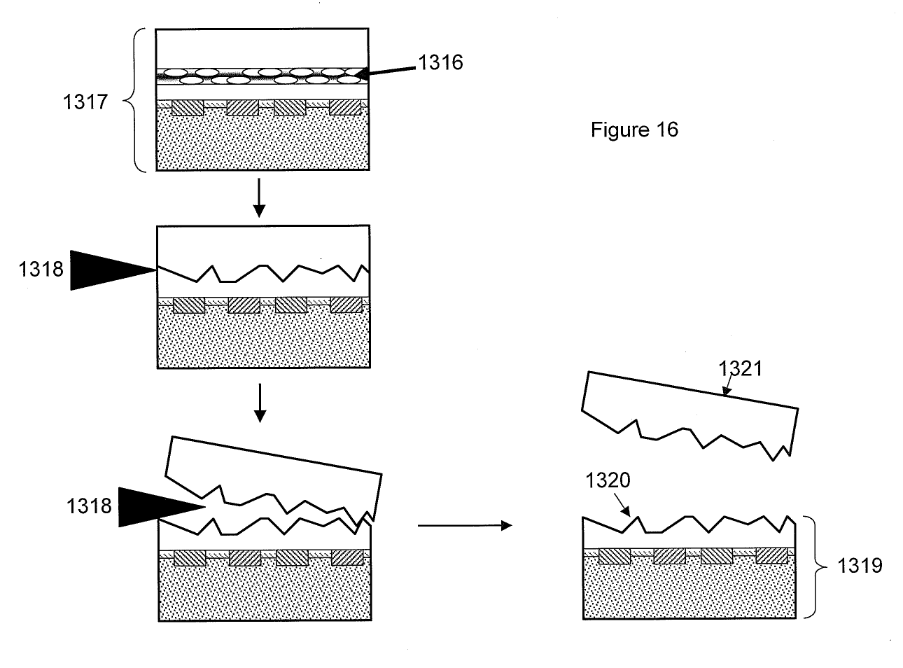

FIG. 16 next shows how, with application of external mechanical stimulus 1318 to at least one region of the edge of the compound article 1314, the fracture propagates throughout the defect plane causing physical separation of remaining bulk CZ Si substrate 1321 and thin film CZ Si 1320 coupled to alternative substrate 1319; alternative mechanical stimulus, such as bending, may be appropriate. The resulting defect plane may exhibit rough surface on both the exposed thin film CZ Si 1320 and the cleaved surface of the bulk substrate. The surface roughness of 1320 may have surface features ranging from several nanometers to several micrometers depending on the O:H ratio and implant energy. Typically, higher implant energies result in wider full width at half maximum of the Gaussian defect layer. For example, a 3 MeV H⁺ implant results in a straddle of ˜1 μm.

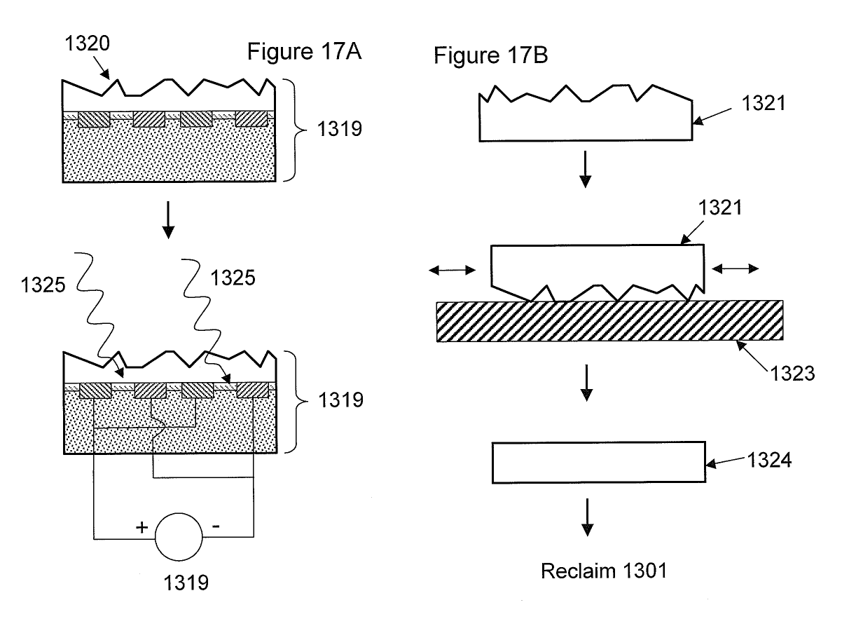

FIG. 17 shows how the wafer bonded thin film CZ Si and conductive buried contacts on the alternative substrate 1319 are then processed to form a planar type solar cell device 1319. Metal contacts 1307 and 1308 are disposed on the same buried surface 1310. Contacts 1307 and 1308 are optionally ohmic and/or Schottky type. For example, high performance solar cells may use rare-earth silicide (RE-Siₓ) and/or metal, such as platinum silicide (Pt—Siₓ), ohmic contacts. A silicide contact can be deposited as RE and/or Pt metal and then anneal to form the respective silicide by consuming and alloying with Si film. Alternatively, metals exhibiting Schottky barrier when in contact with Si can be also used.

The planar solar cell 1319 functions by converting incident solar radiation 1325 into photogenerated electronic charge carriers extracted through the external circuit shown via interconnected cells. Incident optical solar radiation can be coupled to the planar solar cell 1319 through the surface of cleaved thin film CZ Si layer. If alternative substrate 1306 is transparent to all or a portion of the solar spectrum, incident optical solar radiation can be coupled through 1306 into the thin film CZ Si layer.

Lastly, the removed bulk CZ Si substrate portion 1321 can be reprocessed via chemical mechanical processing (CMP) 1323 to form a substantially flat surface 1324 resembling the initial CZ Si substrate. As the removed thin Si film has thickness significantly less than the total thickness of the starting CZ Si substrate 1301, the reprocessed substrate 1324 can be used for subsequent processing of another thin film removal 1301.

### Example 3 Thin Film Solar Planar Process

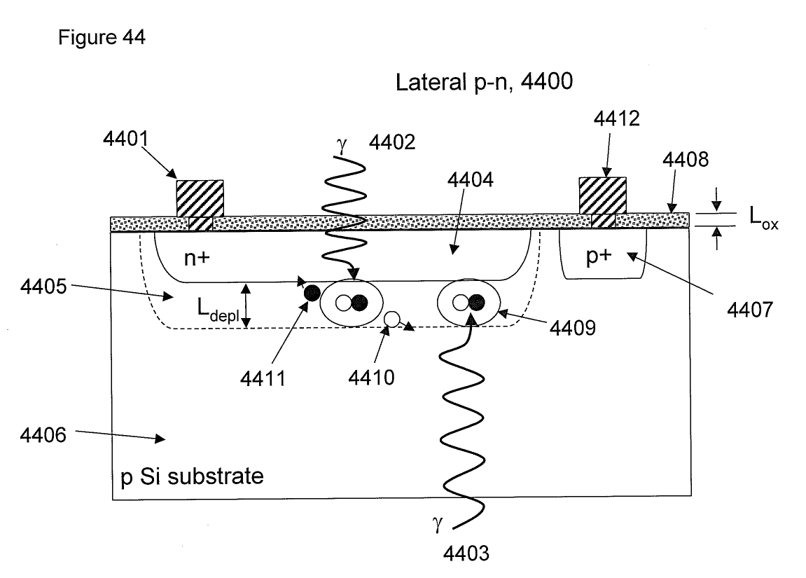

In one embodiment a disclosed process is used to fabricate a planar type opto-electronic solar spectrum energy conversion device using thin film single crystal Si layer transfer method. A key feature of this process is the extensive use of ion implantation to affect the conductivity type of selective regions within the CZ Si thin film active layer. The electronic structures possible are discussed later and disclosed in FIGS. 44 to 51, inclusive.

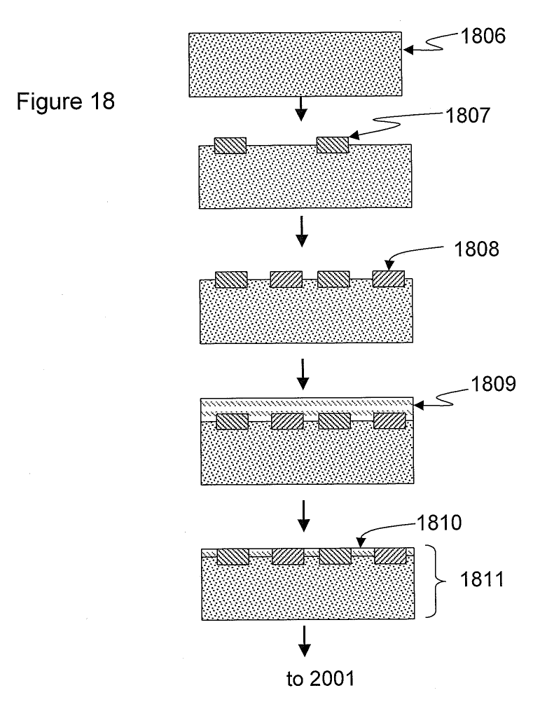

FIGS. 18 to 26 disclose the individual process paths for fabrication of thin film solar cell article and wafer scale solar energy conversion modules.

FIG. 18 shows initial processing steps of the alternative substrate containing patterned planar electrodes. Cleaned alternative substrate 1806 is deposited with spatially patterned conductive layers 1807 and 1808, for example metals such as aluminum (Al) and/or rare-earth (RE) metal. If separate metals are used for 1807 and 1808, they can be deposited sequentially using an appropriate mask (not shown). After the contacts/electrodes 1807 and 1808 are fabricated, an insulating layer 1809 is deposited, as shown. The layer 1809 can be SiO₂, high-k and/or low-k dielectric film. The contacts 1807/1808 and insulating film 1809 can optionally be planarized via CMP to form flat surface 1810, free from particulate contamination.

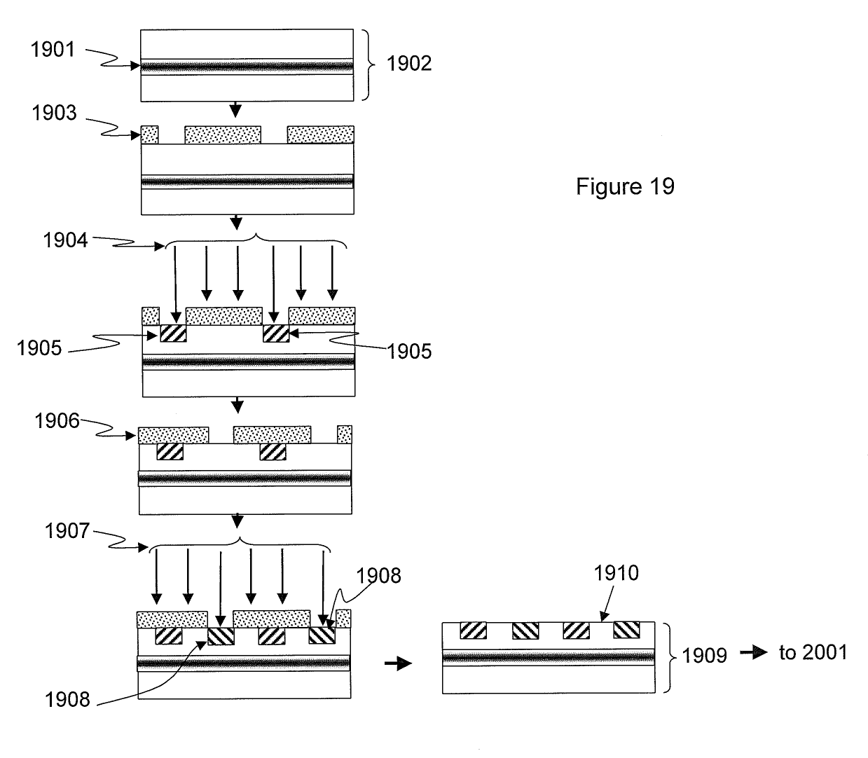

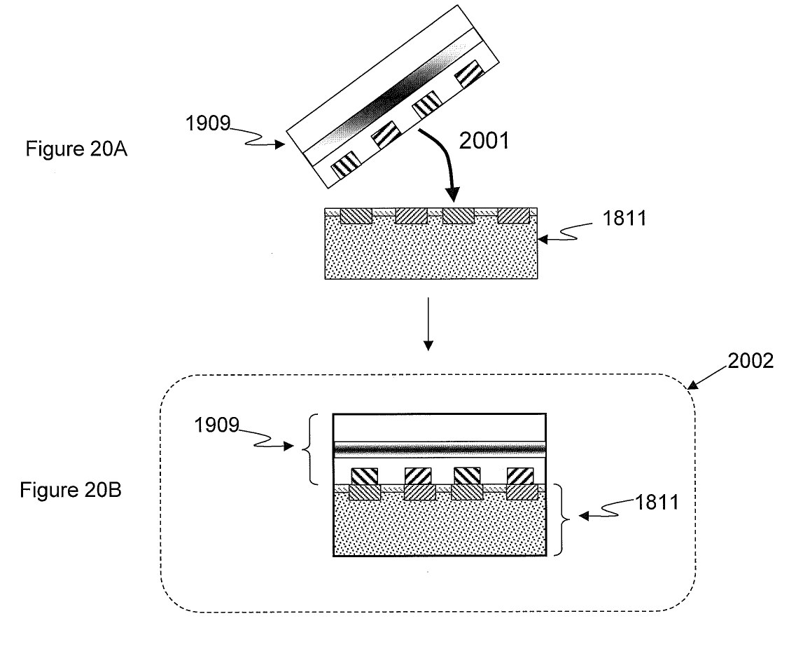

FIG. 19 shows a single crystal CZ Si substrate implanted with a defective layer 1901 separating a thin film CZ Si layer 1920 from the remaining bulk CZ Si substrate 1902. The article 1902 is fabricated using at least one of the methods disclosed in the present invention. CZ Si substrate 1902 and patterned alternative substrate 1811 are optionally cleaned and prepared for processing. A protective mask layer 1903 is deposited or thermally grown on 1909 to allow selective area ion implantation into the desired portions 1905 and 1908 of the thin film CZ Si layer. Ion implantation of impurity atoms, such as, Arsenic (As), Phosphorus (P), Boron (B), Carbon (C), Germanium (Ge) and the like are then implanted to alter the conductivity type of the Si region exposed by the mask 1903. The selective area implantation region 1905 defines either an n-type and/or p-type conductivity region. An optional, alternate conductivity type region can be performed by removing mask layer 1903 and depositing and patterning mask layer 1906. Again, impurity atoms may be implanted 1907 through mask 1906 to form selective area conductivity regions 1908. Next mask layer 1906 is removed and article 1909 is obtained. The surface 1910 is optionally cleaned and/or prepared for wafer bonding to surface 1810 as shown in step 2001 of FIG. 20.

FIG. 20A shows the wafer bonding of 1909 and 1811 to form article 2002, in FIG. 20B, containing defect/cleave layer, patterned electrodes and selective area implants in CZ Si thin film.

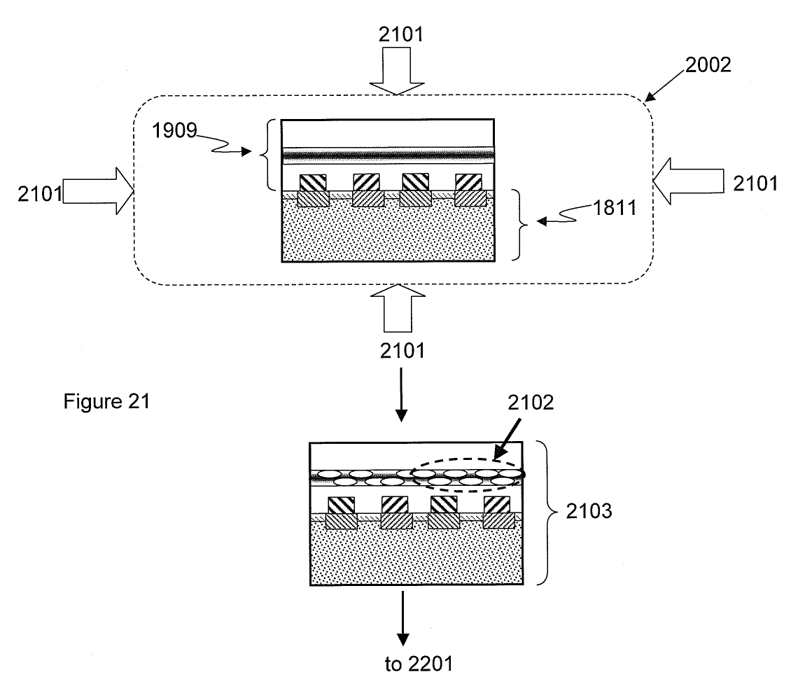

FIG. 21 shows the thermal annealing step 2101 according to the method described in the present invention to form a buried defect layer 2102 in completed multilayered structure 2103. Note, selective removal or release of the separation layer 1901 may also be used to release thin film active layer.

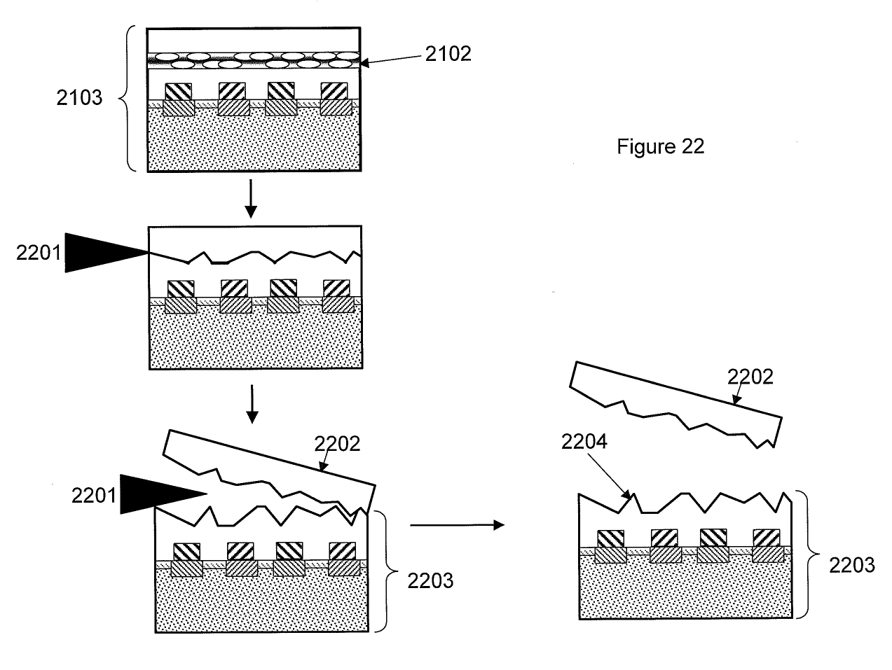

FIG. 22 shows how the structure 2102 may be cleaved using mechanical, or bending or fluid jet or high pressure gas 2201 to initiate fracture propagation along plane defined substantially by defect layer. Alternatively, gaseous species can be used to react with separation layer 1901 to alter structure and thus provide advantageous properties for thin film release. The defined thin film CZ Si layer and planar implant electronic device(s) 2203 are then separated from the bulk CZ Si substrate 2202 via the defective layer 2102. The structure 2203 has surface 2204 that can be made rough so as to allow advantageous coupling of broadband solar spectrum into the thin film CZ Si active layer. Alternatively, the roughness of 2204 may be small enough so as to be ineffectual for further processing. CMP can also be used to planarize 2204 for subsequent thin film depositions, such antireflection and/or filter coatings.

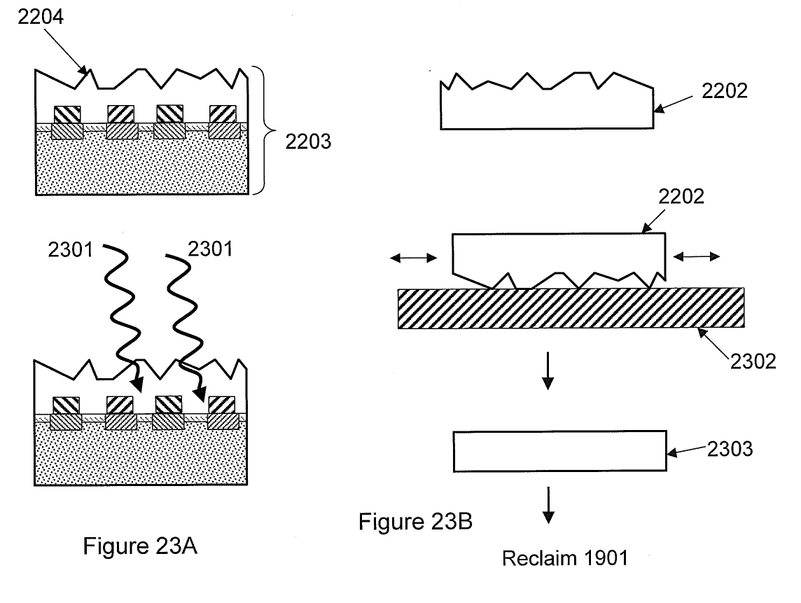

FIG. 23A shows the final schematic steps for formation of a planar implant defined solar conversion device with optical radiation 2301 coupled through surface 2204. The partitioned bulk CZ Si substrate 2202, in FIG. 23B, can then optionally be reprocessed using, for example CMP 2302, to planarize and thus allow recycle of the substrate 2303 acceptable for step 1901.

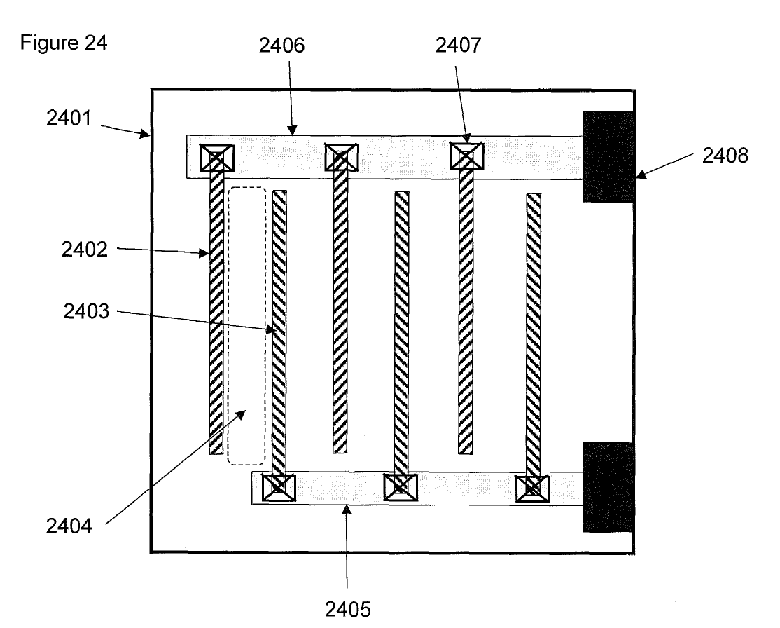

The unique capability of planar solar cell devices as disclosed in the present invention is shown in FIGS. 24 to 27.

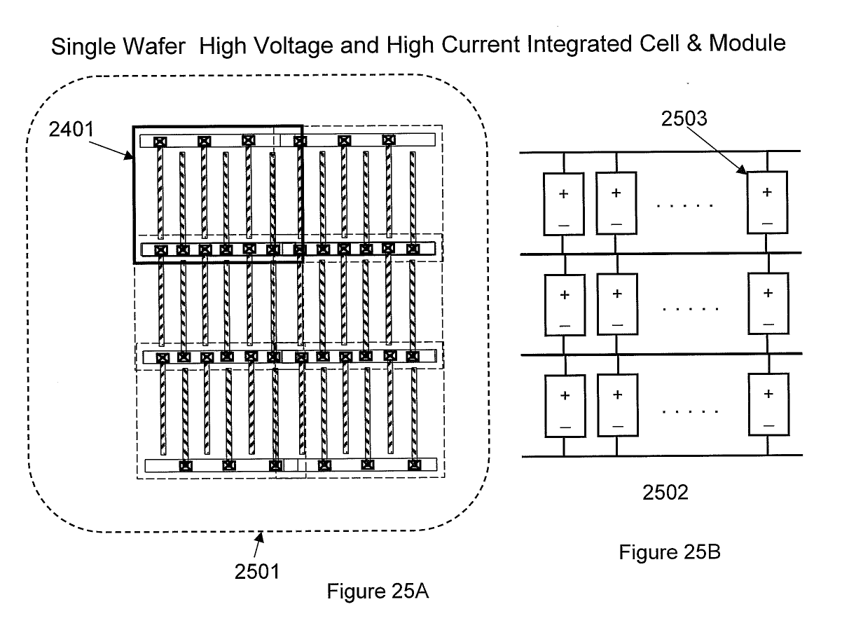

FIG. 24 shows a schematic top view of solar cell device 2401 implemented using, optional, interdigitated p-type 2402 and n-type 2403 regions to define selective area conductivity regions in the CZ Si thin film transferred to a patterned electrodes 2406 and 2405 of the alternative substrate. The electrical contacts between the thin film CZ Si implant regions and the alternative substrate electrodes are shown as 2407. The unit cell 2401 can be lithographically scaled to dimensions of the order of centimeters to nanometers using conventional Si processing equipment. The electrical equivalent circuit of unit cell 2401 is shown as 2503 in FIG. 25B.

FIG. 25A shows the large scale integration implementation of repeating unit cell 2401 into interconnected assemblies 2501. An alternative implementation shows unit solar cell 2401 fabricated in the form of interdigitated p-n junctions, repeated many times on a wafer. The alternate carrier type regions defined by implantation are separated by not intentionally doped bulk semiconductor comprising the thin film active layer. Multiple unit cells 2401 are connected electrically via bus bars 2405 and 2406 in parallel and series. The electrical equivalent circuit is shown as 2502.

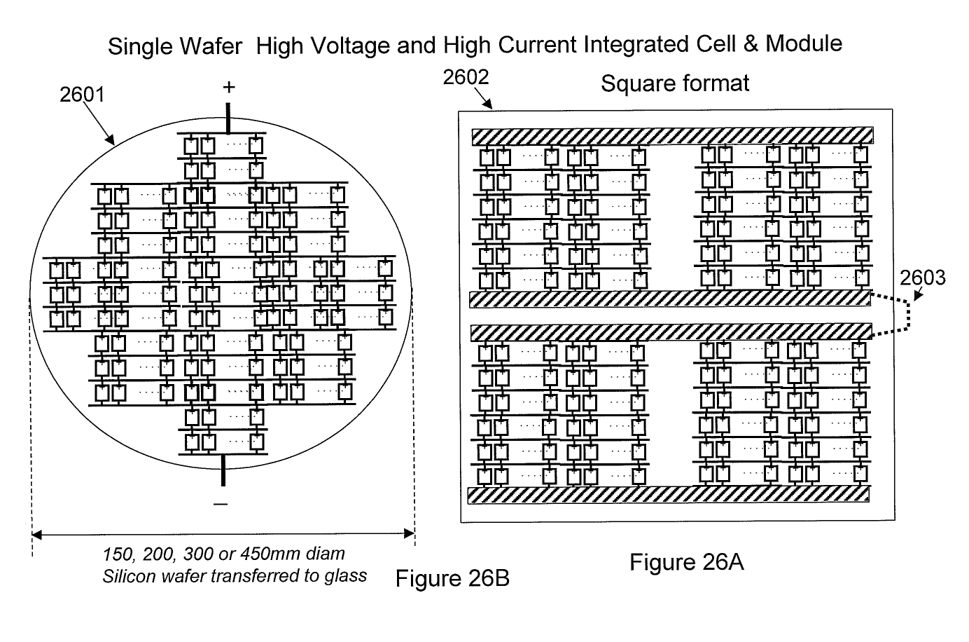

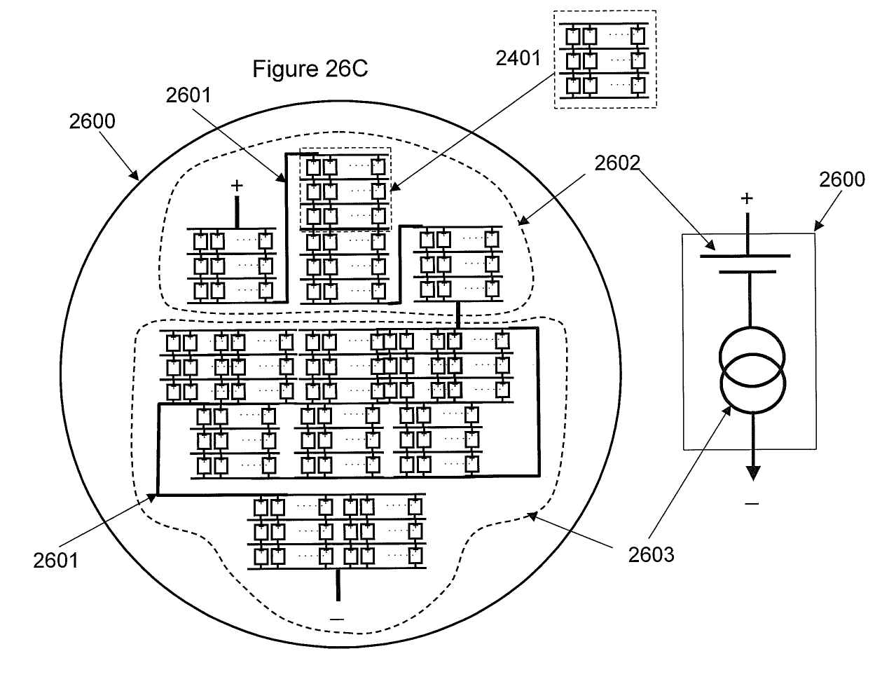

FIG. 26A shows utility of patterning large numbers of appropriately scaled unit cells, for example unit cell 2401, onto a large area wafer format 2601 and 2602.

FIGS. 26B and C disclose alternative embodiments of present invention for high performance thin film CZ Si solar module based on wafer scale manufacturing process disclosed herein. For example, unit cell 2401 is replicated in an advantageous fashion to allow high density packing of 2401 onto a large area wafer. The unit cells can be grouped advantageously to functional blocks of voltage source and current source. That is, the incident solar spectrum impinging the solar module defined by the wafer 2600, can be constructed to generate a photoinduced voltage source 2602 and current source 2603. The unit cell 2401 can be kept constant across the wafer or optimized unit cells can be implemented in advantageous regions across the wafer depending on the defining mask pattern. The cost incurred in altering 2401 is only in the mask, the processing costs will be identical. This is the power of planar CMOS style manufacture. The interconnections between unit cells 2601 on wafer 2600 are shown. The equivalent circuit of the thin film CZ Si solar module is also shown.

FIG. 27 to 36 disclose thin film CZ Si solar energy conversion structures used for coupling solar optical radiation into the Si and/or semiconductor active region. For example, simple metal-semiconductor-metal (MSM) and implant defined conductivity regions are used to implement the electrical functions according to the present invention. Various optical coupling layers are disclosed to optimize all or portion of the incident solar spectrum.

FIG. 27 schematically shows a simple form of the thin film device 2700. Electrodes 2701 and 2702 contact the thin film CZ Si 2707. The electrodes are spaced distance defined by 2711. Optical radiation 2706 or 2708 may couple the active region 2707 of the cell being incident on the electrode side of the device or through the substrate 2704 and directly into 2707. The fill factor is determined by the electrode width and the electrode spacing and impedes the coupling of 2706 into 2707. The electric field lines 2703 between the electrodes extend into the Si film and/or the alternative substrate 2704, as shown. Optical radiation 2708 however, suffers reflection loss 2710, leaving only portion 2709 of incident radiation 2708 to couple into the active region. By appropriate choice of alternative substrate 2704 thickness and refractive index, the reflection loss can be minimized.

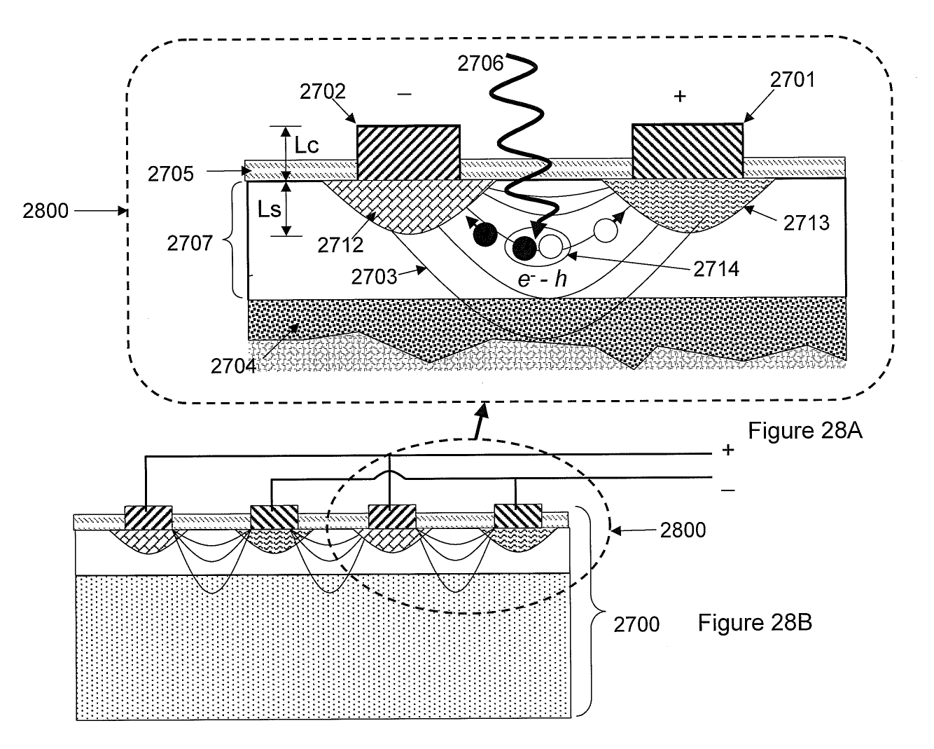

FIG. 28A shows in detail 2800 the optical to electronic conversion process of unit cell 2700. An incident photon 2706 creates an electron and/or hoe pair 2714. Example conductivity type implants and/or diffused metal and/or dopants are shown as regions 2712 and 2713. The separation of the photogenerated e-h pair is shown, with electrons and holes transport to opposite electrodes. UV photons are typically created close to the interface between protective and/or passivation oxide 2705 and the active layer 2707. FIG. 28B shows multiple portions of 2800. If the finger spacing is small enough and/or the electric field strength strong enough, the electron and hole are collected before non-radiative recombination process occurs.

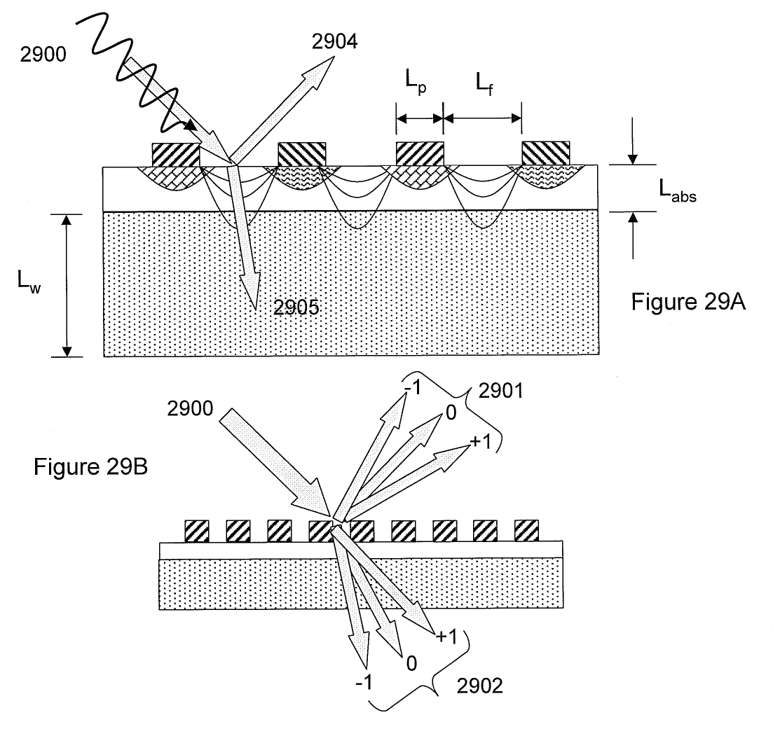

FIG. 29A shows the effect of small electrode width Lₚ, and separation L_{f} so as to form optical grating action. If the electrode dimensions are very large compared to the wavelength of incident radiation 2900 impinging on the active region will be reflected 2904 and transmitted 2905. The transmitted portion will be refracted into the active region. If the grating is comparable to the optical wavelength or multiple thereof, the incident radiation will diffract into diffractive orders 2901 and 2902. The diffractive effect occurs in a similar fashion for optical radiation impinging from beneath through an alternative substrate. The advantage in the later configuration, the light couples first into the active layer, and may reflect or diffract back from the electrode grating back into the active region. This effect enhances the optical coupling into the thin film active layer.

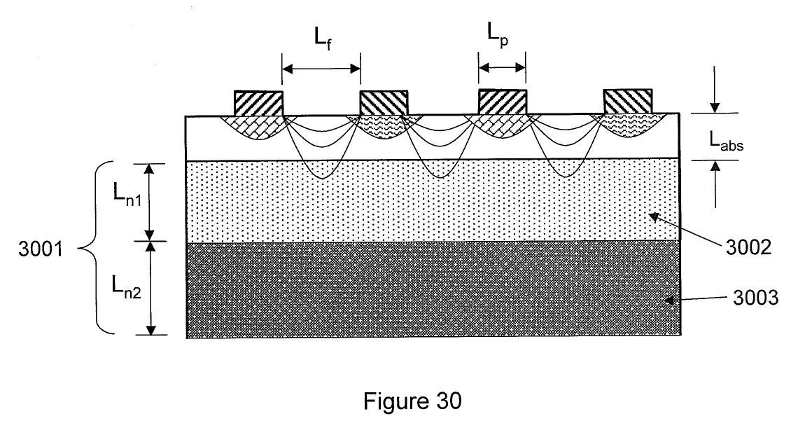

FIG. 30 show how the reflective losses of the device in FIG. 27 can be overcome by application of an anti-reflective (AR) coating 3003. If the alternative substrate is transparent to all or part of the solar spectrum, then the alternative substrate 3002 will form part of the AR system. Considering different refractive indices nᵢ for materials 3002 and 3003, the thickness of at least one of 3002 and/or 3003 can be chosen to be an odd or even multiple of quarter wavelength.

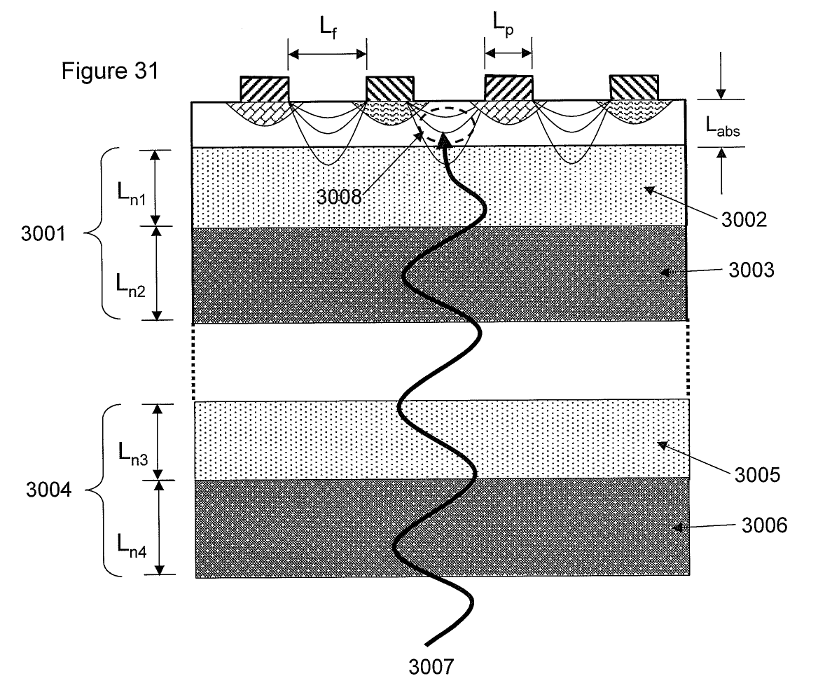

FIG. 31 shows how a multiple layer dielectric coating can be deposited on an alternative substrate so as to form an optical filter and/or broadband interference filter. The dielectric layer pairs 3001 and 3004 can be identical and/or chirped to form a distributed Bragg mirror or broad band coupler.

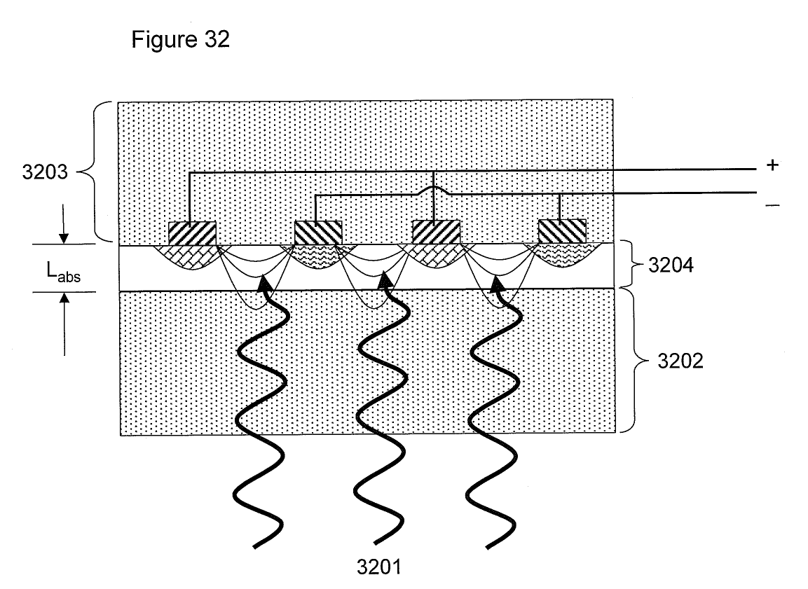

FIG. 32 shows how backside optical coupling 3201 through the alternative substrate 3202 can be used to couple into active layer 3204. The addition of dielectric layer 3203 can be used to advantageous couple optical radiation.

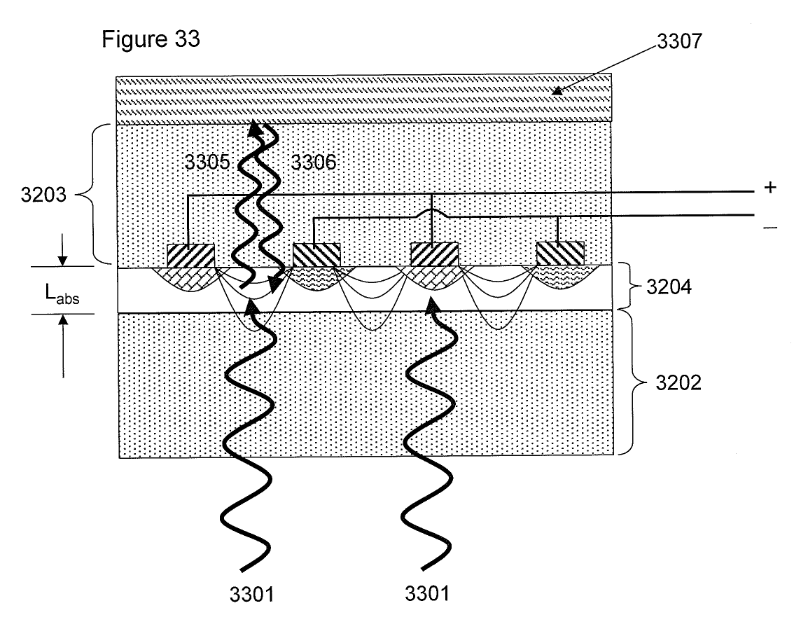

FIG. 33 shows how the device of FIG. 32 can be used for photon recycling 3305 and 3306 back into the active layer 3204. A high reflectivity layer 3307 (for example Aluminum) is deposited on the dielectric layer 3203 (for example SiO₂).

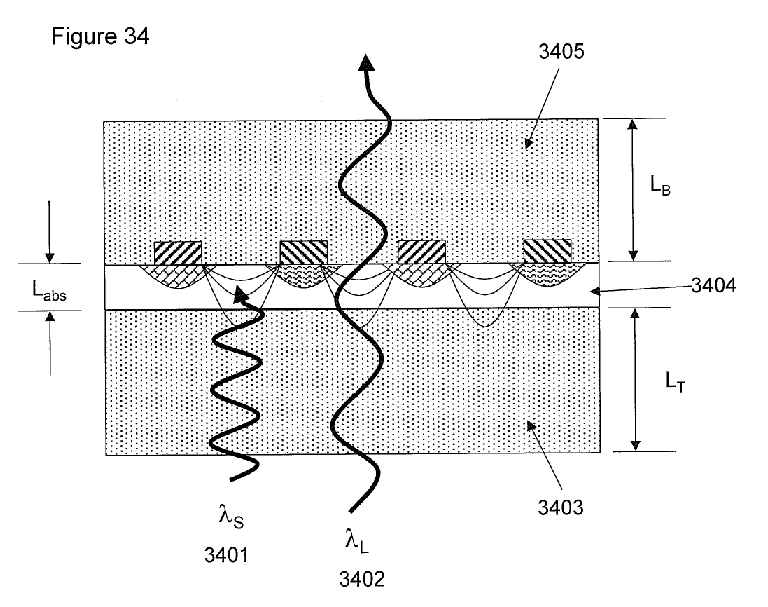

FIG. 34 shows how backside optical coupling can be used to affect short 3401 and long 3402 wavelengths into the active region 3404 by suitable choice of layer thicknesses 3405 and 3403.

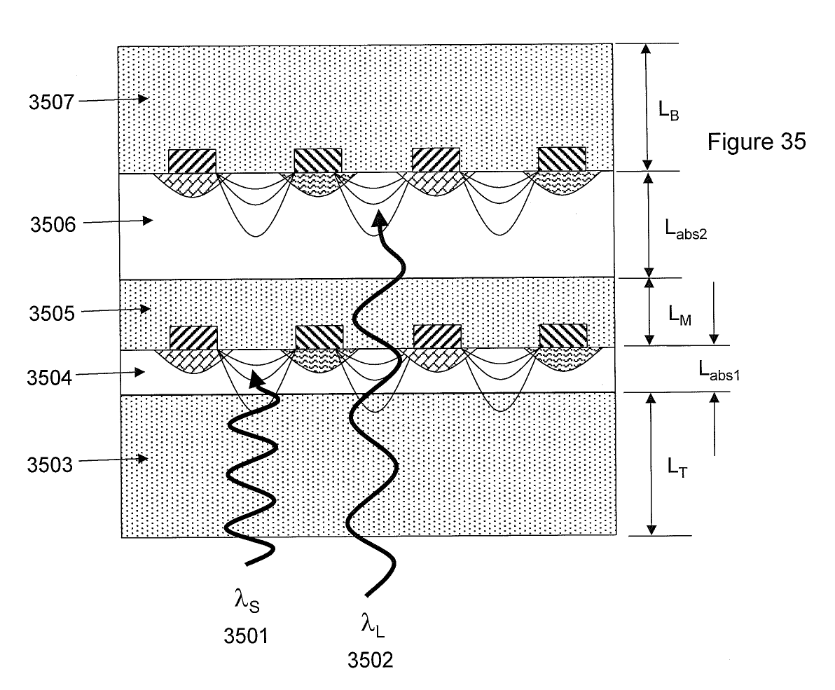

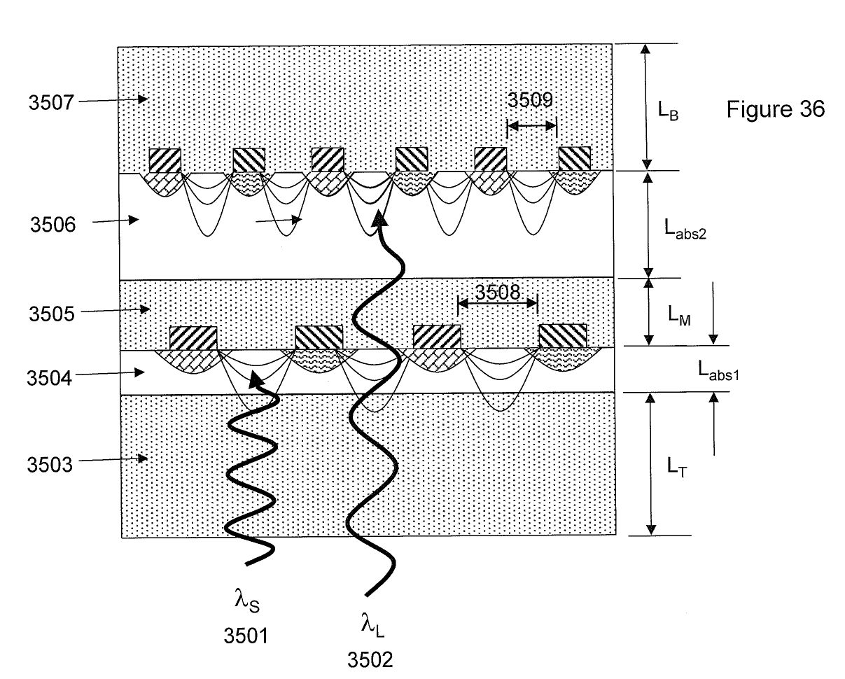

FIGS. 35 and 36 show how multiple layer thin films and electrode arrangements can be used to optimize the wavelength selectivity of the solar cell device.

FIG. 37 shows the high energy absorption spectrum 3701 of commercially relevant semiconductors. The indirect absorption edge of Si and Ge exhibit long absorption tails with relatively low absorption co-efficient for a majority of the spectrum. However, the absorption coefficient of Si and Ge exceed those of GaAs, InP and SiC for wavelength smaller than ˜400 nm. Therefore, Si can be used advantageously and uniquely for UV solar selectivity.

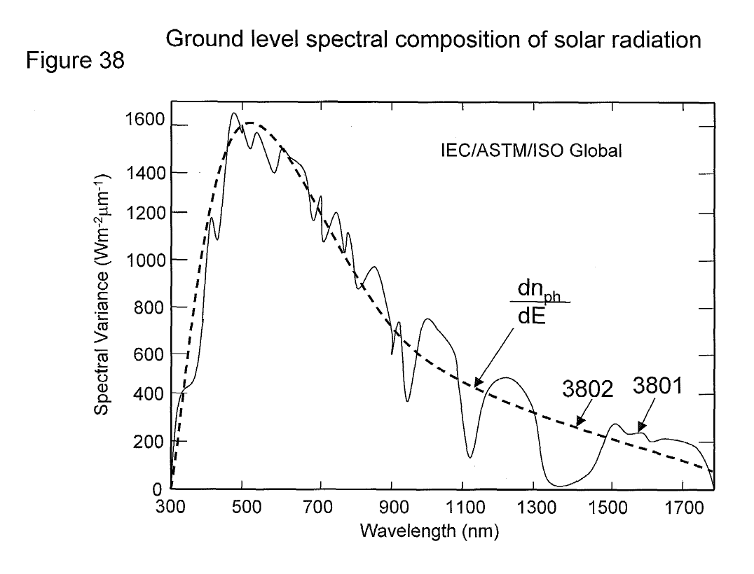

FIG. 38 shows the ground level solar spectrum 3801 and the approximation 3802. The spectral variance is proportional to the derivative of the photon number with respect to the photon energy. The peak variance is observed to occur ˜500 nm or 2.48 eV.

FIG. 39 shows the UV optimized efficiency spectrum of a thin film CZ Si solar cell using the device of FIG. 33. The use of intrinsic (high oxygen doped CZ Si 3901) and n-type doped CZ Si (3902) are shown. Alternatively, oxygen may be implanted; alternatively gases other than hydrogen and oxygen may be employed; any two chemical specie which can be implanted and subsequently react to form a compound which expands on heating are suitable candidates; examples comprise carbon, hydrogen, nitrogen, oxygen; water is preferred but not the only possibility.

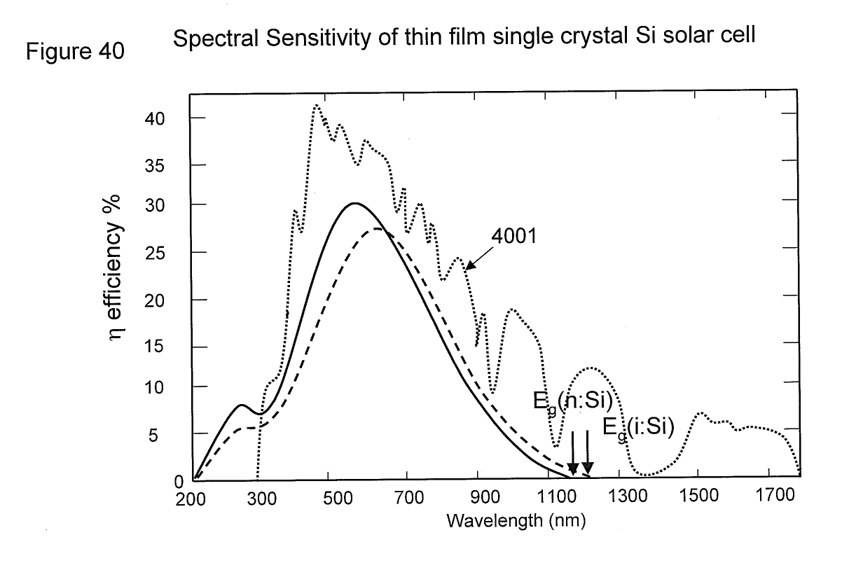

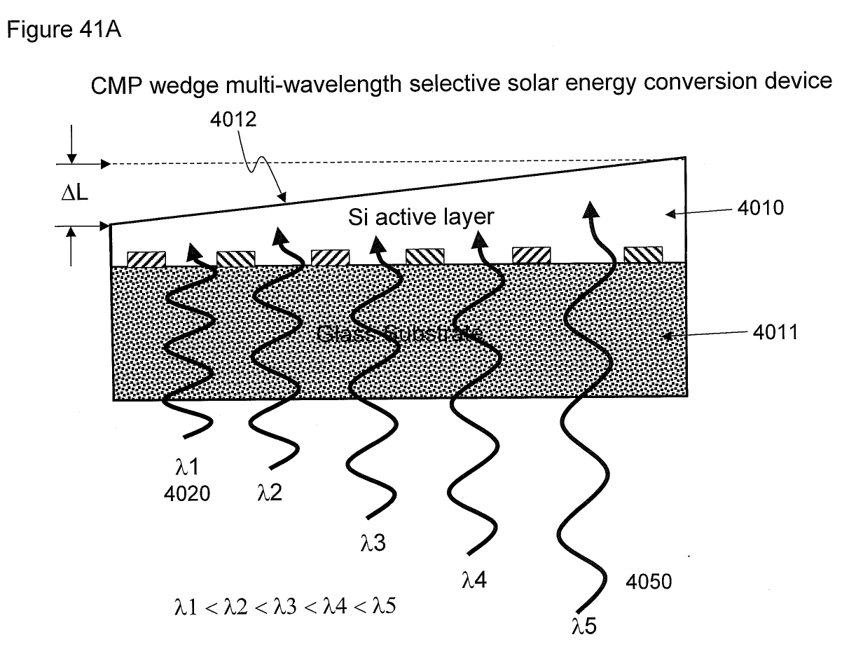

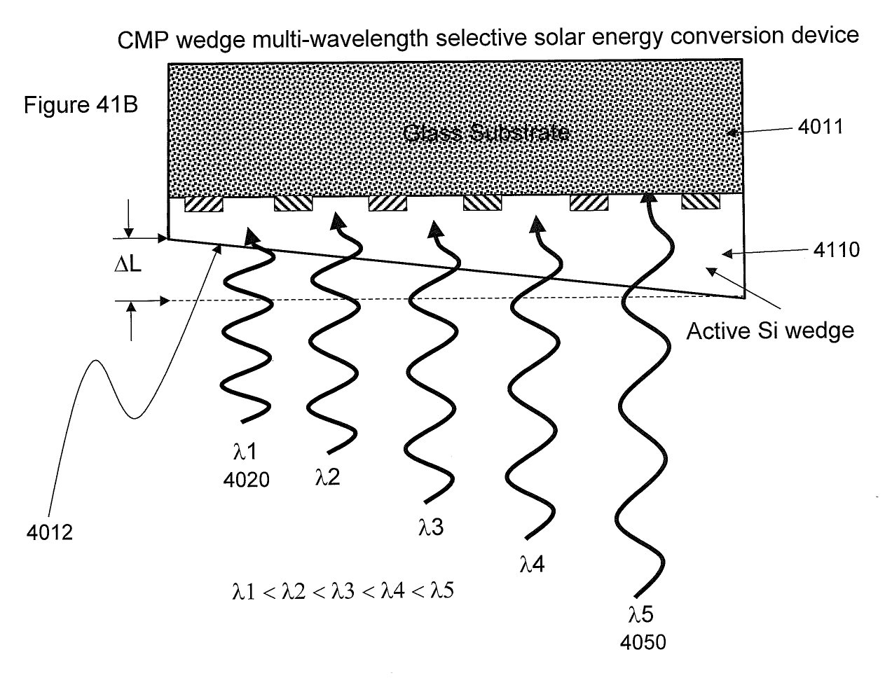

FIGS. 40 and 41A and B show solar cell device based on spatially variable thin film CZ Si active layer 4010 transferred on to an alternative substrate 4011. The wavelength selectivity can be advantageously used to couple different wavelengths spatially into the Si active layer. The wedge 4012 can be fabricated by simple CMP polish. Wavelengths range from UV, 4020, to infrared, 4050 are shown absorbed in various regions of the cell.

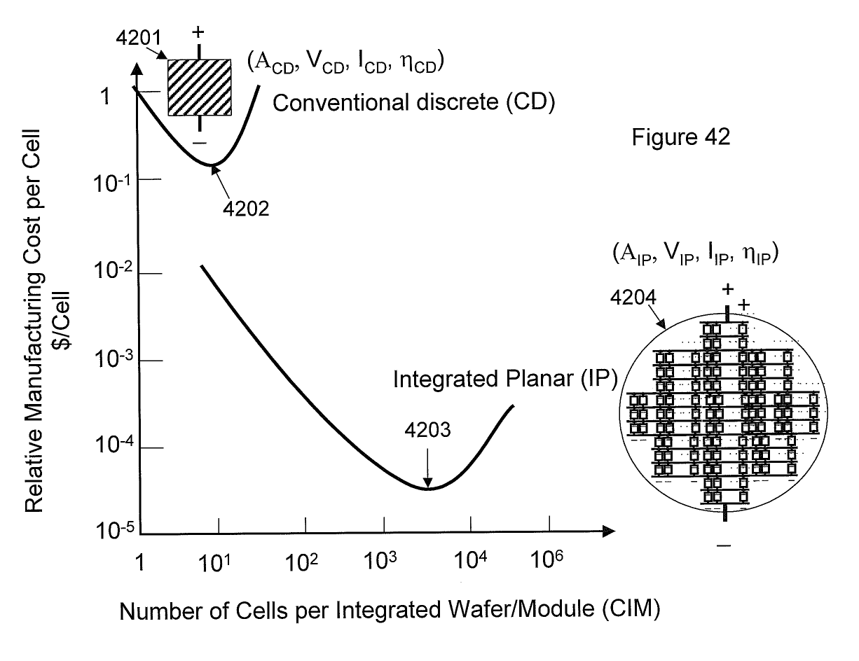

FIG. 42 schematically shows the comparison of the cost of manufacture of a unit solar cell versus the number of solar cells per module. The discrete manufacturing case is shown as conventional discrete and represents prior art approaches to solar cell and module production. As was demonstrated with the discrete transistor manufacture, a minimum cost curve was found. The integrated planar transistor such as CMOS FETs introduced a new manufacturing paradigm, wherein the minimum cost per transistor was many orders of magnitude lower that the discrete manufacturing process. The planar integrated device allowed more transistors to be densely packed into a finite area with large improvement in complexity and/or function and reduced system cost. The present case compares the analogous case for solar cells and solar modules. The instant invention allows the cost per unit solar cell to be dramatically reduced and the number of integrated cells per module to be dramatically increased. The present invention claims that higher efficiency solar modules based on wafer scale manufacturing method as disclosed herein is superior for lowering cost. Further more, the voltage and current of the wafer scale module can be optimized for increased flexibility and function. Yet further, the present invention teaches the optimization of solar cell device efficiency via the use of small scales. Smaller devices require lower lifetime semiconductors to be used and idealized photocurrent conversion structures. Multiplication in number of optimal small solar cells can be used to scale the total electrical output of the module.

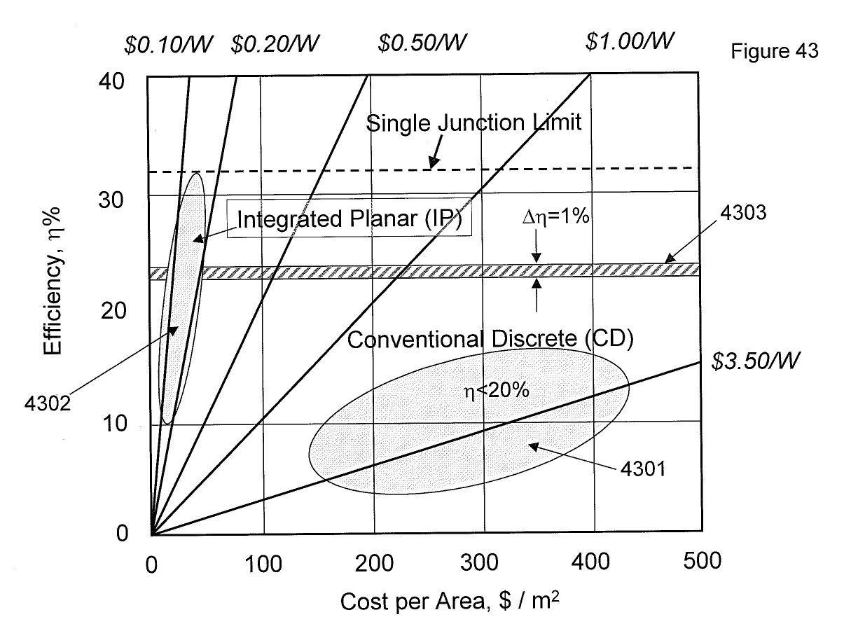

FIG. 43 shows the efficiency of single junction (SJ) solar cells versus cost per area. The cost per watt lines area superimposed on the graph. The upper theoretical limit of SJ cells is ˜30-32%. Conventional discrete (CD) prior art approaches are represented as the region 4301, typically exhibiting energy conversion efficiencies less than □<20%. It is claimed, the devices of the present invention can increase efficiency of SJ from □<20% toward and up to the theoretical maximum by the optimal use of IP manufacturing technique. Note, a 1% increase in efficiency for prior art techniques with high cost per area and low efficiency is prohibitive for innovation. For example, a □□=1% increase for CD technologies cost approximately $25-50/m². Compared to the present invention using IP method, the □□=1% increase will cost substantially less than <$1/m². Furthermore, the flexibility in adapting electronic cell designs using implant and lithographic processing method as disclosed, is highly accommodating to innovation.

Unit Cell Configurations

Example embodiments of electrical devices in FIGS. 44 to 51 inclusive, are used for implementing the active layer structures optimized for converting solar radiation into electrical energy. FIGS. 44 to 51 inclusive, are example implementations of the present invention. One knowledgeable in the field understands other configurations are possible and are also herein disclosed.

FIG. 44 shows how the active thin film CZ Si layer can be configured to operate as a lateral p-n junction diode 4400. The figure represents a unit cell that can be replicated on wafer into a module. Electrodes 4401 and 4412 contact the implanted regions 4404 and 4407. The depletion layer 4405 formed allows photogenerated e-h pairs 4409 to be separated into electron 4411 and holes 4410 by the built in electric field and be extracted into the n+ 4404 and p+ 4407 regions through the same surface. Optical radiation can couple into the active layer via the electrode side 4402 or through the alternative substrate (not shown) 4403. The CZ Si thin film is p-doped Si (p Si).

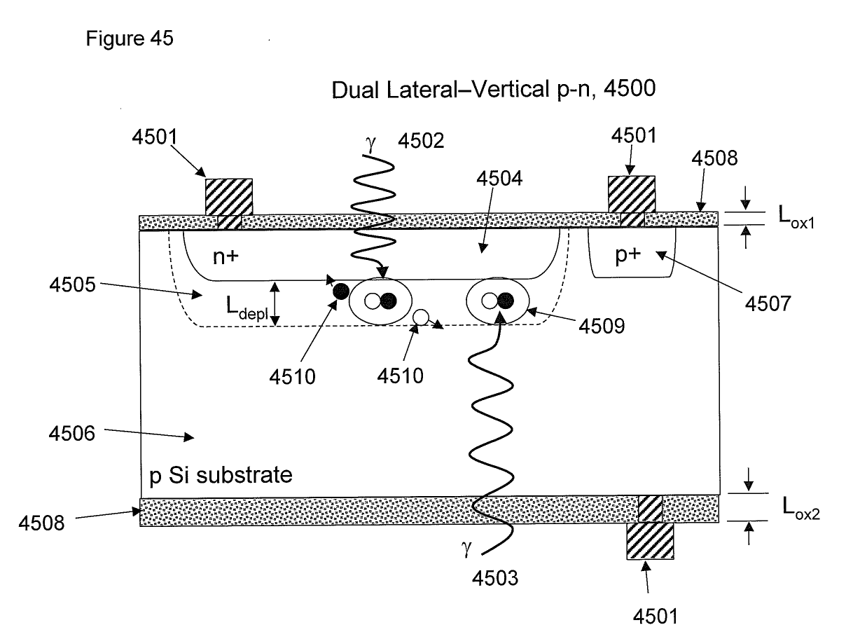

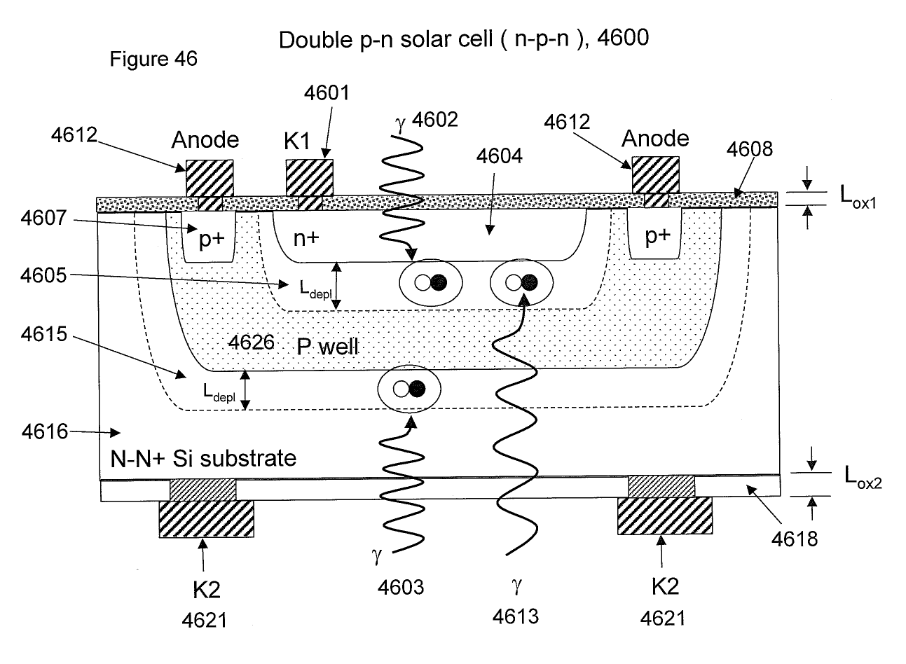

FIG. 45 shows the device 4500 constructed as disclosed in FIG. 44, but having an additional backside contact 4501. FIGS. 45 and 46 are numbered similarly with the addition of backside insulator 4508.

FIG. 46 shows a double p-n junction or n-p-n device 4600. The device 4600 has two depletion layers 4605 and 4615 formed by the n−n+ substrate 4616 and p-well 4626, and also between the p well 4616 and the n+ region 4604. All n-type and p-type conductivity regions are altered from the initial n−n+ Si substrate constituting the thin film Si layer transferred onto an alternative substrate (not shown). Optical radiation may couple the device via 4602, topside, and/or 4603, backside. Electrodes 4601, 4612 and 4621 are connected to the external circuit to extract the photocurrent. Optical coupling layers 4608 and 4618 are typically fabricated from SiO₂.

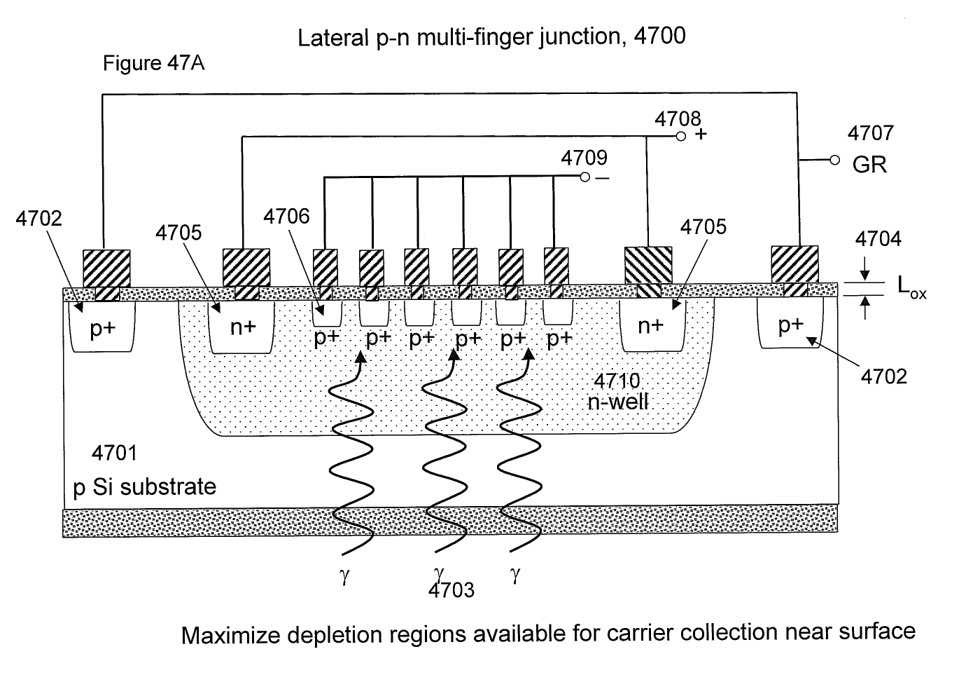

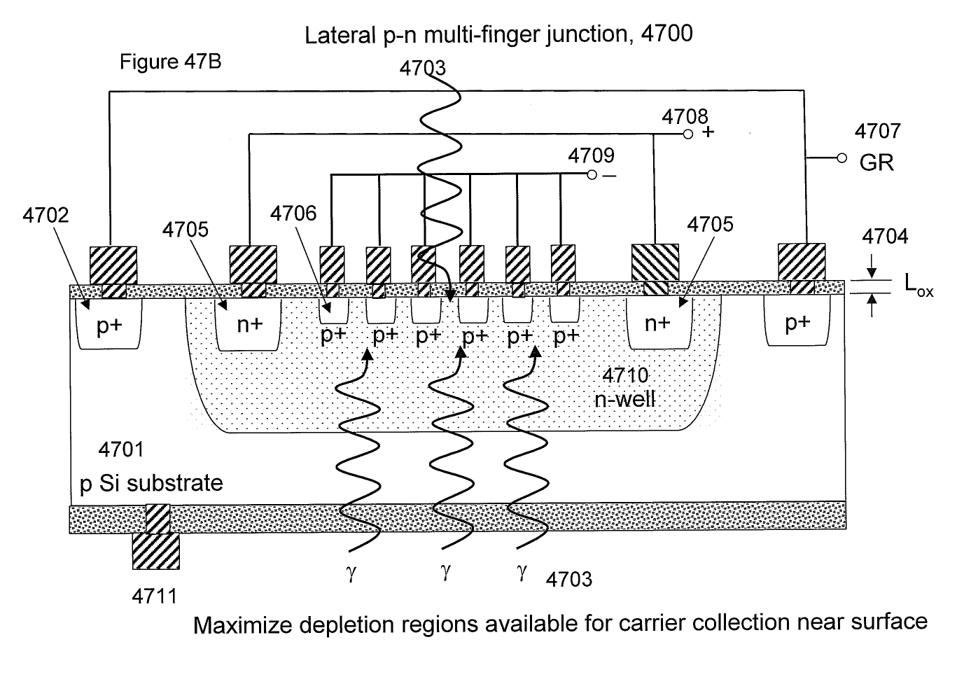

FIG. 47A shows how a multi-finger electrode 4706 arrangement can be used to increase photocarrier collection efficiency. The device 4700 utilizes p Si thin film layer 4701 transferred to alternative substrate. The implanted regions 4702, 4705, 4706 and 4710 alter the conductivity type of the thin film Si layer 4701 which is chosen for example as p-type Si. Optical radiation coupled in preference via 4703 through alternative substrate. A guard ring formed by grounding 4707 is used to prevent charge leakage between cells.

FIG. 47B shows device 4700 with additional backside electrode contact 4711 and, optionally, light coming in to the back or top surface.

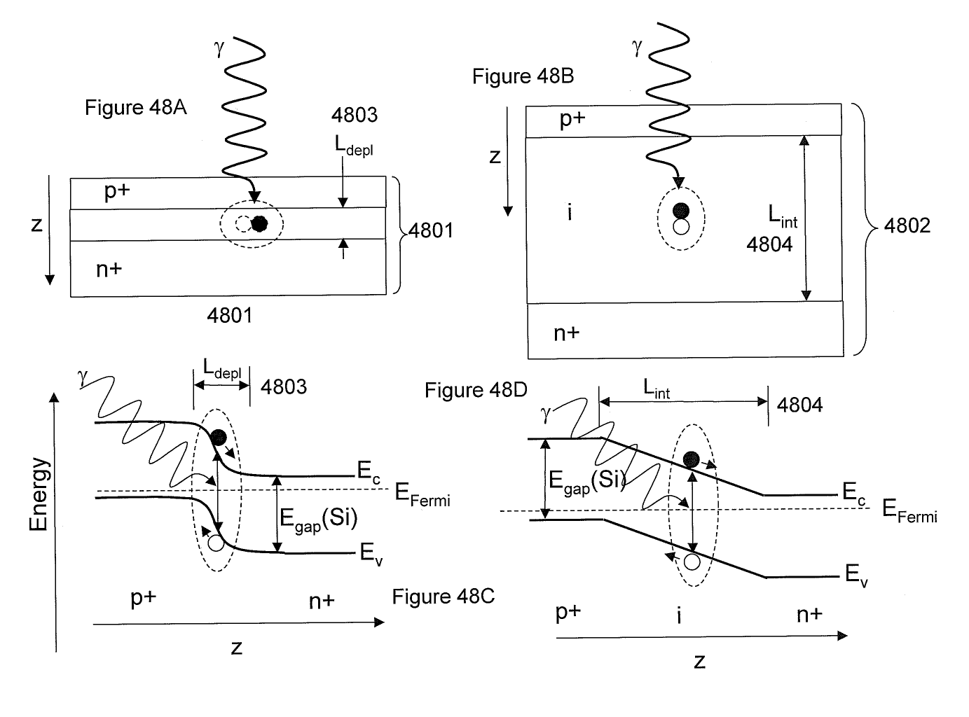

FIGS. 48A and B shows vertical p-n junction diode 4801 and p-i-n diode 4802 configurations for use in solar cell device. The vertical multilayers 4801 and 4802 are shown. The energy band structure versus physical distance z is also shown for the p-n and p-i-n diode configurations. The conduction and valence band edges, FIGS. 48C and D, represent the fundamental band gap of single crystal Si. Incident photon is absorbed in the depletion region 4803 and/or intrinsic region 4804 thereby creating an e-h pair.

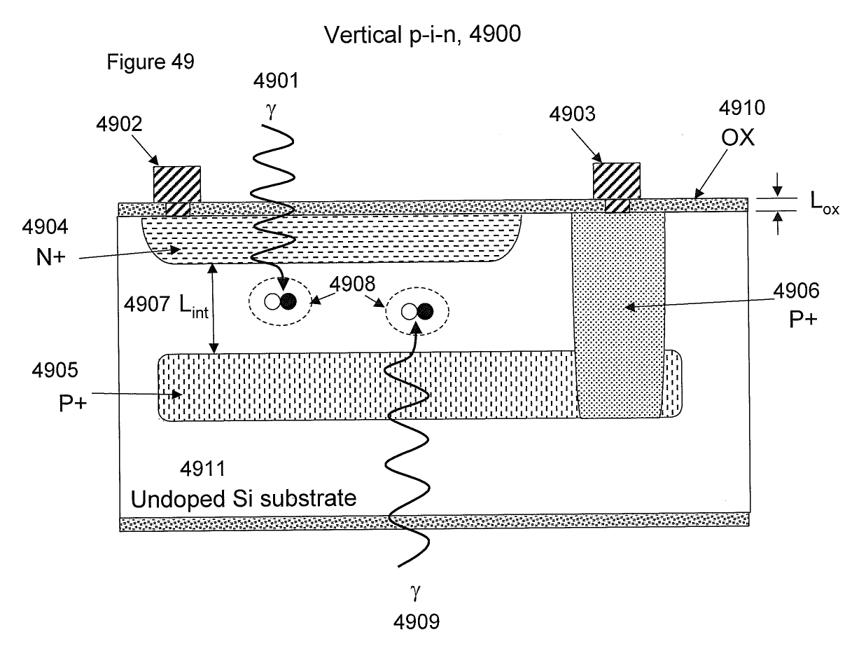

FIG. 49 shows implementation of vertical pin device 4900 using selective area and depth implantation of impurities in regions 4904, 4906 and 4905, in order to alter the conductivity type of the region. The thin film Si layer 4911 has not intentional doping and/or intrinsic. Optical radiation 4901 and/or 4909 couple into 4907 and is absorbed, thereby creating e-h pairs 4908.

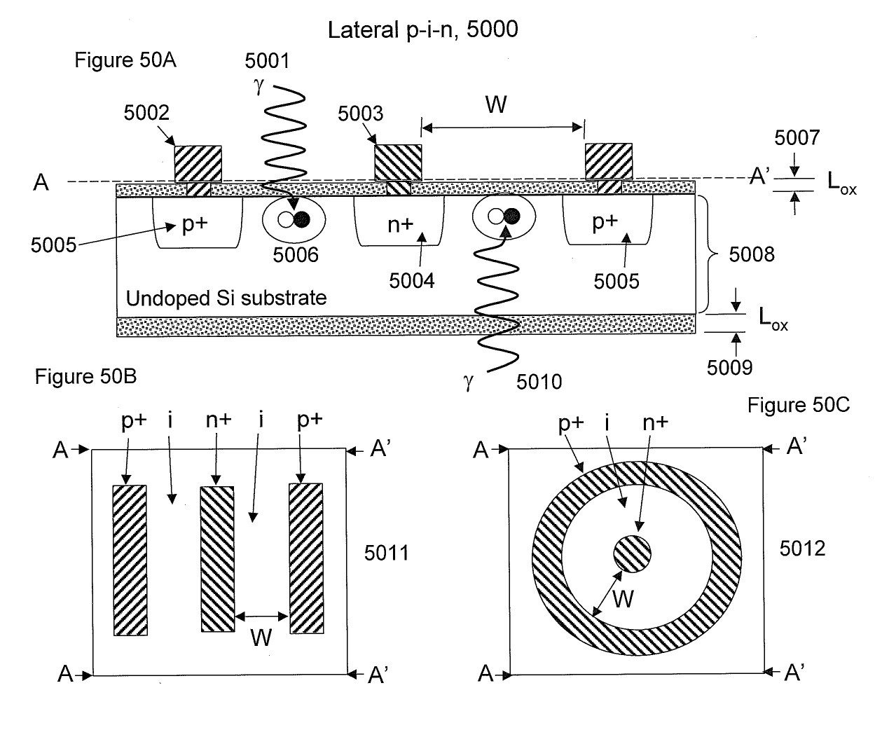

FIG. 50A shows a lateral p-i-n device 5000 formed via selective area implantation of regions 5005, 5004 into thin film Si active layer 5008. The optical radiation 5001 and/or 5010 is absorbed in the active layer and more preferentially into intrinsic region 5006. The electrodes 5002, 5003 and implant regions beneath may be arranged in the configuration 5011 of FIG. 50B and/or 5012 of FIG. 50C.

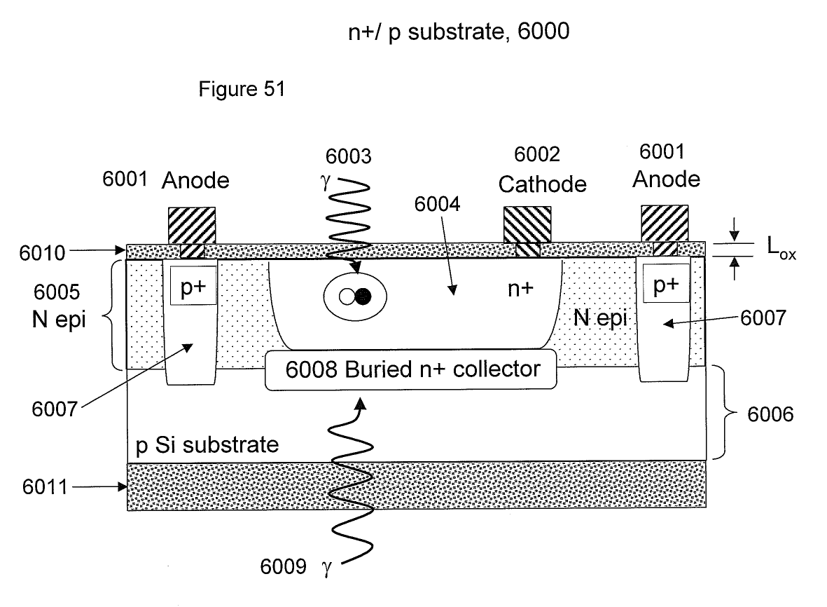

FIG. 51 shows n+/p diode 6000 used for solar cell element. The thin film layer transferred to an alternative substrate is a p-type Si 6006 followed by n-type epitaxial layer 6005 deposition. The layers 6006 ad 6005 may alternative be transferred from a substrate onto the alternative substrate. The selective area and depth implant regions 6007, 6008, 6004 are performed after the thin film Si layer transfer onto the alternative substrate 6011.

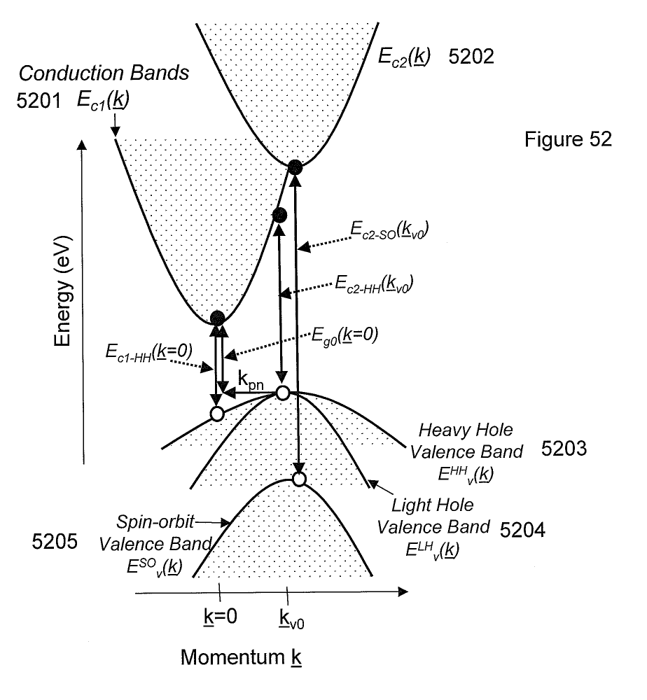

FIG. 52 depicts schematic of conduction and valence band energy versus crystal momentum of indirect band gap energy semiconductor such as Silicon. The possible optical absorption transitions are shown relative to the conduction and valence bands. Band edge resonant absorption E_{c1-HH}(k=0) requires the additional participation of a phonon of momentum kₚₙ. High energy photons may directly create electron-hole pairs with large excess energy with respect to the fundamental band edges. This fact is used advantageously for UV enhanced avalanche multiplication process described herein.

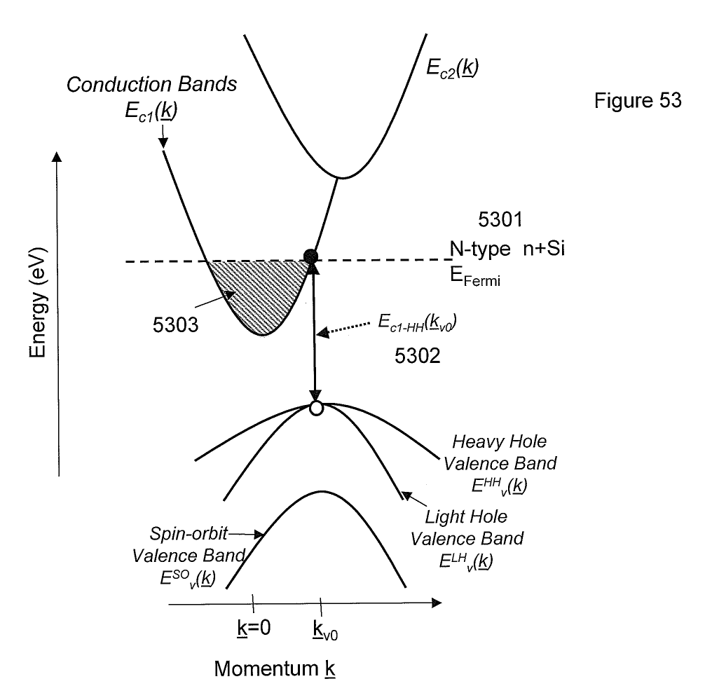

FIG. 53 depicts schematic of conduction and valence band energy versus crystal momentum of indirect band gap energy semiconductor, such as Silicon, doped with impurity atoms to exhibit degenerate n-type conductivity. The Fermi level 5301 shows that the conduction band is filled 5303, causing optical absorption to begin for energies exceeding 5302.

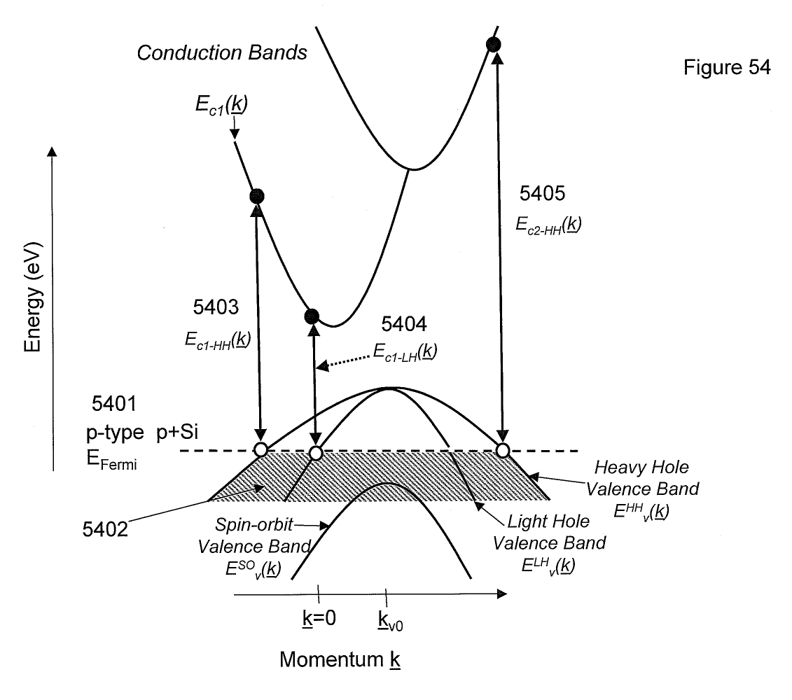

FIG. 54 depicts schematic of conduction and valence band energy versus crystal momentum of indirect band gap energy semiconductor such as Silicon, doped with impurity atoms to exhibit degenerate p-type conductivity. The Fermi level 5401 shows that the valence bands are filled 5402, causing optical absorption to begin for energies exceeding 5403, 5404 and 5405. Therefore, the onset of the absorption edge is shifted to higher energy and results in a sharper transition from transparent to opaque property.

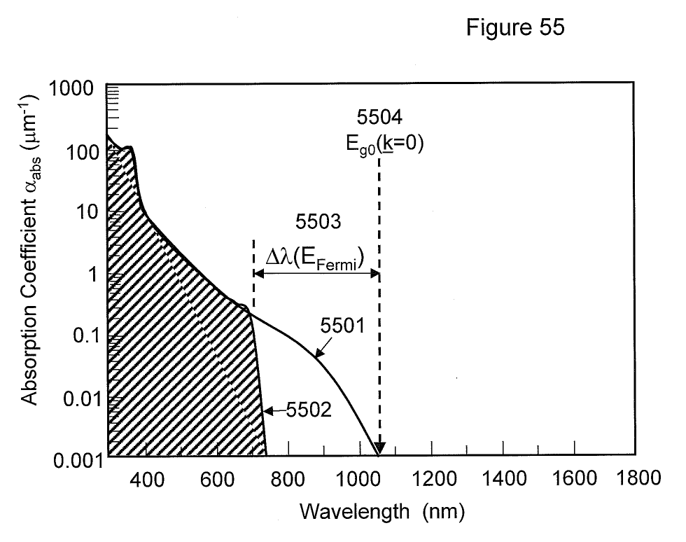

FIG. 55 shows how the optical absorption spectrum of single crystal Si is altered from intrinsic 5501 conductivity type to degenerately p-doped 5502. The blue shift in the absorption edge 5503 is also shown, due to phase space filling.

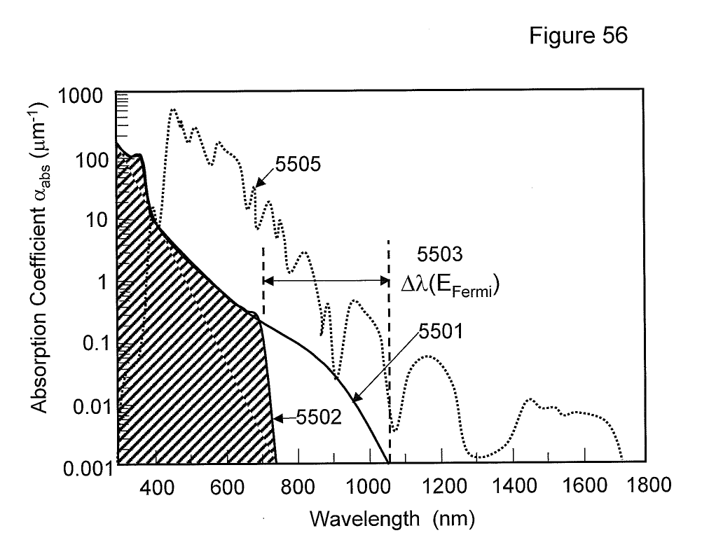

FIG. 56 shows how the blue shift described in FIG. 56 compares to the solar spectrum at ground level. The impurity doping of Si can be used advantageously for tuning the absorption edge to shorter wavelengths.

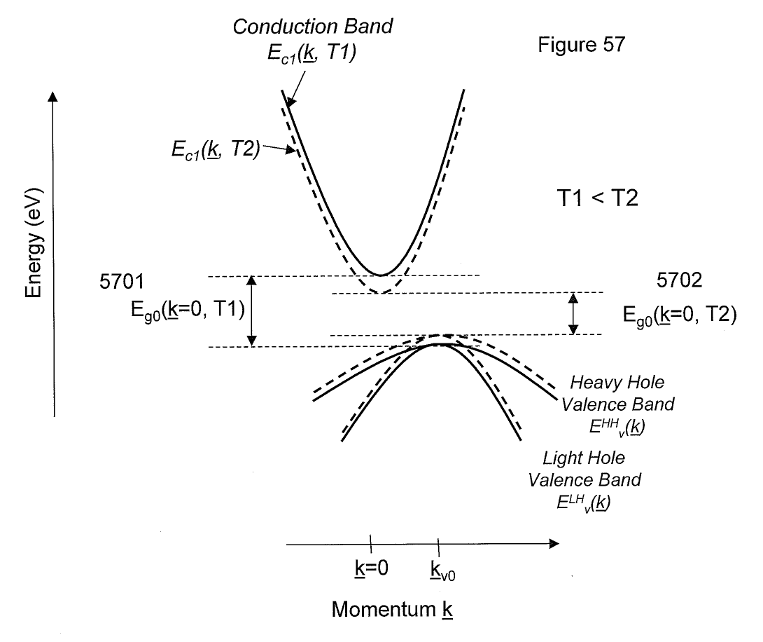

FIG. 57 shows how the effect of increased temperature on an indirect band gap material. As temperature increases, from T1 to T2, the band gap 5701 narrows to 5702. The fundamental band gap of single crystal Si is therefore temperature dependent.

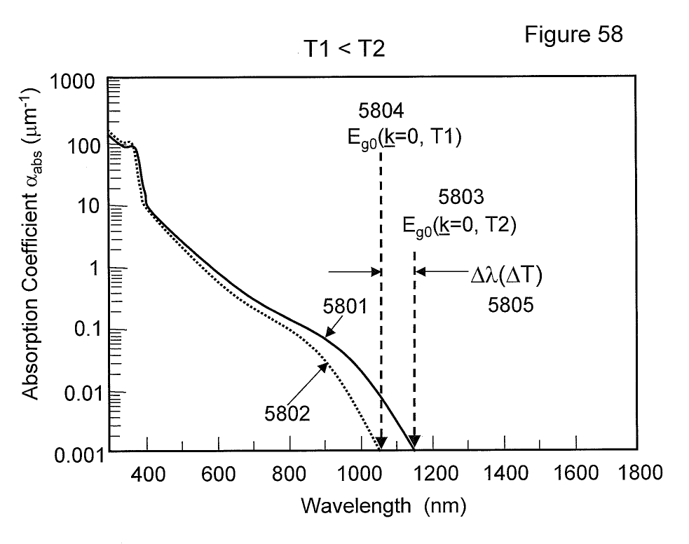

FIG. 58 shows how the optical absorption spectrum of single crystal Si is changed by the increase in temperature. The absorption edge shifts to longer wavelengths with increasing temperature.

Smart Link Integrated Wafer Scale Reconfigurable Modules

Optoelectronic energy conversion devices fabricated using planar wafer scale processing methods are disclosed. The same method can also be used to fabricate monolithically integrated electronic functions capable of performing digital and/or analog functions intimately integrated on the wafer scale sole module. For example, electronic diodes and transistors such as planar p-n junction diodes and planar bipolar n-p-n and/or n-p-n transistors can be fabricated using the same mask steps as used for fabrication of solar cell units. The electronic functions can powered from the voltage and/or current generated on wafer and are therefore self provisioning. Electronic functions that can be implemented on a planar integrated solar wafer module are power monitoring and smart switches that can be externally programmed to configure unit solar cells to perform voltage source and/or current source operation. For example, solar cell unit arrays fabricated by replicating basic energy conversion units may be placed in an array, with smart switches controlling functional blocks on a wafer. That is, analogous functions of programmable array logic can be used for implementation of a programmable power module based on internal configuration of voltage and/or current of the wafer module.

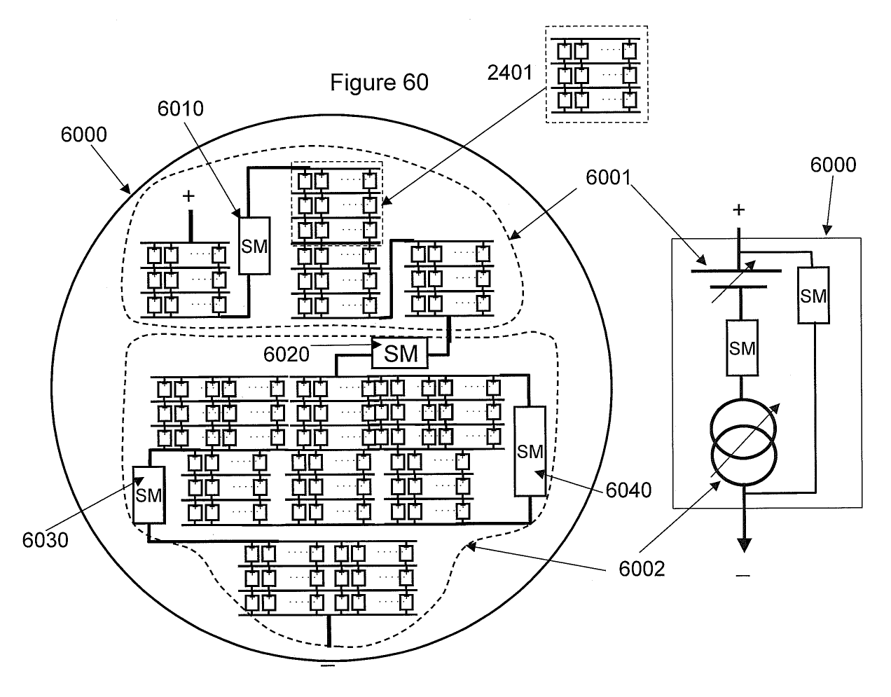

FIG. 60 shows wafer scale solar module 6000 with smart links and/or smart switches 6010, 6020, 6030 and 6040 that are programmable so as to form a programmable voltage source 6001 or current source 6002.

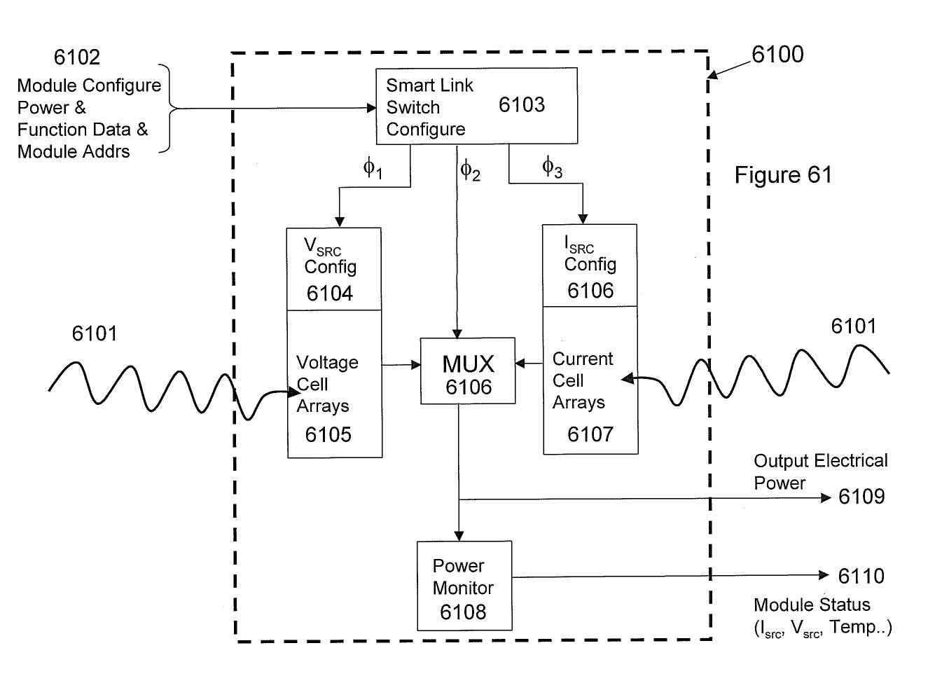

FIG. 61 develops the programmable module concept further with external control input(s) 6102 used to configure the smart links of wafer scale solar module 6100. The input solar energy 6101 is incident on both voltage source array V_{src} 6105 and current source array I_{src} 6107 sections. The smart links are controlled by configuration section 6103 and 6104, 6106. Output power multiplexer MUX 6106 outputs to module power 6109. Optional power monitoring of the wafer scale solar module 6108 can be used to provide health and/or status and/or temperature 6110 of the module. The temperature and output power can be used to dynamically optimize the module performance for varying external solar radiation fluence. On board power regulation can also be employed using power regulation electronics also monolithically integrated on the wafer scale solar module.

In summary, the present invention teaches the use of electronic circuitry monolithically integrated in the same wafer scale solar module so as to perform logic and/or analog functions. The added electronic functions aid in the performance optimization of the module and make the module reconfigurable for many diverse applications. The additional cost of the electronic functions is negligible as the performance of the transistors need only be simple. For example, high speed performance is not necessary and need only be equivalent to LSI bipolar transistor technology of the 1970-80's.

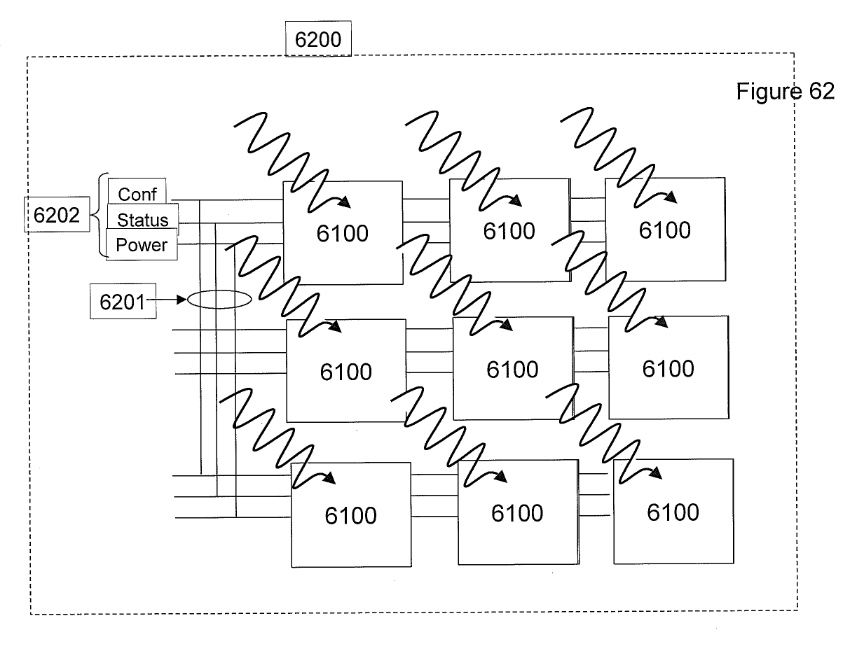

FIG. 62 discloses the utility of using reconfigurable wafer scale solar modules 6100 in complex systems 6200. For example, a simple array composed of multiple wafer scale solar modules can be interconnected 6201 as shown. Depending on the application and size of the array optimal module configurations 6202 can be employed.

Solar Module Charge Pumping Concept

Typically, solar module functions are designed for steady state operation producing substantially constant direct current and/or power output, for a given constant solar fluence. An alternative method is the concept of charge pumping energy storage units on the wafer by use of capacitor and switch technique. For example, a solar cell unit can be electrically isolated from an external circuit and photogenerated carriers allowed to build up in an essentially capacitive device during timed exposure to solar radiation.

Once a predetermined time and/or charge threshold is reached, an electrical switch connects a charge pump to an external circuit and the stored charge transfers to the external circuit. Conceptually, large arrays of solar cell charge storage cells may be interconnected and discharged into an electrical circuit using electrically controlled switches. The electronic functions can be implemented via monolithic means as described in the present invention. Capacitive storage cells can be fabricated using, for example, SiO₂, silicon oxynitride, Si nanocrystals, SiNₓ and/or high dielectric materials to form suitable capacitive capability.

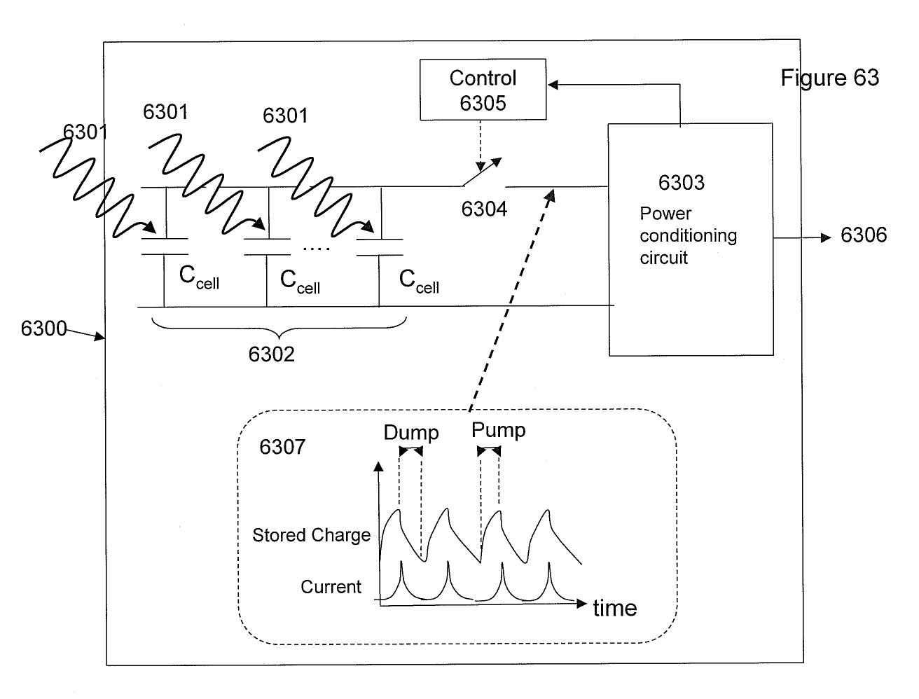

FIG. 63 discloses charge pump solar module 6300. A charge pump and discharge unit can be replicated across an entire wafer and thus produce wafer scale functionality as described in the present invention. The schematic function of the device consists of charge storage unit cells 6302 which convert optical photons into electronic photocarriers which are stored in an array of C_{cell}. Electrical switch 6304 is controlled by electronic circuit 6305 that determines charge time and discharge time of storage cells. A power conditioning unit 6303 processes the time varying current pulses suitable for external power output 6306. Time varying current pulses and stored charge are shown as 6307. Pump and dump cycles are determined by a switch position, open-state and closed-state, respectively. The utility of such a system is that the peak electrical power is large and can be used advantageously in internal and/or external power condition circuits for high efficiency conversion into alternating current. External loads may also use advantageously high peak power output from the said module.

Thin Film Layer Separation

In one embodiment, ion implantation is used to create preferential defect layer and/or multiple layers beneath the Si surface of a Si substrate in order to allow removal of a desired thickness of thin film Si in the range of 1 □m≦L_{Si}≦250 □m. In one embodiment, a defect layer is produced across, optionally, the entire wafer to approximately the same depth and thickness. The said defect layer can then be induced to create a chemical and/or mechanical reaction so as to locally disrupt the otherwise perfect Si crystal structure. Mechanical fracture localized at the defect layer can separate the topmost sc-Si film from the bulk of the substrate.

High energy ion implanters up to 5 MeV are presently used in CMOS processing to generate deep doped Si wells.

One embodiment of the present invention utilizes large amounts of foreign atoms placed at a specific depth below the Si surface, exceeding the solubility limit of the host Si crystal structure. The method of ion implantation typically produces a Gaussian profile of depth versus concentration of the implanted species. The peak concentration at the depth L_{D}, is primarily controlled by the ion species and the beam energy of the ion. The CMOS industry routinely implants silicon, germanium, oxygen, hydrogen, deuterium, helium and dopant species such as As, P, B and Sb. Various energy regimes are used to create shallow, medium and deep implant profiles relative to the surface. Typically, CMOS processes do not exceed several microns in depth. The present invention teaches the use of extremely deep implantation profiles in the range of 1 μm≦L_{D}≦250 μm to form removable thin films of sc-Si.

One embodiment of the present invention uses high energy ion implantation of hydrogen and/or helium and/or silicon and/or germanium and/or oxygen to imbed large concentration of implanted atoms below the surface to a specific depth of a high quality Si substrate. The use of hydrogen is well known to workers in the field as a means to generate buried layer cleaving planes disposed substantially parallel to the wafer surface [Refs 1-5]. The present invention further teaches the use of individual implant of single ion species and/or sequential ion implant of different species.

Ion implantation of rare-gas species in many materials has been known for some time to result in blisters at or immediately below the material surface at fluences of 10¹⁶-10¹⁷ cm⁻². For example, Ar⁺ in Ge and/or Si, H⁺ in GaP and Si [9], He⁺ in metals such as, Mo, Nb, Ni and Al.

Prior art techniques for Si thin film separation from the remaining bulk substrate using this blistering effect have concentrated on injecting large external source concentrations of ions into the said substrate at the required depth. The substrate is initially deficient in the injected atom species. Upon implantation and a thermal anneal sequence, the high concentration of introduced ions, typically hydrogen, form gaseous microbubbles in a predetermined region and results in layer separation. The present invention benefits from this method.

A further aspect of the present invention is the use of an improved method of ion implantation facilitated layer separation technique.

Thin Film separation using Hydrogen in Si

In one embodiment, implantation of H into Si at doses of ˜5×10¹⁶ cm⁻² [10] are required to form uniform density of decorated defects and/or micro-bubbles in a buried defect layer. Micro-bubbles can be made to coalesce into larger structures via externally applied thermal energy. Gaseous hydrogen builds pressure in the defect layer eventually splitting the thin layer from the reaming bulk substrate. A critical step for uniform fracture of large diameter Si substrates requires the defect plane to be substantially aligned to a crystallographic plane to serve as a cleaving plane.

Thin Film Separation Using Helium in Si

One embodiment employs helium ion implantation to generate a buried defect plane beneath the Si surface. The heavier atomic mass of He relative to H requires approximately twice as much implant energy for He to penetrate the Si surface to the same depth. Sequential implantation of H and He ion implants may also be used, with the latter providing a means to potentially reduce the total dose required.

While other species such as carbon, nitrogen and fluorine may also result in the same bubble and split process, the energy requirements on the ion implanter are not practical for the depths proposed for SJ thin film sc-Si solar cell devices.

Thin Film Separation Using Hydrogen and Oxygen in Single Crystal CZ Si

The growth of single crystal Si from high purity poly-Si is germane to wafer production. Two techniques are typically used: (i) crystal pulling (or Czochralski, CZ) method [8]; and (ii) zone-melting (or float-zone, FZ) method [7]. Large area Si substrates (≧300 mm dia.) are typically grown using the CZ method, where a single crystal is grown by pulling from a molten region of Si. The said molten region of Si is contained, (and heat energy supplied from by an external source), using a high purity quartz or vitreous silica (SiO₂) crucible. The quartz crucible is filled with polysilicon pieces and heated just past the melting point of Si. The diameter of the quartz crucible limits the size of the single crystal boule pulled from the molten Si source and thus determines the final wafer diameter. Prior art has determined the highest quality Si boule is via the use of high purity quartz in preference to all other known crucible materials capable of containing molten Si. A major limiting factor for choice of crucible materials is the fact that Si forms an alloys readily with all refractory metals and/or commercially available ceramics, well below the melting point of Si-rendering alternative crucible materials useless. The poisoning of the Si boule by the crucible material is a key aspect determining the final quality and application of the Si product. The single crystal Si is therefore grown by physically pulling from the melt contained in the quartz crucible, with the pulling rate determined in part by the melt temperature. The surfaces of the quartz crucible in contact with the molten Si is consumed over time as a result of the reaction SiO₂+Si→2SiO, and the quartz is said to devitrify. This reaction enriches the Si melt and pulled Si crystal with oxygen atoms. A portion of the oxygen atoms evaporate from the melt surface as volatile silicon monoxide (SiO), and the remaining oxygen atoms become incorporated at the melt-crystal interface and thus into the growing Si crystal boule. These incorporated oxygen atoms determine the electrical, chemical and strength properties of the Si crystal. Historically, oxygen contamination was viewed as a problem and determined that the oxygen atoms were preferentially incorporated at interstitial lattice sites within the Si crystal. The concentration of incorporated oxygen into CZ Si crystals typically exceeds the solid solubility, and the supersaturated oxygen can precipitate during subsequent thermal annealing treatments. A key step forward in CZ Si development and therefore CMOS performance, was the observation that the interior defects produced by the oxygen precipitation produce an effective method to suppress epitaxial stacking faults in CZ crystals. Furthermore, the impurity oxygen concentration in CZ Si was shown to advantageously act as an internal gettering agent, and is widely used presently in high performance CMOS industry. The effectiveness of the internal gettering action of oxygen is determined by the initial oxygen concentration and anneal process. In addition to the beneficial effect of oxygen containing CZ Si it has been shown to be advantageous in supersaturated regime rather than oxygen lean regime. Prior art has demonstrated that FZ Si is inferior in mechanical strength compared to oxygen containing CZ Si. Therefore, the oxygen concentration in CZ Si affects: (i) internal defects produced by oxygen precipitation; (ii) mechanical strength; and (iii) the presence of oxygen donors. The present invention exploits the use of oxygen containing CZ Si wafer for the direct application to the present invention for the purpose thin film cleaving and separation method.

The control of oxygen concentration in CZ Si is of paramount importance for application to CMOS ULSICs. The process control, lifetime and purity control of the quartz crucibles is a major component in the manufacture of large diameter Si substrates suitable for CMOS manufacture. The Si wafer becomes the active layer of the field-effect-transistors (FETs) and is the most critical component in the entire front-end-of-line (FEOL) process. The oxygen concentration in CZ Si can be classified into low, medium and high concentration [O]_{CZ} ranges. For CMOS applications, the medium range is characterized by [O]_{CZ} in the 14-17 ppma range [6]. The high and low concentrations are therefore relative to the medium range. For the present invention the CZ Si medium [O]_{CZ} range is given as about 2×10¹⁷≦[O]_{CZ}≦1×10¹⁸ atoms/cm⁻³ in the Si crystal.

In one embodiment, the present invention teaches at least a three step process wherein: (i) the Si substrate is chosen in preference from oxygen containing CZ Si; (ii) the wafer is implanted by bombardment of high energy ions, optionally, hydrogen (H⁺) to form hydrogen containing layer spatially separated from the Si surface and residing a predetermined depth from the surface with finite thickness. The hydrogen containing layer substantially uniform in extent and substantially parallel to plane of the wafer surface; (iii) subjecting at least one of the frontside and/or backside of the CZ Si wafer containing the as-implanted substrate to heat treatment in suitable ambient gas so as to promote reaction between the hydrogen and oxygen species in the immediate vicinity of the implanted layer.

The buried regions containing reacted hydrogen and oxygen and/or bubbles and/or steam or vapor generated acting so as to cleave the desired topmost CZ Si film free from the remaining portion of the substrate.

The prime advantage of the above film separation method in preference to the previously described prior art techniques is the significant reduction of hydrogen dose required for film splitting and separation. This directly translates into shorter H⁺-implanter beam times.

An optional advantage is the vapor as produced using the above process may also act so as to reduce the Si atoms in the immediate neighborhood of the cleave, thereby forming native SiO₂ and/or releasing hydrogen, which may passivate surface states at the cleaved Si surfaces.

An additional benefit of the above disclosed process is the use of the denuding action of oxygen during thermal treatment [6]. Oxygen is well known in CZ Si to form a denuded region under thermal treatment. Depending on the exposed surface ambient, either oxygen rich or deficient, the oxygen profile near the exposed Si surface can be manipulated. Typically, oxygen precipitates can be driven into the interior of the Si crystal away from the surface. This is advantageous for the present invention wherein the oxygen precipitates can be driven toward the hydrogen containing layer defining the cleave plane. Note, the different temperature selectivity of steam or vapor splitting and denuding can be also used advantageously. A denuding effect can be incorporated in a separate thermal treatment independent of a cleaving process.

For application to SJ Si solar cell manufacture, the oxygen concentration is not critical. Heat treatment of the oxygen containing CZ Si above approximately 500° C. results in electrically inactive and/or neutral precipitates and does not disadvantage the performance of SJ solar cells. This allows cheaper CZ production methods to be utilized to form high quality single crystal Si. That is, high quality single crystal Si substrates can be manufactured for solar cells but not to the same tight tolerances required in the CMOS industry.

The present invention utilizes a preferred embodiment of supersaturated oxygen containing CZ Si (O:Si CZ) wafer for the creation of thin film separation method. The O:Si CZ wafer is implanted preferentially with hydrogen to a predetermined depth such as to produce a large hydrogen concentration layer—called the defect layer, with H+doses 10¹⁴≦H⁺≦10¹⁶ cm⁻². Upon thermal annealing the buried hydrogen and oxygen atoms preferentially combine to form, optionally, water molecules and/or oxygen precipitates and/or hydrogenic clusters. In one embodiment, water molecules and the like cluster to form nanometer and micrometer sized water and/or oxygen precipitates and/or hydrogenic cluster containing regions. Under the external influence of an appropriate heat treatment, anneal time and oxygen to hydrogen ratio (O:H) the water containing regions will expand in volume with temperature and form a predetermined fracture plane substantially defined by the hydrogen implant profile. The heated water containing regions form gaseous species at low temperature (below 500° C.) and generally reduces the thermal budget required for defect layer fracture. Laser anneal and rapid thermal anneal techniques are optional methods for heating a wafer.

As medium to high oxygen incorporation is encouraged via the above described invention, other oxide crucible materials may potentially be used. The present inventor has demonstrated that zirconium oxide (ZrO₂) can be used successfully for the containment of molten Si well in excess of the melting point of Si (1420° C.), up to approximately 1700° C. Please refer to related U.S. patent application No. 60/820,438. This high temperature operation allows the CZ method to pull the Si boule at a substantially faster rate, thereby increasing CZ Si boule production throughput and thus reducing Si wafer cost. This new technique for sc-Si production is disclosed and claimed in its entirety herein.

An alternate embodiment of the present invention is the use of ion-exchange process for driving large amounts of foreign atoms from the surface to a predetermined depth. The defect layer so formed using the above methods, is then subjected to a predetermined reaction and/or stress to initiate and/or complete the fracturing and/or cleave process. The fracturing process propagates across the wafer and separates the thin sc-Si film from the bulk portion of the CZ Si substrate. By combining the aforementioned film removal and cleaving process with layer transfer and bonding to a lower cost substrate, the thin film Si can be bonded to the cost-effective substrate.

In one embodiment, the present invention discloses methods of single crystal layer transfer processes onto alternative substrate to form a thin film article. Furthermore, the present invention discloses methods of single crystal layer transfer process onto alternative substrate and methods for incorporating electrical and opto-electrical conversion regions within said thin film articles. Single crystal silicon is cited as an embodiment; other single crystal compositions are in the scope of the instant invention, including, but not limited to, germanium, silicon-germanium, silicon carbide, carbon, III-V and II-VI materials and rare-earth mixtures of all.

In some embodiments a device employing avalanche multiplication is enabled; optionally, thin film, single crystal silicon with a thickness ranging from about 20 nm to about 10 microns on an insulating and/or transparent substrate is an optional structure. Alternatively, ion implantation is employed to define a p-i-n-type conductivity region; optionally, comprising a 3-terminal device; optionally, a p-i-n device is a lateral p-i-n device and, optionally, comprises a dielectric and one or more metal contacts to span the intrinsic, i, region. In some embodiments, adsorption of high energy photons in the range of 200-700 nm of the solar spectrum in a thin film silicon layer is preferred. Alternatively, one or more single crystal, thin film layers of a composition chosen from a group comprising silicon, germanium, silicon-germanium, silicon carbide, carbon, III-V compounds, and II-VI compounds comprise an avalanche multiplication device converting radiation into electrical energy. Alternatively, one or more rare-earths may be added to said one or more single crystal, thin film layers of a composition chosen from a group comprising silicon, germanium, silicon-germanium, silicon carbide, carbon, III-V compounds, and II-VI compounds to improve adsorption and/or conversion efficiency of solar radiation to electrical energy; alternatively, one or more rare-earths may be combined with oxygen, and/or nitrogen and/or phosphorus as a distinct thin film layer and/or combined with one or more materials chosen from a group comprising silicon, germanium, silicon-germanium, silicon carbide, carbon, III-V compounds, and II-VI compounds.

As used herein an alternative, or replacement, substrate is a substrate other than the original substrate used in forming regions, active and/or not active; subsequently the regions so formed, or delineated, are transferred to the alternative substrate. Several methods are disclosed so as to enable transfer; however the present invention is not limited to transfer methods disclosed. One knowledgeable in the art will be aware of multiple methods for transferring layers from an original substrate to an alternative substrate, all are considered equivalent for purposes of enabling the instant invention.

The foregoing described embodiments of the invention are provided as illustrations and descriptions. They are not intended to limit the invention to a precise form as described. In particular, it is contemplated that functional implementation of invention described herein may be implemented equivalently in hardware or various combinations of hardware and software and/or other available functional components or building blocks. Other variations and embodiments are possible in light of above teachings to one knowledgeable in the art, and it is thus intended that the scope of invention not be limited by this Detailed Description, but rather by Claims following.

### REFERENCES

[1] “Method of fabricating SOI wafer by hydrogen ion delamination method and SOI wafer fabricated by the method”, US Patent, U.S. Pat. No. 6,372,609 B1, April 2002.
[2] “Process for producing semiconductor article”, US Patent, U.S. Pat. No. 6,100,166, August 2000.
[3] “Semiconductor-on-insulator silicon wafer and method of formation”, US Patent, U.S. Pat. No. 7,018,484 B1, March 2006.
[4] “Method of fabricating silicon-on-insulator semiconductor substrate using rare-earth oxide or rare-earth nitride”, US Patent, U.S. Pat. No. 7,037,806 B1, May 2006.
[5] “Ion beams in silicon processing and characterization”, Chason et. al, J. Appl. Phys., Vol. 81, No. 10, May 1997.
[6] “Oxygen in Silicon”, Semiconductors and Semimetals, Vol. 42, Academic Press, ISBN 0-12-752142-9.
[7] Float-zone method: Keck and Golay, Phys. Rev. Vol. 89, p. 1297, 1953.
[8] Crystal pulling method: Teal and Little, Phys. Rev, Vol. 80, p. 647, 1950.
[9] “Radiation effects”, Ligeon et. al., Vol. 27, Gordon and Breach Science Publ., p. 129, 1976.
[10] “Process for the production of thin semiconductor material films”, US Patent, U.S. Pat. No. 5,374,564, December 1994.

What I claim is:

1. A device for converting radiation to electrical energy comprising:
a substrate; and
at least one thin film, single crystal layer formed on an original substrate; wherein the original substrate has an oxygen content between about 2×10¹⁶ and 1×10¹⁹ atoms/cm³.

2. A device for converting radiation to electrical energy of claim 1 wherein at least one of said at least one thin film, single crystal layer is of a composition chosen from a group comprising silicon, germanium, silicon-germanium, silicon carbide, carbon, III-V compounds, and II-VI compounds

3. A device of claim 1 further comprising at least one electrical contact comprising a rare-earth silicide.

4. A device of claim 1 comprising interdigitated electrodes.

5. a device of claim 4 wherein said interdigitated electrodes have an electrode width of less than about two microns and an inter electrode spacing of less than about two microns.

6. A device of claim 1 wherein said substrate is an alternative substrate.

7. A device of claim 6 further comprising at least one electrical contact formed on said alternative substrate.

8. A device of claim 6 wherein said alternative substrate is transparent to at least 50% of solar radiation.

9. A device of claim 6 wherein said alternative substrate further comprises at least one antireflective layer.

10. A device for converting radiation to electrical energy comprising:
a substrate; and
a plurality of unit cells comprising vertical p-n junctions;
wherein at least one unit cell is configured as a voltage source and at least one unit cell is configured as a current source.

11. The device of claim 10 wherein said substrate is an alternative substrate.

12. The device of claim 10 wherein said vertical p-n junctions comprise inversion layer diodes.

13. A device for converting radiation to electrical energy comprising:
a substrate; and
a plurality of unit cells comprising lateral p-n junction diodes; wherein at least one unit cell is configured as a voltage source and at least one unit cell is configured as a current source.

14. The device of claim 13 further comprising at least one electrical contact comprising a rare-earth silicide.

15. The device of claim 13 wherein said substrate is an alternative substrate.

16. The device of claim 13 comprising interdigitated electrodes.

17. The device of claim 16 wherein said interdigitated electrodes have an electrode width of less than about two microns and an inter-electrode spacing of less than about two microns.

18. The device of claim 15 wherein said alternative substrate is transparent to at least 50% of solar radiation.

19. The device of claim 15 wherein said alternative substrate further comprises at least one antireflective layer.

20. The device of claim 13 wherein said lateral p-n junctions comprise inversion layer diodes.

21. A device for converting radiation to electrical energy comprising:
a substrate; and
a single crystal, thin film layer with a thickness ranging from about 20 nm to about 10 microns such that radiation in the range of about 200 to 700 nm enables avalanche multiplication.

22. A device for converting radiation to electrical energy of claim 21 further comprising
a lateral p-i-n-type conductivity region comprising a 3-terminal device wherein a dielectric and one or more metal contacts span the intrinsic region.

23. A device for converting radiation to electrical energy of claim 21 wherein said single crystal, thin film layer is one or more single crystal, thin film layers of a composition chosen from a group comprising silicon, germanium, silicon-germanium, silicon carbide, carbon, III-V compounds, and II-VI compounds

24. A device for converting radiation to electrical energy of claim 23 further comprising one or more rare-earths in combination with said one or more single crystal, thin film layers.

25. A device for converting radiation to electrical energy of claim 24 further comprising
one or more elements chosen from a group comprising oxygen, nitrogen and phosphorus in combination with said one or more rare-earths.
